(19) United States
(12) Patent Application Publication
(10) Pub. No.: US 2015/0021156 A1
(43) Pub. Date: Jan. 22, 2015

(54) TRANSPARENT CONDUCTIVE ELEMENT AND METHOD FOR MANUFACTURING THE SAME, INPUT DEVICE, ELECTRONIC APPARATUS, AND METHOD FOR PATTERNING THIN FILM

(71) Applicant: DEXERIALS CORPORATION, Tokyo (JP)

(72) Inventors: Junichi Inoue, Tochigi (JP); Tomoo Fukuda, Kanagawa (JP)

(21) Appl. No.: 14/372,571

(22) PCT Filed: Jan. 24, 2013
(86) PCT No.: PCT/JP2013/051411

§ 371 Date: Jul. 16, 2014

(30) Foreign Application Priority Data
Jan. 24, 2012 (JP) 2012-012529
Aug. 21, 2012 (JP) 2012-182787

(51) Int. Cl. H03K 17/96; G06F 3/044

(52) U.S. Cl. CPC H03K 17/962; G06F 3/044; H03K 2217/960755; H03K 2017/9613
USPC 200/600; 200/278; 216/17

(57) ABSTRACT

A transparent conductive element easily formed by a printing method includes a substrate having a surface, and transparent conductive portions and transparent insulating portions that are alternately provided in a planar manner on the surface. Each of the transparent insulating portions is a transparent conductive layer including a plurality of hole elements provided two-dimensionally in a first direction and a second direction on the surface of the substrate. The hole elements that are adjacent in the first direction are connected to each other, and the hole elements that are adjacent in the second direction are connected to each other.

### TECHNICAL FIELD

The present technique relates to a transparent conductive element and a method for manufacturing the same, an input device, an electronic apparatus, and a method for patterning a thin film. In particular, the present technique relates to a transparent conductive element including transparent conductive portions and transparent insulating portions that are alternately provided in a planar manner on the surface of a substrate.

### BACKGROUND ART

In recent years, mobile devices such as mobile phones and portable music terminals are often equipped with capacitive touch panels. Capacitive touch panels use a transparent conductive film including a substrate film and a patterned transparent conductive layer formed on the surface of the substrate film.

Patent Document 1 proposes a transparent conductive sheet having the following configuration. The transparent conductive sheet includes a conductive pattern layer formed on a substrate sheet and an insulating pattern layer formed on a some surface region of the substrate sheet on which no conductive pattern layer is formed. The conductive pattern layer has a plurality of fine pinholes, and the insulating pattern layer is formed as a plurality of islands separated by narrow grooves.

### PRIOR ART DOCUMENT(S)

### Patent Document(s)

Patent Document 1: Japanese Patent Application Laid-Open No. 2010-157400

### SUMMARY OF INVENTION

### Technical Problem

Recently, it is desired that a printing method is used to produce a thin film, such as a transparent conductive layer and a metal layer, having a fine pattern as described above. To meet the above demand, it is preferable that a fine pattern that can be easily formed by a printing method be used.

Accordingly, it is an object of the present technique to provide a transparent conductive element that can be easily formed by a printing method and a method for manufacturing the same, an input device, an electronic apparatus, and a method for patterning a thin film.

### Solution to Problem

To solve the above problem, a first technique is

a transparent conductive element including:

a substrate having a surface; and

transparent conductive portions and transparent insulating portions that are alternately provided in a planar manner on the surface, wherein

each of the transparent insulating portions is a transparent conductive layer including a plurality of hole elements provided two-dimensionally in a first direction and a second direction on the surface of the substrate, and

the hole elements that are adjacent in the first direction are connected to each other, and the hole elements that are adjacent in the second direction are connected to each other.

A second technique is an input device including:

a substrate having a first surface and a second surface;

transparent conductive portions and transparent insulating portions that are alternately provided in a planar manner on the first surface and on the second surface, wherein

each of the transparent insulating portions is a transparent conductive layer including a plurality of hole elements provided two-dimensionally in a first direction and a second direction, and

the hole elements that are adjacent in the first direction are connected to each other, and the hole elements that are adjacent in the second direction are connected to each other.

A third technique is an input device including:

a first transparent conductive element; and

a second transparent conductive element provided on a surface of the first transparent conductive element, wherein

each of the first transparent conductive element and the second transparent conductive element includes
a substrate having a surface,
transparent conductive portions and transparent insulating portions that are alternately provided in a planar manner on the surface,

each of the transparent insulating portions is a transparent conductive layer including hole elements provided two-dimensionally in a first direction and a second direction, and

the hole elements that are adjacent in the first direction are connected to each other, and the hole elements that are adjacent in the second direction are connected to each other.

A fourth technique is an electronic apparatus including:

a transparent conductive element including a substrate having a first surface and a second surface, and transparent conductive portions and transparent insulating portions that are alternately provided in a planar manner on the first surface and on the second surface, wherein

each of the transparent insulating portions is a transparent conductive layer including hole elements provided two-dimensionally in a first direction and a second direction, and

the hole elements that are adjacent in the first direction are connected to each other, and the hole elements that are adjacent in the second direction are connected to each other.

A fifth technique is an electronic apparatus including:

a first transparent conductive element; and

a second transparent conductive element provided on a surface of the first transparent conductive element, wherein

each of the first transparent conductive element and the second transparent conductive element includes
a substrate having a first surface and a second surface,
transparent conductive portions and transparent insulating portions that are alternately provided in a planar manner on the first surface and on the second surface,

each of the transparent insulating portions is a transparent conductive layer including hole elements provided two-dimensionally in a first direction and a second direction, and

the hole elements that are adjacent in the first direction are connected to each other, and the hole elements that are adjacent in the second direction are connected to each other.

A sixth technique is a method for manufacturing a transparent conductive element, the method including:

printing an etching solution onto a transparent conductive layer provided on a surface of a substrate to form hole elements arranged two-dimensionally in a first direction and a second direction on the surface of the substrate, whereby transparent conductive portions and transparent insulating portions that are alternately provided in a planar manner on the surface are formed, wherein

the hole elements that are adjacent in the first direction are connected to each other, and the hole elements that are adjacent in the second direction are connected to each other.

A seventh technique is a method for patterning a thin film, the method including:

printing an etching solution onto a thin film provided on a surface of a substrate to form a plurality of hole elements arranged one-dimensionally or two-dimensionally in the thin film, wherein

the hole elements are connected to each other.

In the above techniques, a plurality of hole elements are provided two-dimensionally in the first direction and the second direction on the surface of the substrate. The hole elements can be easily produced using a printing method. Since hole elements adjacent in the first direction are connected to each other and hole elements adjacent in the second direction are connected to each other, electric paths in the transparent conductive layer are cut, so that the transparent conductive layer can function as insulating portions.

In the above techniques, since the transparent conductive portions and transparent insulating portions are alternately provided in a planar manner on the surface of the substrate, the difference between the reflectance in regions having the transparent conductive portions provided therein and the reflectance in regions having no transparent conductive portions provided therein can be reduced. Therefore, visual recognition of the pattern of the transparent conductive portions can be suppressed.

### Advantageous Effects of Invention

As described above, the present technique can provide a transparent conductive element that can be easily formed using a printing method.

### BRIEF DESCRIPTION OF DRAWINGS

FIG. 1 is a cross-sectional view illustrating a configuration example of an information input device according to a first embodiment of the present technique.

FIG. 2A is a plan view illustrating a configuration example of a first transparent conductive element according to the first embodiment of the present technique. FIG. 2B is a cross-sectional view taken along line A-A shown in FIG. 2A.

FIG. 3A is a plan view illustrating a configuration example of transparent electrode portions of the first transparent conductive element according to the first embodiment of the present technique. FIG. 3B is a cross-sectional view taken along line A-A shown in FIG. 3A. FIG. 3C is a plan view illustrating a configuration example of transparent insulating portions of the first transparent conductive element according to the first embodiment of the present technique. FIG. 3D is a cross-sectional view taken along line A-A shown in FIG. 3C.

FIG. 4A is a schematic diagram illustrating a first arrangement example of hole elements in the transparent electrode portions. FIG. 4B is a schematic diagram illustrating a second arrangement example of the hole elements in the transparent electrode portions.

FIG. 5A is a schematic diagram illustrating a first arrangement example of hole elements in the transparent insulating portions. FIG. 5B is a schematic diagram illustrating a second arrangement example of the hole elements in the transparent insulating portions.

FIG. 6A is a plan view illustrating an example of a shape pattern in a boundary portion. FIG. 6B is a cross-sectional view taken along line A-A shown, in FIG. 6A.

FIG. 7A is a schematic diagram illustrating a first arrangement example of hole elements in boundary portions. FIG. 7B is a schematic diagram illustrating a second arrangement example of the hole elements in the boundary portions.

FIG. 8A is a plan view illustrating a configuration example of a second transparent conductive element according to the first embodiment of the present technique. FIG. 8B is a cross-sectional view taken along line A-A shown in FIG. 8A.

FIGS. 9A to 9C are process diagrams illustrating an example of a method for manufacturing the first transparent conductive element according to the first embodiment of the present technique.

FIG. 10 is a flowchart for explaining a random pattern generation algorithm.

FIGS. 11A to 11D are schematic diagrams for explaining the random pattern generation algorithm.

FIGS. 12A and 12B are schematic diagrams illustrating the relationship between dots (cells) constituting a grid and the size of hole elements.

FIGS. 13A to 13D are cross-sectional views illustrating modifications of the first transparent conductive element according to the first embodiment of the present technique.

FIGS. 14A and 14B are cross-sectional views illustrating modifications of the first transparent conductive element according to the first embodiment of the present technique.

FIG. 15A is a plan view illustrating a configuration example of transparent electrode portions of a first transparent conductive element according to a second embodiment of the present technique. FIG. 15B is a cross-sectional view taken along line A-A shown in FIG. 15A. FIG. 15C is a plan view illustrating a configuration example of transparent insulating portions of the first transparent conductive element according to the second embodiment of the present technique. FIG. 15D is a cross-sectional view taken along line A-A shown in FIG. 15C.

FIG. 16A is a plan view illustrating an example of a shape pattern in a boundary portion. FIG. 16B is a cross-sectional view taken along line A-A shown in FIG. 16A.

FIG. 17A is a plan view illustrating a configuration example of a first transparent conductive element according to a third embodiment of the present technique. FIG. 17B is a cross-sectional view taken along line A-A shown in FIG. 17A.

FIG. 18A is a plan view illustrating a configuration example of a first transparent conductive element according to a fourth embodiment of the present technique. FIG. 18B is a cross-sectional view taken along line A-A shown in FIG. 18A.

FIG. 19A is a plan view illustrating a configuration example of a first transparent conductive element according to a fifth embodiment of the present technique. FIG. 19B is a cross-sectional view taken along line A-A shown in FIG. 19A.

FIG. 20A is a plan view illustrating a configuration example of a first transparent conductive element according to a sixth embodiment of the present technique. FIG. 20B is a cross-sectional view taken along line A-A shown in FIG. 20A.

FIG. 21A is a plan view illustrating a configuration example of transparent electrode portions of a first transparent conductive element according to a seventh embodiment of the present technique. FIG. 21B is a plan view illustrating a configuration example of transparent insulating portions of the first transparent conductive element according to the seventh embodiment of the present technique.

FIG. 22A is a schematic diagram illustrating an example of a grid having two dot sizes. FIG. 22B is a schematic diagram illustrating an example of a transparent electrode portion formed using the grid having two dot sizes. FIG. 22C is a schematic diagram illustrating an example of a transparent insulating portion formed using the grid having two dot sizes.

FIG. 23A is a schematic diagram illustrating an example of a grid having three dot sizes. FIG. 23B is a schematic diagram illustrating an example of a transparent electrode portion formed using the grid having three dot sizes. FIG. 23C is a schematic diagram illustrating an example of a transparent insulating portion formed using the grid having three dot sizes.

FIG. 24A is a schematic diagram illustrating an example of a grid with a parallelogrammic dot shape. FIG. 24B is a schematic diagram illustrating an example of a transparent electrode portion formed using the grid with a parallelogrammic dot shape. FIG. 24C is a schematic diagram illustrating an example of a transparent insulating portion formed using the grid with a parallelogrammic dot shape.

FIG. 25A is a plan view illustrating a configuration example of a first transparent conductive element according to a tenth embodiment of the present technique. FIG. 25B is a plan view illustrating a configuration example of a second transparent conductive element according to the tenth embodiment of the present technique.

FIG. 26 is a cross-sectional view illustrating a configuration example of an information input device according to an eleventh embodiment of the present technique.

FIG. 27A is a plan view illustrating a configuration example of an information input device according to a twelfth embodiment of the present technique. FIG. 27B is a cross-sectional view taken along line A-A shown in FIG. 27A.

FIG. 28A is an enlarged plan view illustrating the vicinity of an intersecting portion C shown in FIG. 27A. FIG. 28B is a cross-sectional view taken along line A-A shown in FIG. 28A.

FIG. 29A is a plan view illustrating a first configuration example of a region R shown in FIG. 27A. FIG. 29B is a plan view illustrating a second configuration example of the region R shown in FIG. 27A.

FIG. 30 is an appearance diagram showing an example of a television set as an electronic apparatus.

FIGS. 31A and 31B are appearance diagrams showing an example of a digital camera as the electronic apparatus.

FIG. 32 is an appearance diagram showing an example of a notebook personal computer as the electronic apparatus.

FIG. 33 is an appearance diagram showing an example of a video camera as the electronic apparatus.

FIG. 34 is an appearance diagram showing an example of a portable terminal device as the electronic apparatus.

FIG. 35A is a diagram illustrating a raster image in bitmap format used to produce a transparent conductive sheet in Example 2. FIG. 35B is a diagram illustrating a raster image in bitmap format used to produce a transparent conductive sheet in Example 4. FIG. 35C is a diagram illustrating a raster image in bitmap format used to produce a transparent conductive sheet in Example 7. FIG. 35D is a diagram illustrating a raster image in DXF format used to produce the transparent conductive sheet in Example 4.

FIG. 36 is a diagram illustrating a raster image in bitmap format used to produce a transparent conductive sheet in Example 9.

FIG. 37A is a schematic diagram illustrating a configuration example of a main body of a minute droplet application system according to a thirteenth embodiment of the present technique. FIG. 37B is an enlarged schematic diagram illustrating a main part for liquid droplet application in FIG. 37A.

FIGS. 38A and 38B are diagrams illustrating examples of an etching solution applied using the minute droplet application system according to the thirteenth embodiment of the present technique.

FIGS. 39A to 39D are schematic diagrams illustrating an exemplary operation of an application needle in the minute droplet application system according to the thirteenth embodiment of the present technique. FIG. 39E is a schematic diagram illustrating a liquid droplet formed on an application target surface in the steps in FIGS. 39A to 39D.

FIG. 40 is a schematic diagram illustrating the movement of a liquid droplet ejected from an inkjet nozzle until the liquid droplet lands on the application target.

FIG. 41A is a plan view illustrating an example of a liquid droplet formed by inkjet printing. FIG. 41B is a cross-sectional view taken along line A-A shown in FIG. 41A. FIG. 41C is a plan view illustrating an example of a liquid droplet formed by a needle-type dispenser. FIG. 41D is a cross-sectional view taken along line A-A shown in FIG. 41C.

FIG. 42A is a cross-sectional view illustrating an example of a droplet of an organic solvent dropped on a transparent conductive layer. FIG. 42B is a cross-sectional view illustrating an example of a minute droplet of the organic solvent dropped on the transparent conductive layer.

FIGS. 43A and 43B are process diagrams illustrating an example of a method of forming hole elements in transparent electrode portions and transparent insulating portions in a fourteenth embodiment of the present technique.

FIGS. 44A to 44C are process diagrams illustrating a method for manufacturing a transparent conductive substrate in Example 36.

### DESCRIPTION OF THE EMBODIMENTS

Embodiments of the present technique will next be described in the following order with reference to the drawings.

1. First embodiment (examples of transparent electrode portions and transparent insulating portions that include randomly provided hole elements)

2. Second embodiment (examples of transparent electrode portions and transparent insulating portions that include regularly provided hole elements)

3. Third embodiment (examples of transparent electrode portions formed from a continuous film and transparent insulating portions including randomly provided hole elements)

4. Fourth embodiment (examples of transparent electrode portions formed from a continuous film and transparent insulating portions including regularly provided hole elements)

5. Fifth embodiment (examples of transparent electrode portions including randomly provided hole elements and transparent insulating portions including regularly provided hole elements)

6. Sixth embodiment (examples of transparent electrode portions including regularly provided hole elements and transparent insulating portions including randomly provided hole elements)

7. Seventh embodiment (examples of transparent electrode portions and transparent insulating portions that include randomly provided conductive portion elements)

8. Eighth embodiment (examples of transparent electrode portions and transparent insulating portions that have hole elements with different sizes)

9. Ninth embodiment (an example in which arrangement directions of hole elements are in a diagonally crossing relationship)

10. Tenth embodiment (an example in which transparent electrode portions having a shape with pad sections connected are provided)

11. Eleventh embodiment (an example in which transparent electrode portions are provided on opposite sides of a substrate)

12. Twelfth embodiment (an example in which transparent electrode portions crossing each other are provided on a principal surface of a substrate)

13. Thirteenth embodiment of (examples of transparent electrode portions and transparent insulating portions when hole elements are formed using a minute droplet application system)

14. Fourteenth embodiment (examples of transparent electrode portions and transparent insulating portions when hole elements are formed by wiping after swelling with an organic solvent or water)

15. Fifteenth embodiment (application examples of an electronic apparatus)

### 1. First Embodiment

### [Configuration of Information Input Device]

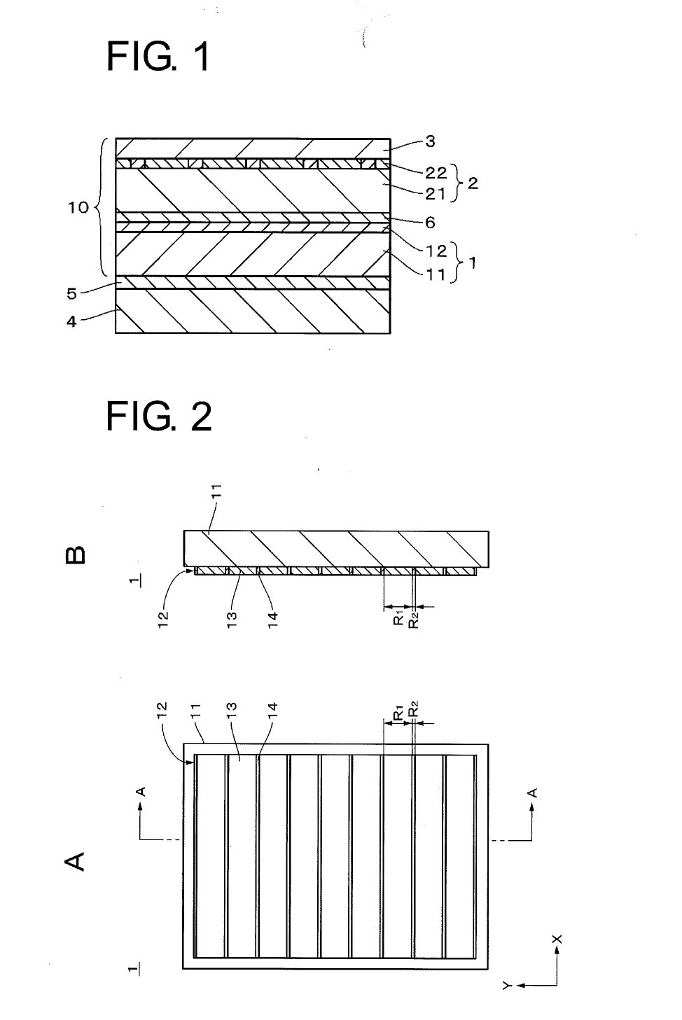

FIG. 1 is a cross-sectional view illustrating a configuration example of an information input device according to a first embodiment of the present technique.

As shown in FIG. 1, the information input device 10 is provided on a display surface of a display device 4, which is an example of an electronic apparatus. The information input device 10 is bonded to the display surface of the display device 4 through, for example, a bonding layer 5.

### (Display Device)

No particular limitation is imposed on the display device 4 to which the information input device 10 is applied. Examples of the display device 4 may include various display devices such as a liquid crystal display, a CRT (Cathode Ray Tube) display, a plasma display (Plasma Display Panel: PDP), an electroluminescence (Electro Luminescence: EL) display, and a surface-conduction electron-emitter display (Surface-conduction Electron-emitter Display: SED).

### (Information Input Device)

The information input device 10 is a so-called projection type capacitive touch panel, and includes a first transparent conductive element 1 and a second transparent conductive element 2 provided on the surface of the first transparent conductive element 1. The first transparent conductive element 1 and the second transparent conductive element 2 are bonded to each other through a bonding layer 6. If necessary, an optical layer 3 may be further provided on the surface of the second transparent conductive element 2.

### (First Transparent Conductive Element)

FIG. 2A is a plan view illustrating a configuration example of the first transparent conductive element according to the first embodiment of the present technique. FIG. 2B is a cross-sectional view taken along line A-A shown in FIG. 2A. As shown in FIGS. 2A and 2B, the first transparent conductive element 1 includes a substrate 11 having a surface and a transparent conductive layer 12 provided on the surface. As employed herein, two mutually orthogonal directions in a plane of the substrate 11 are defined as an X-axis direction (first direction) and a Y-axis direction (second direction).

The transparent conductive layer 12 includes transparent electrode portions (transparent conductive portions) 13 and transparent insulating portions 14. The transparent electrode portions 13 are X electrode portions extending in the X-axis direction. The transparent insulating portions 14 are so-called dummy electrode portions and are insulating portions extending in the X-axis direction and interposed between the transparent electrode portions 13 to insulate the adjacent transparent electrode portions 13 from each other. These transparent electrode portions 13 and transparent insulating portions 14 are alternately and adjacently provided on the surface of the substrate 11 in a planar manner in the Y-axis direction. In FIGS. 2A and 2B, a first region R₁ is a region in which a transparent electrode portion 13 is formed, and a second region R₂ is a region in which a transparent insulating portion 14 is formed.

### (Transparent Electrode Portions and Transparent Insulating Portions)

Preferably, the shape of the transparent electrode portions 13 is appropriately selected according to the shape of the screen, a driving circuit, etc. Examples of the shape of the transparent electrode portions 13 may include a linear shape and a shape composed of a plurality of linearly connected rhombic shapes (diamond shapes), but the shape is not limited to these shapes. In the configuration exemplified in FIGS. 2A and 2B, the transparent electrode portions 13 have a linear shape.

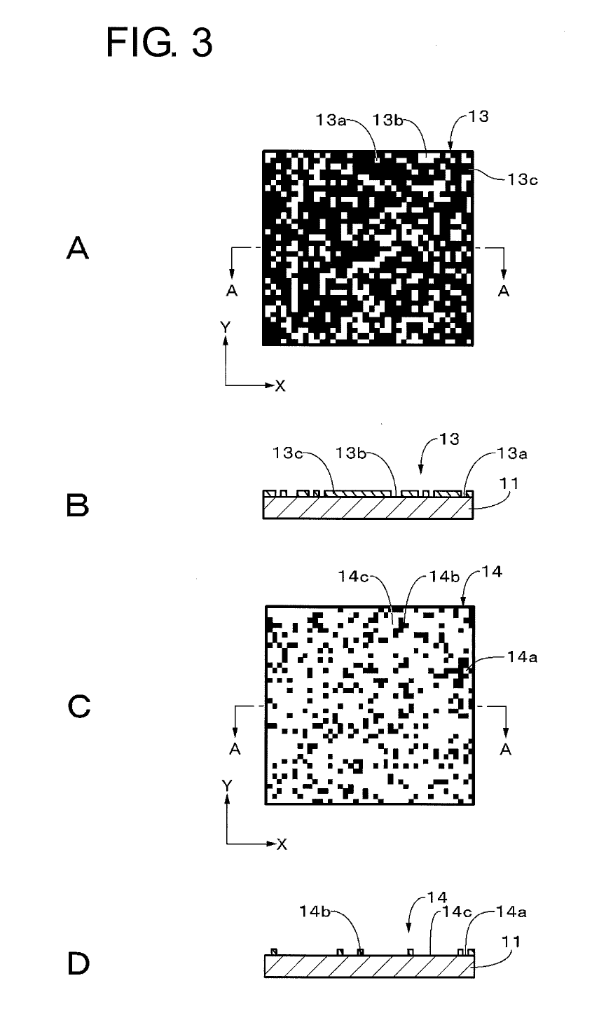

FIG. 3A is a plan view illustrating a configuration example of the transparent electrode portions of the first transparent conductive element. FIG. 3B is a cross-sectional view taken along line A-A shown in FIG. 3A. Each transparent electrode portion 13 is the transparent conductive layer 12 that is formed such that a plurality of hole elements 13a are randomly arranged two-dimensionally in the X-axis and Y-axis directions on the surface of the substrate 11. By randomly forming the plurality of hole elements 13a as described above, the occurrence of moiré can be suppressed. Adjacent hole elements in adjacent rows that are adjacent in the X-axis direction are connected to each other, and adjacent hole elements in adjacent rows that are adjacent in the Y-axis direction are connected to each other.

The plurality of hole elements 13a are formed, for example, so as to be connected to or separated from each other in the X-axis direction. The plurality of hole elements 13a are formed, for example, so as to be connected to or separated from each other in the Y-axis direction. The hole elements 13a formed so as to be connected to or separated from each other described above form hole portions 13b of the transparent electrode portion 13. Specifically, each hole portion 13b is formed of one or a plurality of hole elements 13a. Preferably, diagonally adjacent hole elements 13a in adjacent rows that are adjacent in a direction diagonal to the X-axis or Y-axis direction are spaced apart from each other. In this manner, even when the ratio of hole elements 13a in the transparent electrode portions 13 is increased in order to reduce the difference between the ratio of the area covered with a transparent conductive material in the transparent electrode portions 13 and the ratio of the area covered with the transparent conductive material in the transparent insulating portions 14, conductive paths diagonal to the X-axis or Y-axis direction can be secured. Specifically, low surface resistance can be maintained.

More specifically, each of the transparent electrode portions 13 is the transparent conductive layer 12 including a plurality of hole portions 13b randomly formed so as to be separated from each other, and a transparent conductive portion 13c is interposed between adjacent hole portions 13b. Each hole portion 13b is formed of one hole element 13a or a plurality of connected hole elements 13a. The hole portions 13b have randomly varying shapes on the surface of the substrate 11. The transparent conductive portions 13c are formed mainly of, for example, a transparent conductive material. The transparent conductive portions 13c provide electric conductivity of the transparent electrode portions 13.

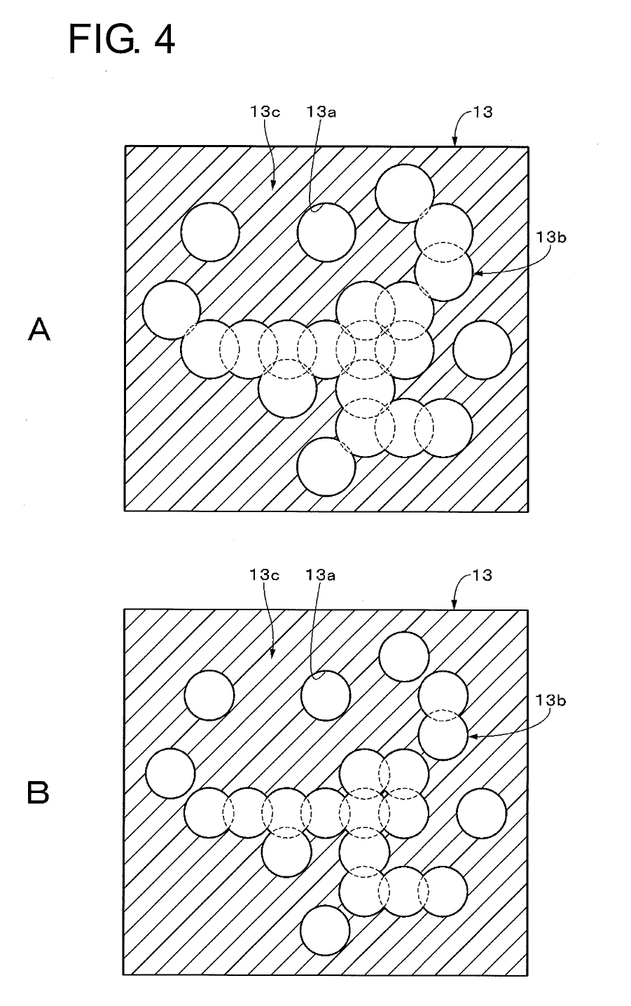

FIG. 4A is a schematic diagram illustrating a first arrangement example of the hole elements in the transparent electrode portions. In the first arrangement example shown in FIG. 4A, adjacent hole elements 13a in adjacent rows that are adjacent in the X-axis direction are connected to each other, and adjacent hole elements 13a in adjacent rows that are adjacent in the Y-axis direction are connected to each other. In addition, adjacent hole elements 13a in adjacent rows that are diagonally adjacent to each other in a direction diagonal to the X-axis or Y-axis direction are connected to each other. As employed herein, the direction diagonal to the X-axis or Y-axis direction is a 45-degree direction, a 135-degree direction, a 225-degree direction, or a 315-degree direction.

FIG. 4B is a schematic diagram illustrating a second arrangement example of the hole elements in the transparent electrode portions. In the second arrangement example shown in FIG. 4B, adjacent hole elements 13a in adjacent rows that are adjacent in the X-axis direction are connected to each other, and adjacent hole elements 13a in adjacent rows that are adjacent in the Y-axis direction are connected to each other. However, adjacent hole elements 13a in adjacent rows that are diagonally adjacent to each other in a direction diagonal to the X-axis or Y-axis direction are separated from each other through transparent conductive portions 13c.

In the first arrangement example, hole elements 13a diagonally adjacent to each other are connected to each other, so that conductive paths in diagonal directions are cut. However, in the second arrangement example, hole elements 13a diagonally adjacent to each other are separated from each other, so that conductive paths in diagonal directions are secured. Therefore, with the second arrangement example, even when the ratio of the hole elements 13a is higher than that in the first arrangement example (i.e., the ratio of the area covered with a transparent conductive material is lower than that in the first arrangement example), the transparent electrode portions 13 can serve as electrode portions. When the second arrangement example is used as the configuration of the transparent electrode portions 13, an increase in the surface resistance of the transparent electrode portions 13 is suppressed. In addition, the difference between the ratio of the area covered with a transparent conductive material in the transparent electrode portions 13 and the ratio of the area covered with the transparent conductive material in the transparent insulating portions 14 is reduced, so that recognition of the pattern of the transparent electrode portions 13 can be suppressed.

FIG. 3C is a plan view illustrating a configuration example of the transparent insulating portions of the first transparent conductive element. FIG. 3D is a cross-sectional view taken along line A-A shown in FIG. 3C. Each transparent insulating portion 14 is the transparent conductive layer that is formed such that a plurality of hole elements 14a are randomly arranged two-dimensionally in the X-axis and Y-axis directions on the surface of the substrate. By randomly forming the plurality of hole elements 14a as described above, the occurrence of moiré can be suppressed. Adjacent hole elements in adjacent rows that are adjacent in the X-axis direction are connected to each other, and adjacent hole elements in adjacent rows that are adjacent in the Y-axis direction are connected to each other.

The plurality of hole elements 14a are formed, for example, so as to be connected to or separated from each other in the X-axis direction. The plurality of hole elements 14a are formed, for example, so as to be connected to or separated from each other in the Y-axis direction. The hole elements 14a formed so as to be connected to or separated from each other described above form separation portions 14c of the transparent insulating portion 14. Preferably, diagonally adjacent hole elements 14a in adjacent rows that are adjacent in a direction diagonal to the X-axis or Y-axis direction are connected to each other. In this manner, even when the ratio of hole elements 14a in the transparent insulating portions 14 is reduced in order to reduce the difference between the ratio of the area covered with a transparent conductive material in the transparent electrode portions 13 and the ratio of the area covered with the transparent conductive material in the transparent insulating portions 14, the number of conductive paths diagonal to the X-axis or Y-axis direction can be reduced. Specifically, high surface resistance can be maintained.

More specifically, each of the transparent insulating portions 14 includes a plurality of island portions 14b spaced apart from each other through separation portions 14c. The plurality of island portions 14b are formed in a random pattern on the surface of the substrate 11. Each separation portion 14c is formed of one hole element 14a or a plurality of connected hole elements 14a. The island portions 14b are electrically insulated from each other through the separation portions 14c. The island portions 14b have randomly varying shapes on the surface of the substrate 11. The island portions 14b are formed mainly of, for example, a transparent conductive material.

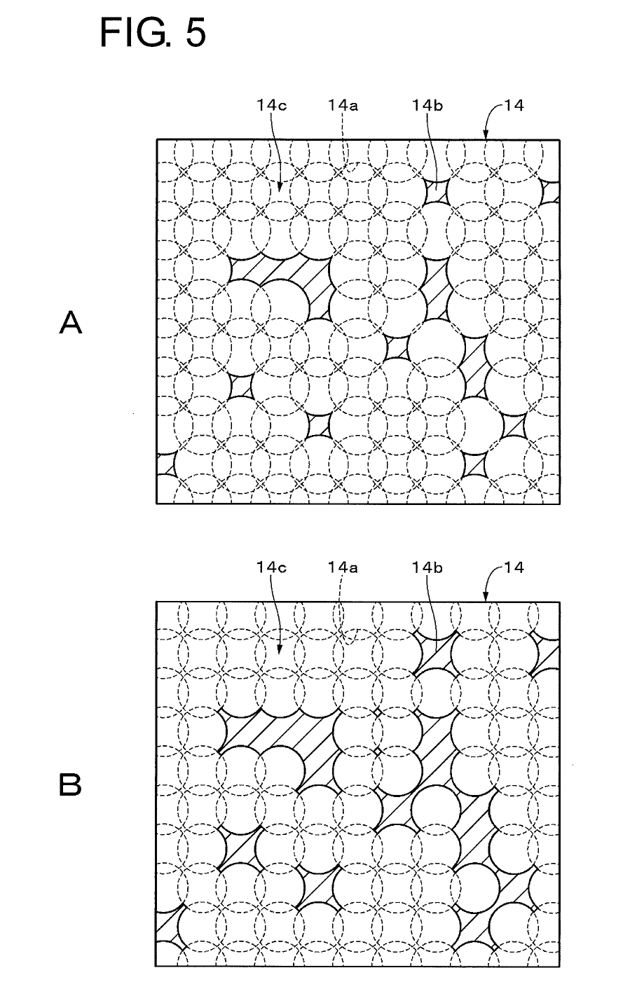

FIG. 5A is a schematic diagram illustrating a first arrangement example of the hole elements in the transparent insulating portions. In the first arrangement example shown in FIG. 5A, adjacent hole elements 14a in adjacent rows that are adjacent in the X-axis direction are connected to each other, and adjacent hole elements 14a in adjacent rows that are adjacent in the Y-axis direction are connected to each other. In addition, adjacent hole elements 14a in adjacent rows that are diagonally adjacent to each other in a direction diagonal to the X-axis or Y-axis direction are connected to each other. As employed herein, the direction diagonal to the X-axis or Y-axis direction is a 45-degree direction, a 135-degree direction, a 225-degree direction, or a 315-degree direction.

FIG. 5B is a schematic diagram illustrating a second arrangement example of the hole elements in the transparent insulating portions. In the second arrangement example shown in FIG. 5B, adjacent hole elements 14a in adjacent rows that are adjacent in the X-axis or Y-axis direction are connected to each other, but adjacent hole elements 14a in adjacent rows that are diagonally adjacent to each other in a direction diagonal to the X-axis or Y-axis direction are separated from each other through island portions 14b.

In the first arrangement example, island portions 14b diagonally adjacent to each other are separated from each other, so that conductive paths in diagonal directions are cut. However, in the second arrangement example, island portions 14b diagonally adjacent to each other are connected to each other, so that conductive paths in diagonal directions are secured. Therefore, with the first arrangement example, even when the ratio of the hole elements 14a is lower than that in the second arrangement example (i.e., the ratio of the area covered with a transparent conductive material is higher than that in the second arrangement example), the transparent insulating portions 14 can serve as insulating portions. When the first arrangement example is used as the configuration of the transparent insulating portions 14, a reduction in the surface resistance of the transparent insulating portions 14 is suppressed, and the difference between the ratio of the area covered with the transparent conductive material in the transparent electrode portions 13 and the ratio of the area covered with the transparent conductive material in the transparent insulating portions 14 is reduced, so that recognition of the pattern of the transparent insulating portions 14 can be suppressed.

FIGS. 4A to 5B show examples of the transparent electrode portions 13 and the transparent insulating portions 14 when the hole elements 13a and 14a are formed using an inkjet printing method. When the hole elements 13a and 14a are formed using the inkjet printing method, the shapes of the hole elements 13a and 14a are, for example, circular, substantially circular, elliptical, or substantially elliptical.

Whether or not the inkjet printing method was used to form the hole elements 13a and 14a can be determined as follows. The transparent electrode portions 13 and the transparent insulating portions 14 are observed, for example, under a microscope to determine whether or not the shapes of the hole elements 13a and the hole elements 14a include shapes such as circular arc, substantially circular arc, elliptical arc, and substantially elliptical arc shapes. When the shapes of the hole elements 13a and the hole elements 14a include any of these shapes, it is assumed that the hole elements 13a and the hole elements 14a were formed using the inkjet printing method.

The shapes of the hole elements 13a and 14a may be, for example, dot shapes. The dot shapes may be, for example, circular, substantially circular, elliptical, or substantially elliptical shapes. The shape of the hole elements 13a and the shape of the hole elements 14a may be different from each other. As employed herein, the substantially circular shapes mean circular shapes obtained by adding some distortion to mathematically defined perfect circles (true circles). The substantially elliptical shapes mean elliptical shapes obtained by adding some distortion to mathematically defined perfect ellipses. The substantially elliptical shapes include, for example, oval shapes and egg-like shapes.

Preferably, the hole elements 13a and the hole elements 14a have visually unrecognizable sizes. The size of the hole elements 13a may be different from the size of the hole elements 14a.

Preferably, the hole portions 13b and the island portions 14b have visually unrecognizable sizes. More specifically, the sizes of the hole portions 13b and the island portions 14b are preferably 100 μm or less and more preferably 60 μm or less. As employed herein, the sizes (diameters) mean the maximum lengths across the hole portions 13b and the island portions 14b. When the sizes of the hole portions 13b and the island portions 14b are 100 μm or less, visual recognition of the hole portions 13b and the island portions 14b can be suppressed.

In each first region R₁, for example, a plurality of hole portions 13b are areas through which the surface of the substrate is exposed, and transparent conductive portions 13c interposed between adjacent hole portions 13b are areas in which the surface of the substrate is covered. In each second region R₂, a plurality of island portions 14b are areas in which the surface of the substrate is covered, and separation portions 14c interposed between adjacent island portions 14b are areas through which the surface of the substrate is exposed.

The average ratio P1 of hole elements 13a per unit section in the transparent electrode portions 13 preferably satisfies the relationship P1≦50[%], more preferably the relationship P1≦40[%], and still more preferably the relationship P1≦30[%]. This is because, when the relationship P1≦50[%] holds, an increase in the electric resistance of the transparent electrode portions 13 is suppressed and the function of the transparent electrode portions 13 as electrodes can be improved.

The average ratio P2 of hole elements 14a per unit section in the transparent insulating portions 14 preferably satisfies the relationship 50[%]<P2 and more preferably 60[%]<P2. This is because, when the relationship 50[%]<P2 holds, a reduction in the electric resistance of the transparent insulating portions 14 is suppressed and the function of the transparent insulating portions 14 as insulating portions can be improved.

The difference ΔP (=P2−P1) between the average ratio P1 of hole elements 13a per unit section in the transparent electrode portions 13 and the average ratio P2 of hole elements 14a per unit section in the transparent insulating portions 14 preferably satisfies the relationship ΔP≦30[%], more preferably the relationship ΔP≦20[%], and still more preferably the relationship ΔP≦10[%]. In the case in which any of these relationships holds, when the transparent electrode portions 13 and the transparent insulating portions 14 are compared visually, the transparent conductive layer 12 looks like it is coated similarly in both the first regions R₁ and the second regions R₂, so that visual recognition of the transparent electrode portions 13 and the transparent insulating portions 14 can be suppressed.

The average ratio P1 of hole elements 13a per unit section in the transparent electrode portions 13 can be determined as follows.

First, an image of the transparent electrode portions 13 is taken under a microscope. Next, a 100×100 grid (unit section) is formed on the image taken. Then whether or not dots (cells) included in the grid have hole elements 13a formed therein is determined, and the number n of dots having hole elements 13a formed therein is counted. As employed herein, a section in which the 100×100 grid is formed is referred to as a unit section. Next, the ratio p of the hole elements 13a is determined using the following formula.

P=(n/N)×100

n: the number of dots in the 100×100 grid which have hole elements 13a formed therein.

N: the total number of dots in the 100×100 grid.

The above processing is performed on 10 sections arbitrarily selected from the transparent electrode portions 13 to determine the ratios p1, p2, . . . , p10 of hole elements 13a per unit section in the transparent electrode portions 13. Then the numbers of dots determined as described above are simply (arithmetically) averaged to determine the average ratio P1 of hole elements 13a per unit section in the transparent electrode portions 13.

The average ratio P2 of hole elements 14a per unit section in the transparent insulating portions 14 can be determined in a similar manner as that for the average ratio P1 of hole elements 13a per unit section in the transparent electrode portions 13 described above.

### (Boundary Portion)

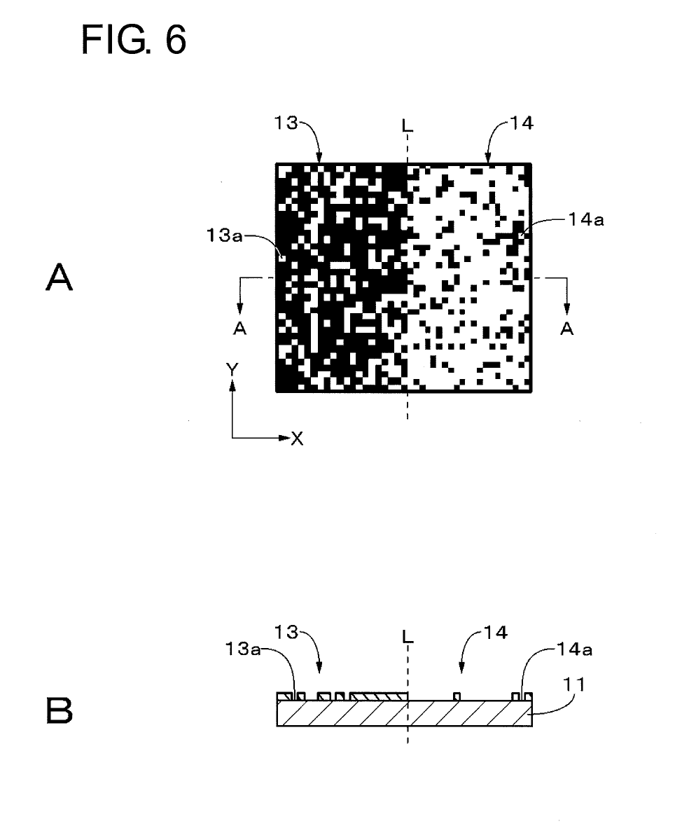

FIG. 6A is a plan view illustrating an example of a shape pattern in a boundary portion. FIG. 6B is a cross-sectional view taken along line A-A shown in FIG. 6A. Preferably, a random shape pattern is provided at boundary portions between the transparent electrode portions 13 and the transparent insulating portions 14. When such a random shape pattern is provided at each boundary portion, visual recognition of the boundary portion can be suppressed. As employed herein, a boundary portion refers to a region between a transparent electrode portion 13 and a transparent insulating portion 14, and a boundary L refers to a boundary line dividing the transparent electrode portion 13 and the transparent insulating portion 14 from each other. For some boundary shape patterns, the boundary L may not a solid line but a virtual line.

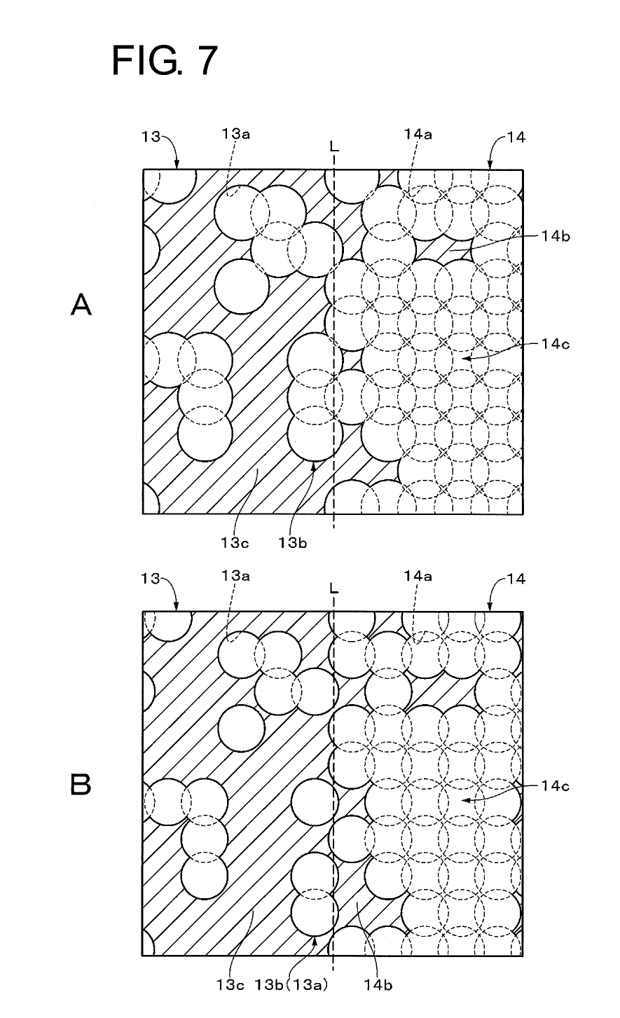

FIG. 7A is a schematic diagram illustrating a first arrangement example of hole elements in the boundary portions. Preferably, in each of the boundary portions between the transparent electrode portions 13 and the transparent insulating portions 14, hole elements 13a and hole elements 14a are randomly arranged in the extending direction of the boundary portion. When such an arrangement is employed, hole elements 13a are arranged, for example, so as to be in contact with the boundary L on the side of the transparent electrode portion 13 or so as to overlap the boundary L. Hole elements 14a are arranged, for example, so as to be in contact with the boundary L on the side of the transparent insulating portion 14 or so as to overlap the boundary L.

The arrangement of hole elements 13a and hole elements 14a in each boundary portion is not limited to the random arrangement. The hole elements 13a and the hole elements 14a may be arranged regularly only in the boundary portion.

Hole portions 13b and island portions 14b may be arranged at the boundary L in a synchronous manner in the extending direction of the boundary L, as shown in FIG. 7B. Hole elements 13a and hole elements 14a or hole portions 13b and island portions 14b may be arranged at the boundary L in a synchronous manner in the extending direction of the boundary L.

### (Substrate)

The substrate 11 used may be, for example, a transparent inorganic substrate or a transparent plastic substrate. The shape of the substrate 11 may be, for example, a transparent film, sheet, or substrate shape. Examples of the material of the inorganic substrate include quartz, sapphire, glass, and clay films. Any known polymer material, for example, may be used as the material of the plastic substrate. Specific examples of the known polymer material may include triacetylcellulose (TAC), polyester (TPEE), polyethylene terephthalate (PET), polyethylene naphthalate (PEN), polyimide (PI), polyamide (PA), aramid, polyethylene (PE), polyacrylate, polyether sulfone, polysulfone, polypropylene (PP), diacetylcellulose, polyvinyl chloride, acrylic resin (PMMA), polycarbonate (PC), epoxy resin, urea resin, urethane resin, melamine resin, cycloolefin polymers (COPs), and cycloolefin copolymers (COCs). The thickness of the plastic substrate is preferably 3 to 500 μm from the viewpoint of productivity but is not particularly limited within this range.

### (Transparent Conductive Layer)

For example, at least one selected from the group consisting of electrically conductive metal oxide materials, electrically conductive metal materials, electrically conductive carbon materials, conductive polymers, etc. can be used as the material of the transparent conductive layer 12. Examples of the metal oxide materials may include indium tin oxide (ITO), zinc oxide, indium oxide, antimony-doped tin oxide, fluorine-doped tin oxide, aluminum-doped zinc oxide, gallium-doped zinc oxide, silicon-doped zinc oxide, zinc oxide-tin oxide based materials, indium oxide-tin oxide based materials, and zinc oxide-indium oxide-magnesium oxide based materials. The metal material used may be, for example, any of metal nanoparticles and metal wires. Specific examples of the metal material may include: metals such as copper, silver, gold, platinum, palladium, nickel, tin, cobalt, rhodium, iridium, iron, ruthenium, osmium, manganese, molybdenum, tungsten, niobium, tantalum, titanium, bismuth, antimony, and lead; and alloys of these metals. Examples of the carbon materials may include carbon black, carbon fibers, fullerenes, graphene, carbon nanotubes, carbon microcoils, and carbon nanohorns. Examples of the conductive polymers may include substituted or unsubstituted polyaniline, substituted or unsubstituted polypyrrole, substituted or unsubstituted polythiophene, and (co)polymers composed of one or two selected from these polymers.

### (Second Transparent Conductive Element)

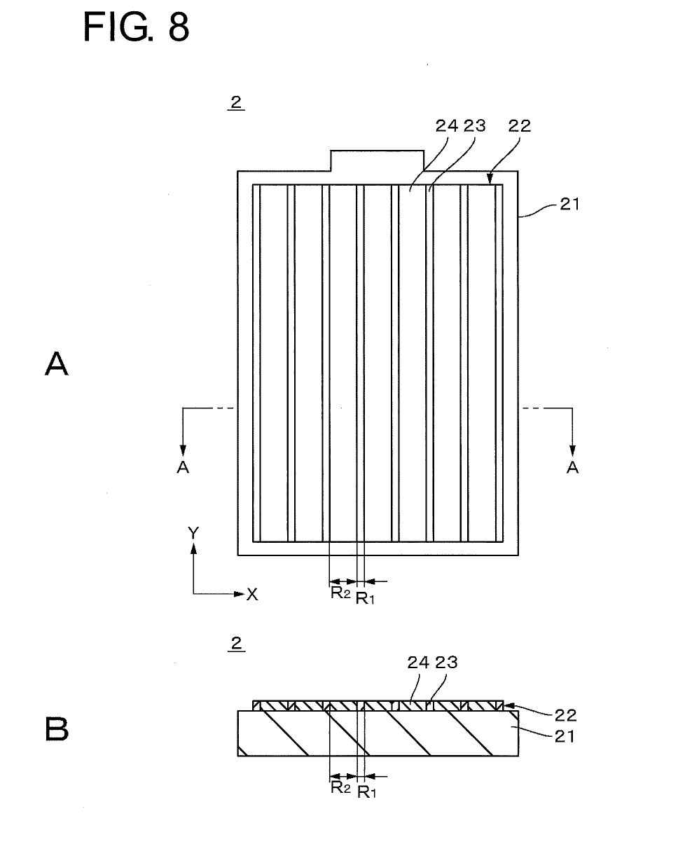

FIG. 8A is a plan view illustrating a configuration example of the second transparent conductive element according to the first embodiment of the present technique. FIG. 8B is a cross-sectional view taken along line A-A shown in FIG. 8A. As shown in FIGS. 8A and 8B, the second transparent conductive element 2 includes a substrate 21 having a surface and a transparent conductive layer 22 disposed on the surface. As employed herein, two mutually orthogonal directions in a plane of the substrate 21 are defined as an X-axis direction and a Y-axis direction.

The transparent conductive layer 22 includes transparent electrode portions (transparent conductive portions) 23 and transparent insulating portions 24. The transparent electrode portions 23 are Y electrode portions extending in the Y-axis direction. The transparent insulating portions 24 are dummy electrode portions and are insulating portions extending in the Y-axis direction and interposed between the transparent electrode portions 23 to insulate adjacent transparent electrode portions 23 from each other. These transparent electrode portions 23 and transparent insulating portions 24 are alternately and adjacently provided on the surface of substrate 21 in a planar manner in the X-axis direction. The transparent electrode portions 13 and the transparent insulating portions 14 included in the first transparent conductive element 1 are, for example, mutually orthogonal to the transparent electrode portions 23 and the transparent insulating portions 24 included in the second transparent conductive element 2. In FIGS. 8A and 8B, a first region R₁ refers to a region in which a transparent electrode portion 23 is formed, and a second region R₂ refers to a region in which a transparent insulating portion 24 is formed.

In the second transparent conductive element 2, the rest of the configuration is the same as that of the first transparent conductive element 1.

### (Optical Layer)

The optical layer 3 is a protective layer for suppressing, for example, changes over time. No particular limitation is imposed on the material of the optical layer 3, so long as it is transparent. Examples of such a material may include UV (ultraviolet) curable resins, thermosetting resins, and thermoplastic resins. Specific examples of such a material may include know materials such as acrylic resin, urethane resin, polyester resin, polyester polyurethane resin, epoxy resin, urea resin, melamine resin, cycloolefin polymers (COPs), cycloolefin copolymers (COCs), ethyl cellulose, polyvinyl alcohol (PVA), and silicone resin.

### [Method for Manufacturing Transparent Conductive Elements]

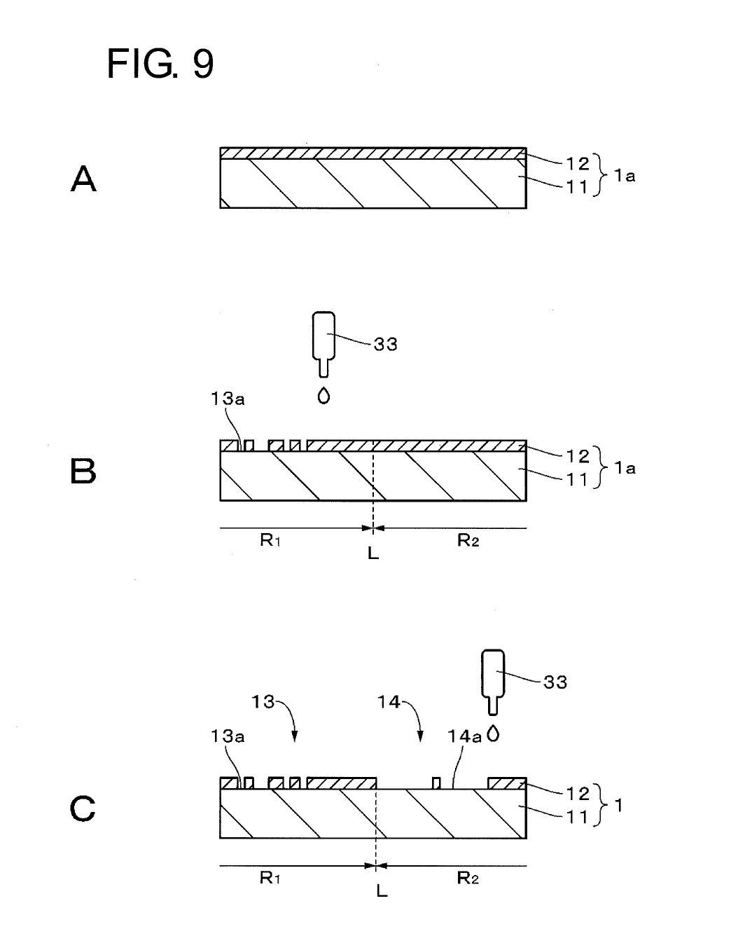

Referring next to FIGS. 9A to 9C, an example of a method for manufacturing the first transparent conductive element 1 configured as described above will be described. Since the second transparent conductive element 2 can be produced in substantially the same manner as that for the first transparent conductive element 1, a description of the method for manufacturing the second transparent conductive element 2 will be omitted.

### (Deposition Step)

First, as shown in FIG. 9A, a transparent conductive layer 12 is deposited on the surface of the substrate 11 to produce a transparent conductive substrate 1a. The method used to deposit the transparent conductive layer 12 may be any of dry and wet deposition methods.

Examples of the dry deposition method used may include: CVD (Chemical Vapor Deposition: techniques for precipitating a thin film from a vapor phase using a chemical reaction) methods such as thermal CVD, plasma CVD, optical CVD, and ALD (Atomic Layer Disposition) methods; and PVD (Physical Vapor Deposition: techniques for forming a thin film by condensing a material physically vaporized in a vacuum on a substrate) methods such as vacuum vapor deposition, plasma-assisted vapor deposition, sputtering, and ion plating methods.

When a dry deposition method is used, the transparent conductive layer 12 may be subjected to annealing treatment as needed after the deposition of the transparent conductive layer 12. In this case, the transparent conductive layer 12 is in, for example, an amorphous-polycrystal mixed state or a polycrystalline state, and the electrical conductivity of the transparent conductive layer 12 is improved.

Examples of the wet deposition method used may include a method including applying or printing a transparent conductive coating material containing a conductive filler to or onto the surface of the substrate 11 to form a coating film on the surface of the substrate 11 and then drying and/or firing the coating film. Examples of the application method used may include a micro-gravure coating method, a wire bar coating method, a direct gravure coating method, a die coating method, a dipping method, a spray coating method, a reverse roll coating method, a curtain coating method, a comma coating method, a knife coating method, and a spin coating method, but the application method is not particularly limited to these methods. Examples of the printing method used may include a letterpress printing method, an offset printing method, a gravure printing method, an intaglio printing method, a rubber plate printing method, and a screen printing method, but the printing method is not particularly limited to these methods. A commercial product may be used as the transparent conductive substrate 1a.

### (Etching Step)

Next, as shown in FIG. 9B, an etching solution is printed (painted) on a first region R₁ of the transparent conductive layer 12 to dissolve the transparent conductive layer 12 by the etching solution. Hole elements 13a are thereby formed so as to be randomly arranged two-dimensionally in the X-axis direction (the first direction) and the Y-axis direction (the second direction) on the surface of the substrate 11. Next, if necessary, the transparent conductive layer 12 is washed to stop the progress of etching. The first region R₁ of the transparent conductive layer 12 is thereby patterned, and a transparent electrode portion 13 is obtained.

Next, as shown in FIG. 9C, the etching solution is printed (painted) on a second region R₂ of the transparent conductive layer 12 to dissolve the transparent conductive layer 12 by the etching solution. Hole elements 14a are thereby formed so as to be randomly arranged two-dimensionally in the X-axis direction (the first direction) and the Y-axis direction (the second direction) on the surface of the substrate 11. Next, if necessary, the transparent conductive layer 12 is washed to stop the progress of etching. The second region R₂ of the transparent conductive layer 12 is thereby patterned, and a transparent insulating portion 14 is obtained.

The above-described etching step performed on the first region R₁ and the second region R₂ is repeated to form transparent electrode portions 13 and transparent insulating portions 14 alternately provided in a planar manner on the surface of the substrate 11.

The etching solution used may be a strong acid or a strong alkali. Examples of the strong acid used may include known acids such as hydrochloric acid, sulfuric acid, aqua regia, and phosphoric acid. Examples of the strong alkali used may include known alkalis such as sodium hydroxide, lithium hydroxide, and potassium hydroxide. For example, an iodine solution containing iodine and an iodine compound can be used as an etching solution for a transparent conductive layer 12 containing a material such as gold or silver.

Examples of the printing method used may include a letterpress printing method, an offset printing method, a gravure printing method, an intaglio printing method, a rubber plate printing method, an inkjet printing method, a microcontact printing method, and a screen printing method. Of these, an inkjet printing method is preferably used. This is because there is no need to produce a plate and on-demand printing is possible. In the example shown in FIGS. 9B and 9C, the etching solution is ejected by the inkjet printing method from a nozzle 33 to print (paint) the etching solution on the transparent conductive layer 12.

The etching solution is printed (painted), for example, according to a random pattern generated in advance. More specifically, the random pattern is stored in advance in a storage unit as a raster image including white dots and black dots arranged in the random pattern, and the etching solution is printed (painted) according to this raster image. The details of an algorithm for generating the raster image including white dots and black dots arranged in a random pattern will be described later.

Preferably, the resolution of printing is appropriately selected according to the printing method used. For example, with the inkjet printing method, the resolution (dots per inch (dpi)) must be determined from the size of one dot according to the performance of the inkjet printing method.

TABLE 1 shows an example of the relationship between the size of one dot and the resolution.

TABLE 1

| Resolution (dpi) | Size of single dot (μm) |
|---|---|
| 300 | 84.7 |
| 600 | 42.3 |
| 1200 | 21.2 |
| 2400 | 10.6 |
| 4800 | 5.3 |

### (Optical Layer Forming Step)

Next, if necessary, an optical layer 3 is formed on the patterned transparent conductive layer 12. For example, a coating method or a printing method can be used to form the optical layer. Examples of the coating method used may include a micro-gravure coating method, a wire bar coating method, a direct gravure coating method, a die coating method, a dipping method, a spray coating method, a reverse roll coating method, a curtain coating method, a comma coating method, a knife coating method, and a spin coating method. Examples of the printing method used may include a letterpress printing method, an offset printing method, a gravure printing method, an intaglio printing method, a rubber plate printing method, inkjet printing, micro-contact printing, and a screen printing method.

The first transparent conductive element 1 shown in FIGS. 2A and 2B is thereby obtained.

### [Algorithm for Generating Raster Image]

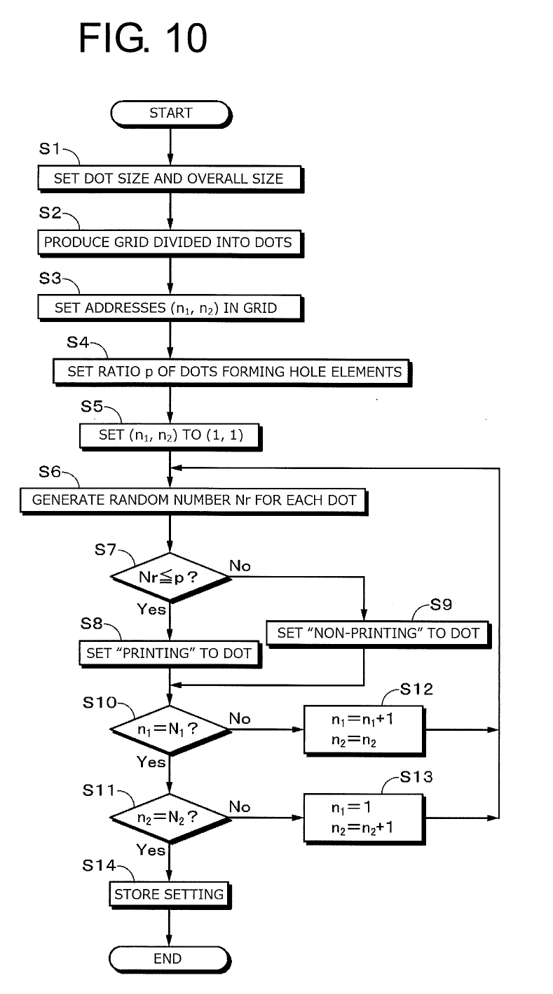

The algorithm for generating a raster image will be described with reference to FIG. 10.

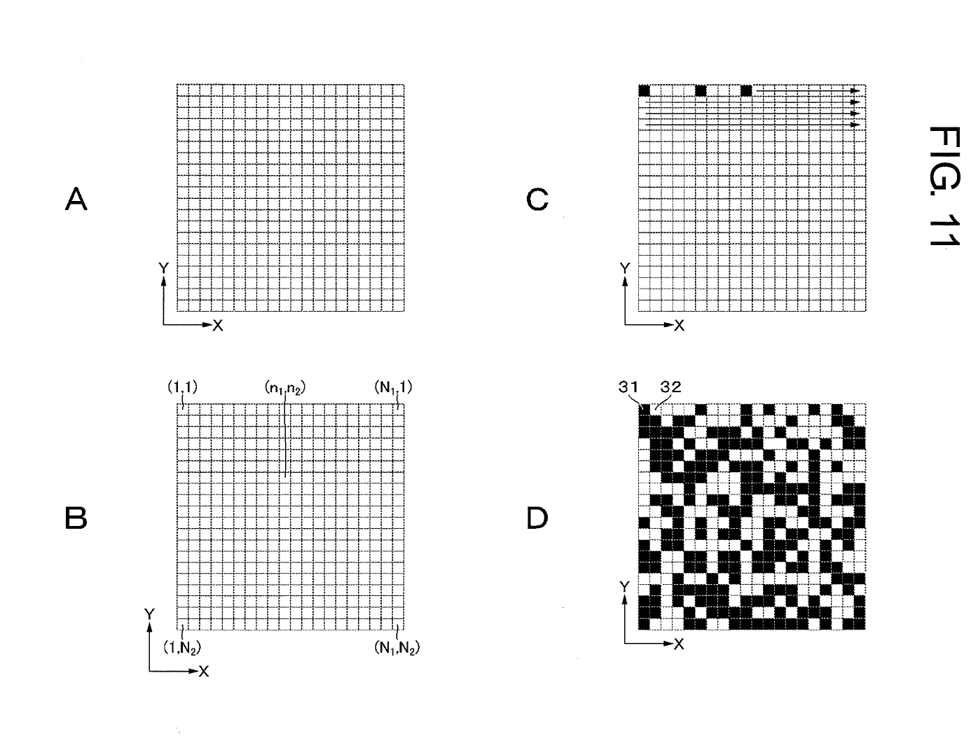

First, in step S1, the size of dots and the overall size are set. Then, in step S2, a grid formed by dividing the overall size into a unit of preset dot size is generated as shown in FIG. 11A. In the etching step described above, the etching solution is printed (painted) on the positions of respective dots in the grid, and hole elements 13a and 14a are thereby formed. The dots constituting the grid are rectangular. When the etching solution is printed (painted) using the inkjet printing method, the hole elements 13a and 14a are circular, substantially circular, elliptical, or substantially elliptical as described above, so that the shape of the dots constituting the grid is different from the shape of the hole elements 13a and 14a.

Next, in step S3, addresses (n₁, n₂) are set for the respective dots in the generated grid, as shown in FIG. 11B. As employed herein, n₁ is an address in a row direction (the X-axis direction (the first direction)), and n₂ is an address in a column direction (the Y-axis direction (the second direction)). Next, in step S4, the ratio p of dots forming hole elements is set. Then, in step S5, the address (n₁, n₂) is set to an initial address (1, 1). The ratio p of dots is a value of 0 or more and 100 or less. In the following description, “%” may be added to the ratio p of dots.

As employed herein, the ratio p of the dots forming hole elements refers to the ratio of the number of dots forming the hole elements to the total number of dots constituting the overall size (i.e., the ratio of dots on which the etching solution is printed (painted)). The ratio p of the dots forming hole elements corresponds to the above-described average ratio P1 of hole elements 13a and to the above-described average ratio P2 of hole elements 14a. When a random pattern for forming a transparent electrode portion 13 is generated, the ratio p of dots is preferably set within the range of p≦50[%], more preferably p≦40[%], and still more preferably p [%]. When a random pattern for forming a transparent insulating portion 14 is generated, the ratio p of dots is preferably set within the range of 50[%]<p and more preferably 60[%]<p.

The difference Δp (=p2−p1) between the ratio p1 of dots in the random pattern for forming the transparent electrode portion 13 and the ratio p2 of dots in the random pattern for forming the transparent insulating portion 14 is preferably set within the range of Δp≦30[%], more preferably Δp≦20[%], and still more preferably Δp≦10[%].

Next, in step S6, a uniform random number Nr of 0 or larger and 100 or less is generated for a dot at the address (n₁, n₂) set in step S5, S12, or S13 (this address is hereinafter referred to as a “set address”). For example, a Mersenne twister (MT) algorithm can be used as the algorithm for generating the random number Nr. Next, in step S7, a determination is made as to whether or not the random number Nr generated in step S6 is equal to or less than the ratio p of dots set in step S4 (Nr p).

TABLE 2 shows the relationship between the random number Nr and printing information (binary information).

TABLE 2

| Random number | Print information |
|---|---|
| 0.34817 | Printing (black) |
| 0.45484 | Printing (black) |
| 0.49999 | Printing (black) |
| 0.5 | Printing (black) |
| 0.63743 | Non-printing (white) |

If the random number Nr is equal to or less than the ratio p of dots, the dot at the set address (n₁, n₂) is set to printing in step S8, as shown in FIG. 11C. If the random number Nr is larger than the ratio p of dots forming hole elements, the dot at the set address (n₁, n₂) is set to nonprinting (hereinafter referred to as “non-printing”) in step S9, as shown in FIG. 11C.

In the example shown in FIG. 11C, dots with a setting of “printing” are represented by “black dots,” and dots with a setting of “non-printing” are represented by “white dots.” In the example shown in FIG. 11C, printing information (binary information of “printing” or “non-printing”) is set for each of the dots in the order shown by arrows. However, this setting order is only an example, and the order of setting the printing information is not limited to this example.

Next, in step S10, a determination is made as to whether or not the address n₁ is equal to a maximum address value N₁ in a row direction. If the address n₁ is equal to the maximum value N₁, the process proceeds to step S11. If the address n₁ is not equal to the maximum value N₁, the address n₁ is incremented in step S12, and the process returns to step S6.

In step S11, a determination is made as to whether or not the address n₂ is equal to a maximum address value N₂ in a column direction. If the address n₂ is not equal to the maximum value N₂, the address n₂ is incremented in step S13, and the process returns to step S6. If the address n₂ is equal to the maximum value N₂, the printing information (binary information) has been set for all the dots constituting the grid, and a raster image including white dots 32 and black dots 31 arranged in a random pattern is completed as shown in FIG. 11D. Then the process proceeds to step S14. Next, in step S14, the raster image (binary image) may be stored in the storage unit.

In the etching step described above, the raster image is read from the storage unit. Then, while a nozzle of an inkjet head is moved sequentially to the positions on the transparent conductive layer 12 that correspond to the respective dots in the raster image, the etching solution is ejected from the inkjet head according to the printing information for the raster image.

More specifically, the etching solution is ejected from the inkjet head at the positions on the transparent conductive layer 12 that correspond to the dots in the raster image set to “printing” (for example, “black dots 31”). However, the etching solution is not ejected from the inkjet head at the positions on the transparent conductive layer 12 that correspond to the dots in the raster image set to “non-printing” (for example, “white dots 32”). In this manner, an etching pattern corresponding to the random pattern of the white dots 32 and black dots 31 in the raster image is formed in the transparent conductive layer 12. In the above description of the example of the control of the movement of the inkjet head, the inkjet head is moved to all the printing and non-printing positions. However, the control of the movement of the inkjet head is not limited to this example. For example, the movement of the inkjet head may be controlled such that the inkjet head is moved sequentially only to the printing positions.

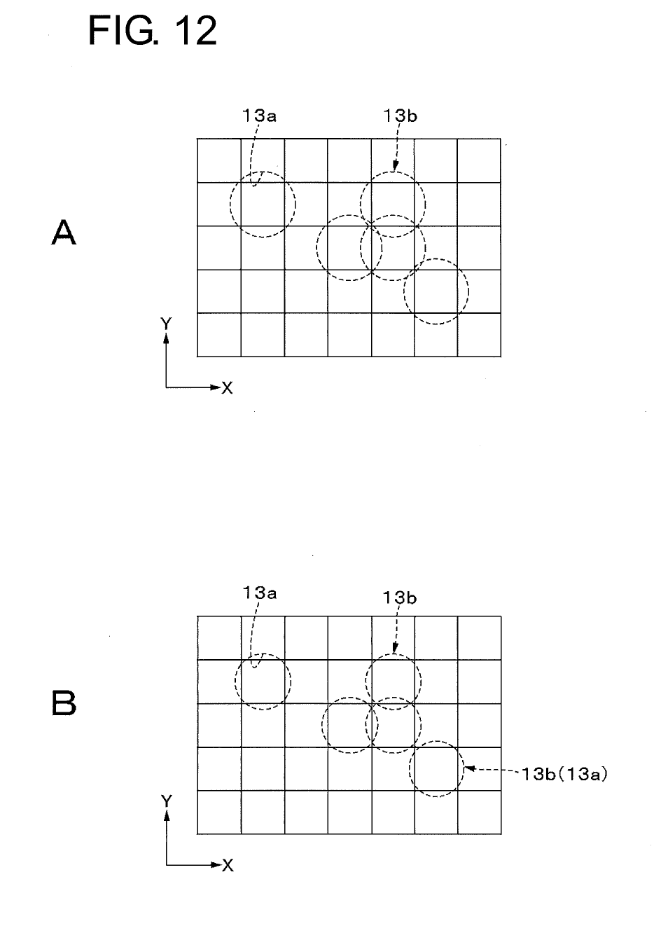

FIGS. 12A and 12B are schematic diagrams illustrating the relationship between dots (cells) constituting a grid and the size of hole elements. When the circumferences (for example, circular circumferences) of hole element's are located outside the corners of square dots as shown in FIG. 12A, not only adjacent hole elements 13a in adjacent rows that are adjacent to each other in the X-axis or Y-axis direction but also adjacent hole elements 13a in adjacent rows that are adjacent to each other in a direction diagonal to the X-axis or Y-axis direction are connected to each other to form one hole portion 13b. However, when the circumferences (for example, circular circumferences) of hole elements are located inside the corners of square dots as shown in FIG. 12B, adjacent hole elements 13a in adjacent rows that are adjacent to each other in a direction diagonal to the X-axis or Y-axis direction are not connected to each other, and separated hole portions 13b are thus formed.

### [Effects]

In the first embodiment, a plurality of hole elements 13a and a plurality of hole elements 14a are randomly arranged in the transparent conductive layer 12 two-dimensionally in the X- and Y-axis directions on the surface of the substrate. Therefore, the hole elements 13a and 14a can be easily produced by a printing method, in particular, an inkjet printing method.

By connecting hole elements 14a adjacent in the X-axis direction to each other and hole elements 14a adjacent in the Y-axis direction to each other, electric paths in the transparent conductive layer 12 are cut, so that the transparent conductive layer 12 is allowed to function as the transparent insulating portions 14.

Since the transparent electrode portions 13 and the transparent insulating portions 14 are alternately provided in a planar manner on the surface of the substrate, the difference between the reflectance of the first regions R₁ having the transparent electrode portions 13 formed therein and the reflectance of the second regions R₂ having no transparent electrode portions 13 can be reduced. Since hole elements 13a are provided also in the transparent electrode portions 13, the difference between the reflectance of the first regions R₁ and the reflectance of the second regions R₂ can be further reduced. Therefore, visual recognition of the pattern of the transparent electrode portions 13 can be suppressed.

When a random pattern is formed using a raster image, the random pattern formed is suitable for a printing method, in particular, an inkjet printing method. Inkjet printing is on-demand printing. Therefore, it is not necessary to produce a plate, and feedback such as prototype design can be easily provided. The inkjet printing method is suitable for production of small batches of a variety of products and is preferably used for applications of touch panels for mobile device products that are being frequently modified.

### (Modifications)

Modifications of the first embodiment will next be described.

### (Hard Coating Layer)

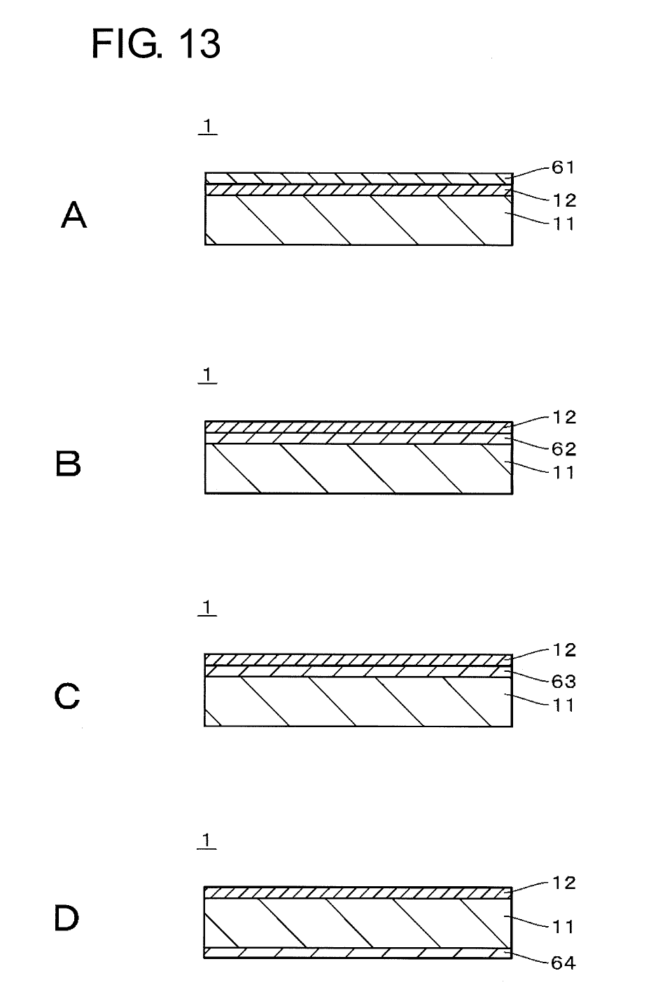

A hard coating layer 61 may be disposed on at least one of opposite surfaces of the first transparent conductive element 1, as shown in FIG. 13A. In this case, when the substrate 11 used is a plastic substrate, the substrate 11 is prevented from being scratched during production, and chemical resistance can be imparted. In addition, precipitation of low-molecular weight materials such as oligomers can be suppressed. The hard coating material used is preferably an ionizing radiation curable resin that is cured by light, an electron beam, etc. or a thermosetting resin that is cured by heat and is most preferably a photosensitive resin that is cured by ultraviolet rays. Examples of the photosensitive resin used may include acrylate-based resins such as urethane acrylate, epoxy acrylate, polyester acrylate, polyol acrylate, polyether acrylate, and melamine acrylate. For example, a urethane acrylate resin is obtained by reacting polyester polyol with an isocyanate monomer or prepolymer and reacting the obtained product with an acrylate or methacrylate-based monomer having a hydroxyl group. The thickness of the hard coating layer 61 is preferably 1 μm to 20 μm but is not particularly limited to this range.

The hard coating layer 61 is formed as follows. First, a hard coating paint is applied to the surface of the substrate 11. No particular limitation is imposed on the method of application, and any known application method can be used. Examples of the known application method may include a micro-gravure coating method, a wire bar coating method, a direct gravure coating method, a die coating method, a dipping method, a spray coating method, a reverse roll coating method, a curtain coating method, a comma coating method, a knife coating method, and a spin coating method. The hard coating paint contains, for example, a raw resin material such as a monomer and/or oligomer having at least two functional groups, a photopolymerization initiator, and a solvent. Next, if necessary, the hard coating paint applied to the surface of the substrate 11 is dried to volatilize the solvent. Next, the hard coating paint on the surface of the substrate 11 is cured by irradiation with ionizing radiation or heat. A hard coating layer 61 may be provided on at least one of opposite surfaces of the second transparent conductive element 2 in the same manner as that for the first transparent conductive element 1 described above.

### (Optical Adjustment Layer)

It is preferable to interpose an optical adjustment layer 62 between the substrate 11 and the transparent conductive layer 12 in the first transparent conductive element 1, as shown in FIG. 13B. This can assist non-visibility of the pattern shape of the transparent electrode portions 13. The optical adjustment layer 62 is formed from, for example, a stack of at least two layers having different refractive indexes, and the transparent conductive layer 12 is formed on the layer with a lower refractive index. More specifically, for example, any known conventional optical adjustment layer may be used as the optical adjustment layer 62. For example, any of optical adjustment layers described in Japanese Patent Application Laid-Open Nos. 2008-98169, 2010-15861, 2010-23282, and 2010-27294 may be used as the optical adjustment layer. An optical adjustment layer 62 may be interposed between the substrate 21 and the transparent conductive layer 22 in the second transparent conductive element 2 in the same manner as that for the first transparent conductive element 1 described above.

### (Adhesion Assisting Layer)

It is preferable to provide an adhesion assisting layer 63 as a primary coating layer for the transparent conductive layer 12 in the first transparent conductive element 1, as shown in FIG. 13C. This can improve the adhesion of the transparent conductive layer 12 to the substrate 11. Examples of the material used for the adhesion assisting layer 63 may include polyacrylic-based resins, polyamide-based resins, polyamide-imide-based resins, polyester-based resins, and products obtained by hydrolysis and dehydration condensation of chlorides, peroxides, and alkoxides of metal elements.

Instead of using the adhesion assisting layer 63, the surface on which the transparent conductive layer 12 is to be provided may be subjected to discharge treatment by applying glow discharge or corona discharge. A chemical treatment method including treatment with an acid or alkali may be applied to the surface on which the transparent conductive layer 12 is to be provided. After the transparent conductive layer 12 is provided, calender treatment may be performed to improve adhesion. An adhesion assisting layer 63 may be provided in the second transparent conductive element 2 in the same manner as that for the first transparent conductive element 1 described above. The above-described treatment for improving adhesion may also be performed.

### (Shielding Layer)

It is preferable to provide a shielding layer 64 in the first transparent conductive element 1, as shown in FIG. 13D. For example, a film including the shielding layer 64 may be laminated onto the first transparent conductive element 1 through a transparent adhesive layer. When the X electrodes and the Y electrodes are formed on the same side of a substrate 11, the shielding layer 64 may be formed directly on the opposite side. The same material as the material of the transparent conductive layer 12 may be used as the material of the shielding layer 64. The same formation method as that for the transparent conductive layer 12 can be used to form the shielding layer 64. However, the shielding layer 64 is not patterned and is used as a layer formed over the entire surface of the substrate 11. By forming the shielding layer 64 in the first transparent conductive element 1, noise due to, for example, electromagnetic waves generated by the display device 4 can be reduced, so that the accuracy of position detection in the information input device 10 can be improved. A shielding layer 64 may be provided in the second transparent conductive element 2 in the same manner as that for the first transparent conductive element 1 described above.

### (Antireflection Layer)

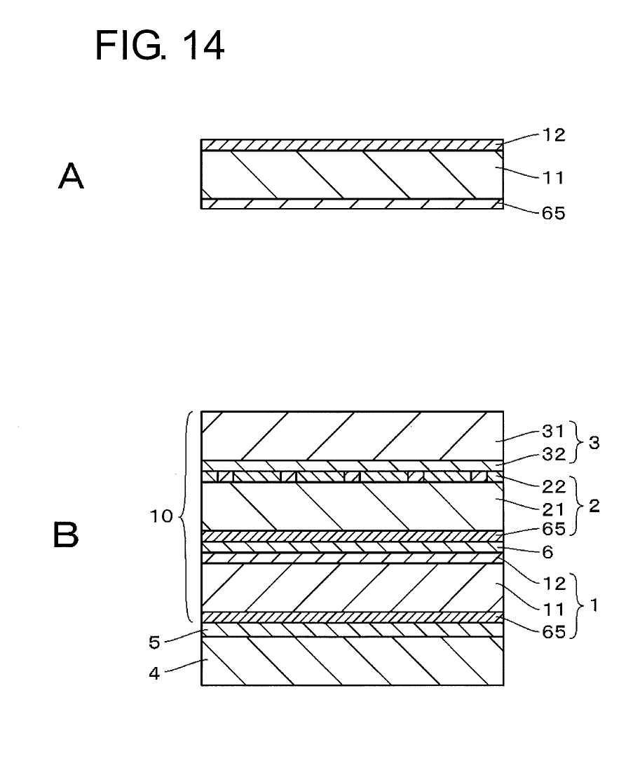

It is preferable to further provide an antireflection layer 65 in the first transparent conductive element 1, as shown in FIG. 14A. The antireflection layer 65 is provided, for example, on one of the principal surfaces of the first transparent conductive element 1, i.e., on a principal surface opposite to the principal surface on which the transparent conductive layer 12 is provided.

For example, a low-refractive index layer or a moth-eye structure may be used as the antireflection layer 65. When a low-refractive index layer is used as the antireflection layer 65, a hard coating layer may be further provided between the substrate 11 and the antireflection layer 65. An antireflection layer 65 may be further provided in the second transparent conductive element 2 in the same manner as that for the first transparent conductive element 1 described above.

FIG. 14B is a cross-sectional view illustrating an application example of a first transparent conductive element including an antireflection layer 65 and a second transparent conductive element including an antireflection layer 65. As shown in FIG. 14B, the first transparent conductive element 1 and the second transparent conductive element 2 are disposed on the display device 4 such that their principal surfaces on which the antireflection layers 65 are provided face the display surface of a display device 4. With the above configuration, transmittance of light through the display surface of the display device 4 can be improved, and the display performance of the display device 4 can be improved.

### 2. Second Embodiment

### [Configuration of Transparent Conductive Element]

### (Transparent Electrode Portions and Transparent Insulating Portions)

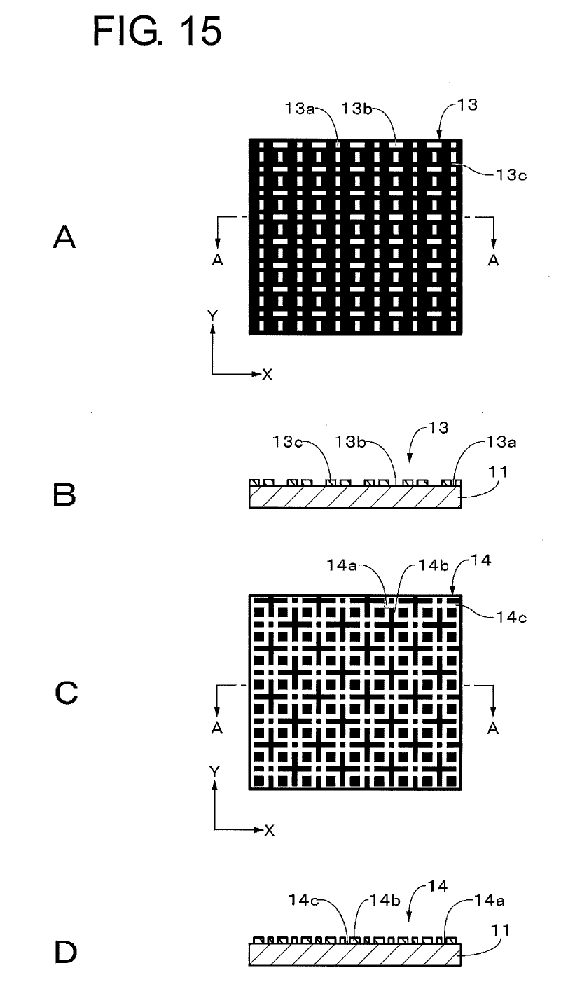

FIG. 15A is a plan view illustrating a configuration example of transparent electrode portions of a first transparent conductive element. FIG. 15B is a cross-sectional view taken along line A-A shown in FIG. 15A. Each transparent electrode portion 13 is a transparent conductive layer 12 that is formed such that a plurality of hole elements 13a are regularly arranged two-dimensionally in X-axis and Y-axis directions on the surface of a substrate 11. Adjacent hole elements in adjacent rows that are adjacent in the X-axis direction are connected to each other, and adjacent hole elements in adjacent rows that are adjacent in the Y-axis direction are connected to each other.

More specifically, each transparent electrode portion 13 is the transparent conductive layer 12 including a plurality of hole portions 13b regularly formed so as to be separated from each other, and a transparent conductive portion 13c is interposed between adjacent hole portions 13b. Each hole portion 13b is formed of one hole element 13a or a plurality of connected hole elements 13a. The hole portions 13b have regularly varying shapes on the surface of the substrate 11.

FIG. 15C is a plan view illustrating a configuration example of transparent insulating portions of the first transparent conductive element. FIG. 15D is a cross-sectional view taken along line A-A shown in FIG. 15C. Each transparent insulating portion 14 is a transparent conductive layer that is formed such that a plurality of hole elements 14a are regularly arranged two-dimensionally in the X-axis and Y-axis directions on the surface of the substrate 11. Adjacent hole elements in adjacent rows that are adjacent in the X-axis direction are connected to each other, and adjacent hole elements in adjacent rows that are adjacent in the Y-axis direction are connected to each other.

More specifically, each transparent insulating portion 14 includes a plurality of island portions 14b spaced apart from each other through separation portions 14c. Each separation portion 14c is formed of one hole element 14a or a plurality of connected hole elements 14a. The island portions 14b have regularly varying shapes on the surface of the substrate 11.

### (Boundary Portion)

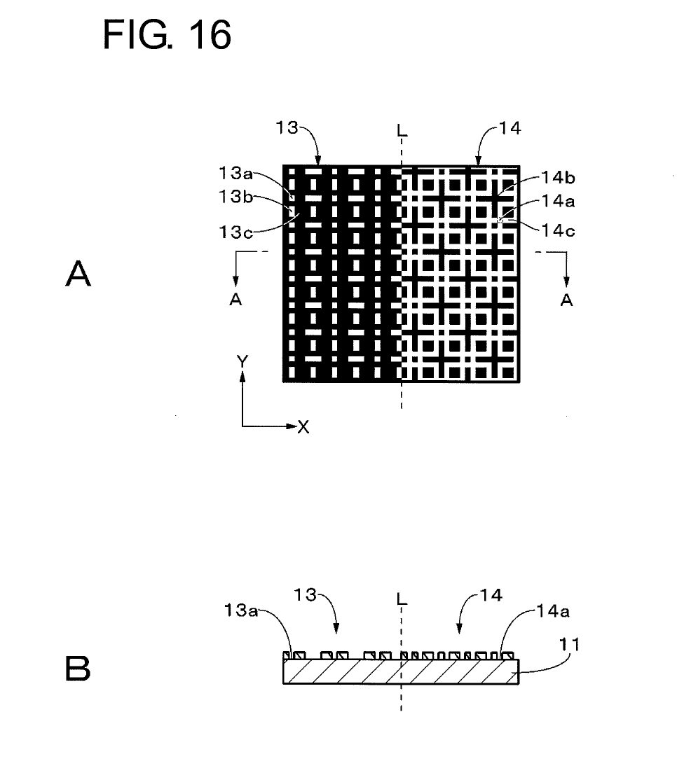

FIG. 16A is a plan view illustrating an example of a shape pattern in a boundary portion. FIG. 16B is a cross-sectional view taken along line A-A shown in FIG. 16A. Preferably, a regular shape pattern is provided at boundary portions between the transparent electrode portions 13 and the transparent insulating portions 14. When such a regular shape pattern is provided at each boundary portion, visual recognition of the boundary portion can be suppressed.

Preferably, in each of the boundary portions between the transparent electrode portions 13 and the transparent insulating portions 14, hole elements 13a and hole elements 14a are regularly arranged in the extending direction of the boundary portion. The arrangement of hole elements 13a and hole elements 14a in each boundary portion is not limited to the regular arrangement. The hole elements 13a and the hole elements 14a may be arranged randomly only in the boundary portion.

### [Method for Manufacturing Transparent Conductive Element]

The method for manufacturing the transparent conductive element is the same as that in the first embodiment described above except that the etching solution is printed (painted) according to a regular pattern generated in advance. The regular pattern is stored in the storage unit in advance, for example, as a raster image including white dots and black dots arranged in the regular pattern, and the etching solution is printed (painted) according to this raster image.

The second embodiment is the same as the first embodiment except for those described above.

### 3. Third Embodiment

### [Configuration of Transparent Conductive Element]

### (Transparent Electrode Portions and Transparent Insulating Portions)

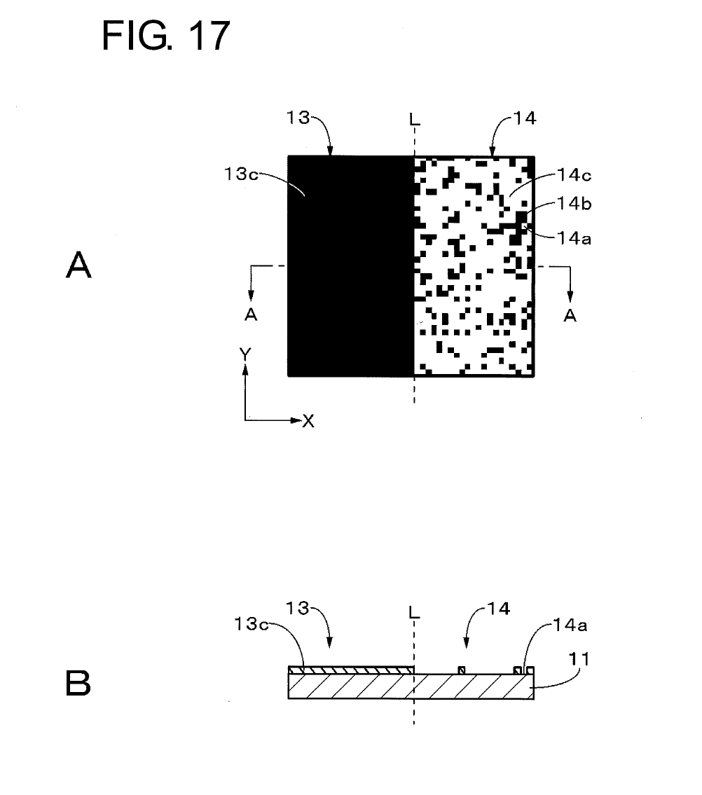

FIG. 17A is a plan view illustrating a configuration example of a first transparent conductive element. FIG. 17B is a cross-sectional view taken along line A-A shown in FIG. 17A. Each transparent electrode portion 13 is a transparent conductive layer 12 (a continuous film) that is continuously provided in a first region (electrode region) R₁ such that the surface of the substrate 11 is not exposed through hole elements 13a, as shown in FIGS. 17A and 17B. However, boundary portions between the first regions (electrode regions) R₁ and second regions (insulating regions) R₂ are excluded. Preferably, each continuous film in the transparent conductive layer 12 has a substantially uniform thickness. Transparent insulating portions 14 have a configuration similar to the configuration of the transparent insulating portions 14 in the first embodiment, as shown in FIGS. 17A and 17B.

### (Boundary Portion)

Preferably, a random shape pattern is provided at boundary portions between the transparent electrode portions 13 and the transparent insulating portions 14. When such a random shape pattern is provided at each boundary portion, visual recognition of the boundary portion can be suppressed.

Preferably, in each of the boundary portions between the transparent electrode portions 13 and the transparent insulating portions 14, hole elements 14a are randomly arranged in the extending direction of the boundary portion. When such an arrangement is employed, hole elements 14a are arranged, for example, so as to be in contact with the boundary L on the side of the transparent insulating portion 14 or so as to overlap the boundary L. The arrangement of hole elements 14a in each boundary portion is not limited to the random arrangement, and the hole elements 14a may be arranged regularly only in the boundary portion.

The third embodiment is the same as the first embodiment except for those described above.

### 4. Fourth Embodiment

### [Configuration of Transparent Conductive Element]

### (Transparent Electrode Portions and Transparent Insulating Portions)

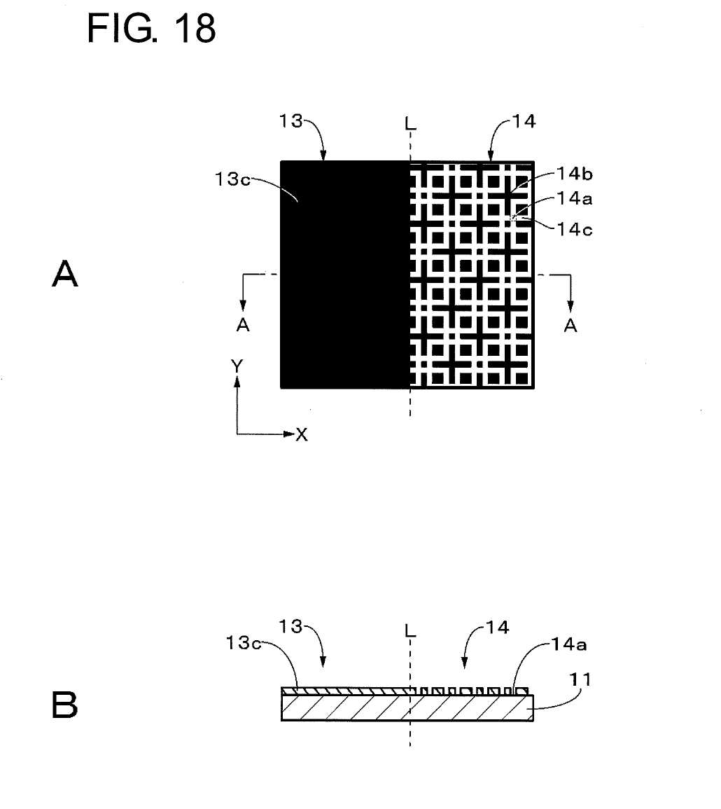

FIG. 18A is a plan view illustrating a configuration example of a first transparent conductive element. FIG. 18B is a cross-sectional view taken along line A-A shown in FIG. 18A. Transparent electrode portions 13 have the same configuration as that of the transparent electrode portions 13 in the third embodiment, as shown in FIGS. 18A and 18B. However, transparent insulating portions 14 have the same configuration as that of the transparent insulating portions 14 in the second embodiment, as shown in FIGS. 18A and 18B.

### (Boundary Portion)

Preferably, a regular shape pattern is provided at boundary portions between the transparent electrode portions 13 and the transparent insulating portions 14. When such a regular shape pattern is provided at each boundary portion, visual recognition of the boundary portion can be suppressed.

Preferably, in each of the boundary portions between the transparent electrode portions 13 and the transparent insulating portions 14, hole elements 14a are regularly arranged in the extending direction of the boundary portion. When such an arrangement is employed, hole elements 14a are arranged, for example, so as to be in contact with the boundary L on the side of the transparent insulating portion 14 or so as to overlap the boundary L. The arrangement of hole elements 14a in each boundary portion is not limited to the regular arrangement, and the hole elements 14a may be arranged randomly only in the boundary portion.

The fourth embodiment is the same as the second embodiment except for those described above.

### 5. Fifth Embodiment

### [Configuration of Transparent Conductive Element]

### (Transparent Electrode Portions and Transparent Insulating Portions)

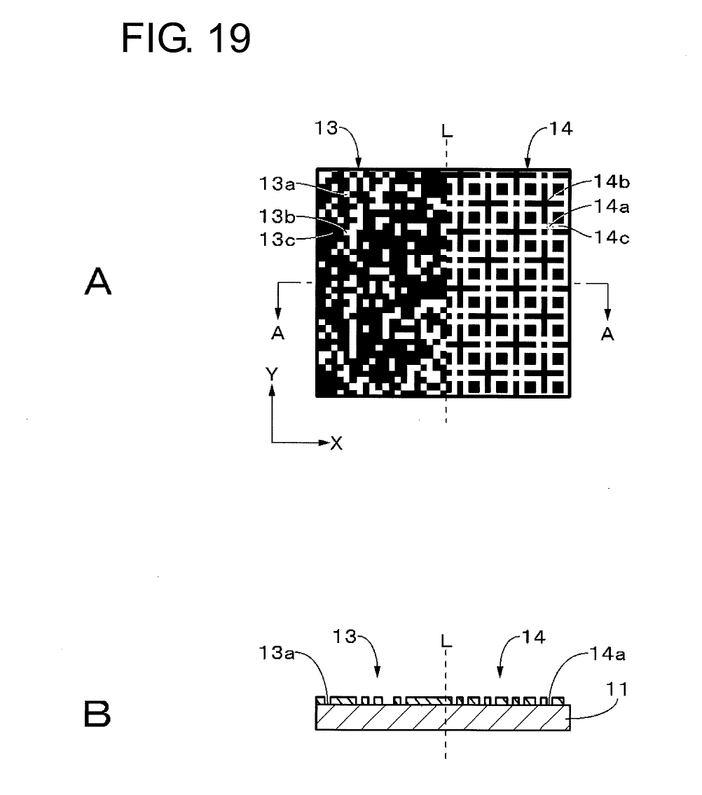

FIG. 19A is a plan view illustrating a configuration example of a first transparent conductive element. FIG. 19B is a cross-sectional view taken along line A-A shown in FIG. 19A. Transparent electrode portions 13 have the same configuration as that of the transparent electrode portions 13 in the first embodiment, as shown in FIGS. 19A and 19B. However, transparent insulating portions 14 have the same configuration as that of the transparent insulating portions 14 in the second embodiment, as shown in FIGS. 19A and 19B.

### (Boundary Portion)

Preferably, a random shape pattern is provided at boundary portions between the transparent electrode portions 13 and the transparent insulating portions 14. When such a random shape pattern is provided at each boundary portion, visual recognition of the boundary portion can be suppressed.

Preferably, in each of the boundary portions between the transparent electrode portions 13 and the transparent insulating portions 14, hole elements 13a are randomly arranged in the extending direction of the boundary portion, and hole elements 14a are regularly arranged in the extending direction of the boundary portion. When such an arrangement is employed, hole elements 13a are arranged, for example, so as to be in contact with the boundary L on the side of the transparent electrode portion 13 or so as to overlap the boundary L. Hole elements 14a are arranged, for example, so as to be in contact with the boundary L on the side of the transparent insulating portion 14 or so as to overlap the boundary L.

The arrangement of hole elements 13a in each boundary portion is not limited to the random arrangement, and the hole elements 13a may be arranged regularly only in the boundary portion. The arrangement of the hole elements 14a in each boundary portion is not limited to the regular arrangement, and the hole elements 14a may be arranged randomly only in the boundary portion.

The fifth embodiment is the same as the first embodiment except for those described above.

### 6. Sixth Embodiment

### [Configuration of Transparent Conductive Element]

### (Transparent Electrode Portions and Transparent Insulating Portions)

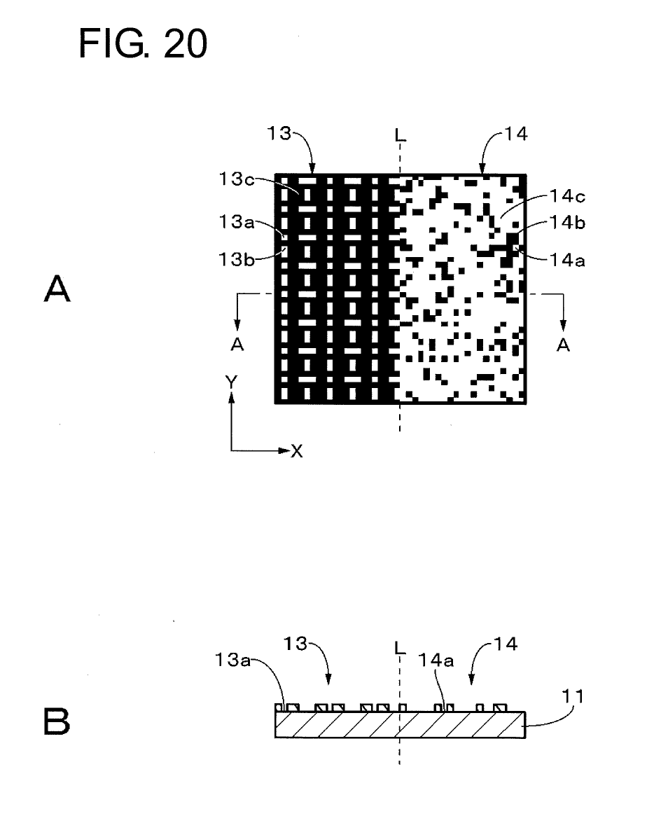

FIG. 20A is a plan view illustrating a configuration example of a first transparent conductive element. FIG. 20B is a cross-sectional view taken along line A-A shown in FIG. 20A. Transparent electrode portions 13 have the same configuration as that of the transparent electrode portions 13 in the second embodiment, as shown in FIGS. 20A and 20B. However, transparent insulating portions 14 have the same configuration as that of the transparent insulating portions 14 in the first embodiment, as shown in FIGS. 20A and 20B.

### (Boundary Portion)

Preferably, a random shape pattern is provided at boundary portions between the transparent electrode portions 13 and the transparent insulating portions 14. When such a random shape pattern is provided at each boundary portion, visual recognition of the boundary portion can be suppressed.

Preferably, in each of the boundary portions between the transparent electrode portions 13 and the transparent insulating portions 14, hole elements 13a are regularly arranged in the extending direction of the boundary portion, and hole elements 14a are randomly arranged in the extending direction of the boundary portion. When such an arrangement is employed, hole elements 13a are arranged, for example, so as to be in contact with the boundary L on the side of the transparent electrode portion 13 or so as to overlap the boundary L. Hole elements 14a are arranged, for example, so as to be in contact with the boundary L on the side of the transparent insulating portion 14 or so as to overlap the boundary L.

The arrangement of hole elements 13a in each boundary portions is not limited to the regular arrangement, and the hole elements 13a may be arranged randomly only in the boundary portion. The arrangement of hole elements 14a in each boundary portion is not limited to the random arrangement, and the hole elements 14a may be arranged regularly only in the boundary portion.

The sixth embodiment is the same as the first embodiment except for those described above.

### 7. Seventh Embodiment

The seventh embodiment is different from the first embodiment in that transparent conductive portions 13c in transparent electrode portions 13 and island portions 14b in transparent insulating portions 14 are formed from a plurality of conductive portion elements.

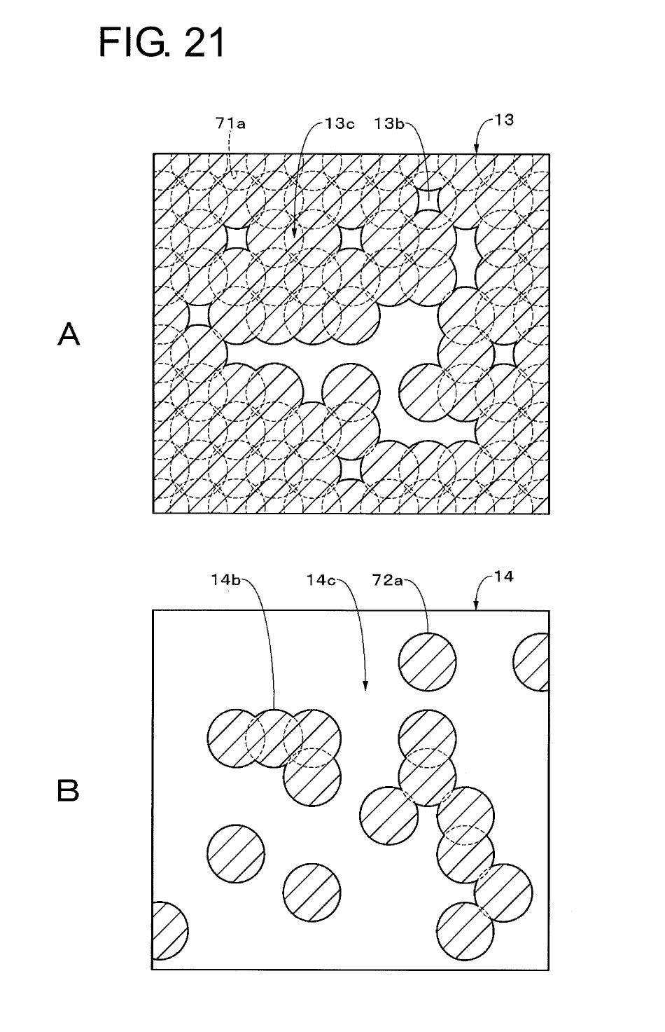

FIG. 21A is a plan view illustrating a configuration example of transparent electrode portions of a first transparent conductive element. Each transparent electrode portion 13 is a transparent conductive layer 12 that is formed such that a plurality of conductive portion elements 71a are randomly arranged two-dimensionally in X-axis and Y-axis directions on the surface of a substrate 11. By randomly forming the plurality of conductive portion elements 71a as described above, the occurrence of moiré can be suppressed. Adjacent conductive portion elements 71a in adjacent rows that are adjacent in the X-axis direction are connected to each other, and adjacent conductive portion elements 71a in adjacent rows that are adjacent in the Y-axis direction are connected to each other.

The plurality of conductive portion elements 71a are formed, for example, so as to be connected to or separated from each other in the X-axis direction. The plurality of conductive portion elements 71a are formed, for example, so as to be connected to or separated from each other in the Y-axis direction. The conductive portion elements 71a formed so as to be connected to or separated from each other described above form transparent conductive portions 13c of the transparent electrode portion 13. More specifically, each transparent conductive portion 13c is formed of one or a plurality of conductive portion elements 71a. Preferably, diagonally adjacent conductive portion elements 71a in adjacent rows that are adjacent in a direction diagonal to the X-axis or Y-axis direction are connected to each other. In this manner, even when the ratio of conductive portion elements 71a in the transparent electrode portions 13 is reduced in order to reduce the difference between the ratio of the area covered with the transparent conductive material in the transparent electrode portions 13 and the ratio of the area covered with the transparent conductive material in the transparent insulating portions 14, conductive paths diagonal to the X-axis or Y-axis direction can be secured. Specifically, low surface resistance can be maintained.

More specifically, each of the transparent electrode portions 13 is the transparent conductive layer 12 including a plurality of hole portions 13b randomly formed so as to be separated from each other, and a transparent conductive portion 13c is interposed between adjacent hole portions 13b. Each transparent conductive portion 13c is formed of one conductive portion element 71a or a plurality of connected conductive portion elements 71a. The hole portions 13b have randomly varying shapes on the surface of the substrate 11. The transparent conductive portions 13c are formed mainly of, for example, the transparent conductive material. The transparent conductive portions 13c provide electric conductivity of the transparent electrode portions 13.

FIG. 21B is a plan view illustrating a configuration example of the transparent insulating portions of the first transparent conductive element. Each transparent insulating portion 14 is a transparent conductive layer that is formed such that a plurality of conductive portion elements 72a are randomly arranged two-dimensionally in the X-axis and Y-axis directions on the surface of the substrate. By randomly forming the plurality of conductive portion elements 72a as described above, the occurrence of moiré can be suppressed. Adjacent conductive portion elements 72a in adjacent rows that are adjacent in the X-axis direction are connected to each other, and adjacent conductive portion elements 72a in adjacent rows that are adjacent in the Y-axis direction are connected to each other.

The plurality of conductive portion elements 72a are formed, for example, so as to be connected to or separated from each other in the X-axis direction. The plurality of conductive portion elements 72a are formed, for example, so as to be connected to or separated from each other in the Y-axis direction. The conductive portion elements 72a formed so as to be connected to or separated from each other as described above form island portions 14b of the transparent insulating portion 14. Preferably, diagonally adjacent conductive portion elements 72a in adjacent rows that are adjacent in a direction diagonal to the X-axis or Y-axis direction are separated from each other. In this manner, even when the ratio of conductive portion elements 72a in the transparent insulating portions 14 is increased in order to reduce the difference between the ratio of the area covered with the transparent conductive material in the transparent electrode portions 13 and the ratio of the area covered with the transparent conductive material in the transparent insulating portions 14, the number of conductive paths diagonal to the X-axis or Y-axis direction can be reduced. Specifically, high surface resistance can be maintained.

More specifically, each of the transparent insulating portions 14 includes a plurality of island portions 14b spaced apart from each other through separation portions 14c. The plurality of island portions 14b are formed in a random pattern on the surface of the substrate 11. Each island portion 14b is formed of one conductive portion element 72a or a plurality of connected conductive portion elements 72a. The island portions 14b are electrically insulated from each other through the separation portions 14c. The island portions 14b have randomly varying shapes on the surface of the substrate 11. The island portions 14b are formed mainly of, for example, the transparent conductive material.

FIGS. 21A and 21B show examples of the transparent electrode portions 13 and the transparent insulating portions 14 when the conductive portion elements 71a and 72a are formed using an inkjet printing method. When the conductive portion elements 71a and 72a are formed using the inkjet printing method, the shapes of the conductive portion elements 71a and 72a are, for example, circular, substantially circular, elliptical, or substantially elliptical.

Whether or not the inkjet printing method was used to form the conductive portion elements 71a and 72a can be determined as follows. The transparent electrode portions 13 and the transparent insulating portions 14 are observed, for example, under a microscope to determine whether or not the shapes of the conductive portion elements 71a and 72a include shapes such as circular arc, substantially circular arc, elliptical arc, and substantially elliptical arc shapes. When the shapes of the conductive portion elements 71a and 72a include any of these shapes, it is assumed that the conductive portion elements 71a and 72a were formed using the inkjet printing method.

The shapes of the conductive portion elements 71a and 72a may be, for example, dot shapes. The dot shapes may be, for example, circular, substantially circular, elliptical, or substantially elliptical shapes. The shape of the conductive portion elements 71a and the shape of the conductive portion elements 72a may be different from each other. As employed herein, the substantially circular shapes mean circular shapes obtained by adding some distortion to mathematically defined perfect circles (true circles). The substantially elliptical shapes mean elliptical shapes obtained by adding some distortion to mathematically defined perfect ellipses. The substantially elliptical shapes include, for example, oval shapes and egg-like shapes.

Preferably, the conductive portion elements 71a and the conductive portion elements 72a have visually unrecognizable sizes. The size of the conductive portion elements 71a may be different from the size of the conductive portion elements 72a.

The conductive portion elements 71a and 72a are formed by printing a conductive composition such as a conductive ink onto the surface of the substrate 11 and then drying and/or firing the conductive composition. The printing (painting) of the conductive composition is performed according to, for example, a random pattern produced in advance. An algorithm for generating the random pattern is the same as that in the first embodiment described above except that the ratio P of conductive portion elements is used instead of the ratio P of hole elements.

### (Boundary Portion)

Preferably, a random shape pattern is provided at boundary portions between the transparent electrode portions 13 and the transparent insulating portions 14. When such a random shape pattern is provided at each boundary portion, visual recognition of the boundary portion can be suppressed.

Preferably, in each of the boundary portions between the transparent electrode portions 13 and the transparent insulating portions 14, conductive portion elements 71a and conductive portion elements 72a are randomly arranged in the extending direction of the boundary portion. When such an arrangement is employed, conductive portion elements 71a are arranged, for example, so as to be in contact with the boundary L on the side of the transparent electrode portion 13 or so as to overlap the boundary L. Conductive portion elements 72a are arranged, for example, so as to be in contact with the boundary L on the side of the transparent insulating portion 14 or so as to overlap the boundary L.

The arrangement of conductive portion elements 71a and conductive portion elements 72a in each boundary portion is not limited to the random arrangement. The conductive portion elements 71a and the conductive portion elements 72a may be arranged regularly only in the boundary portion.

The seventh embodiment is the same as the first embodiment except for those described above.

In the examples in the seventh embodiment, the transparent conductive portions 13c in the transparent electrode portions 13 and the island portions 14b in the transparent insulating portions 14 in the first embodiment are formed from conductive portion elements 71a and conductive portion elements 72a, respectively. However, the present technique is not limited to these examples. For example, the transparent conductive portions 13c in the transparent electrode portions 13 and the island portions 14b in the transparent insulating portions 14 in the second to sixth embodiments may be formed from conductive portion elements 71a and conductive portion elements 72a, respectively.

### 8. Eighth Embodiment

The eighth embodiment is different from the first embodiment in that hole elements 13a and 14a with at least two sizes are provided. To form the hole elements 13a and 14a with at least two sizes, a grid with at least two dot sizes, for example, may be used.

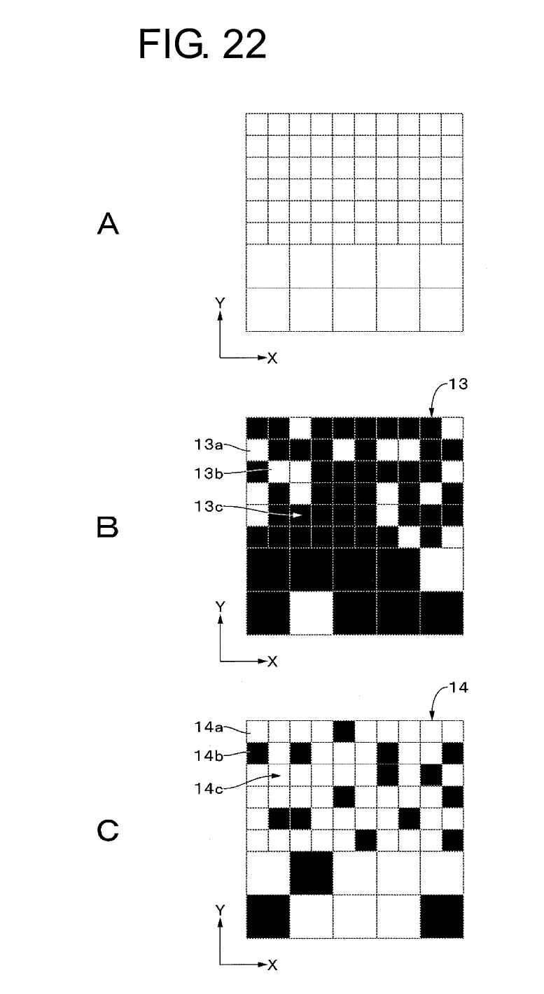

FIG. 22A shows an example of a grid with two dot sizes. FIGS. 22B and 22C show examples of a transparent electrode portion 13 and a transparent insulating portion 14 formed using this grid. These transparent electrode portion 13 and transparent insulating portion 14 include hole elements 13a and 14a with two sizes.

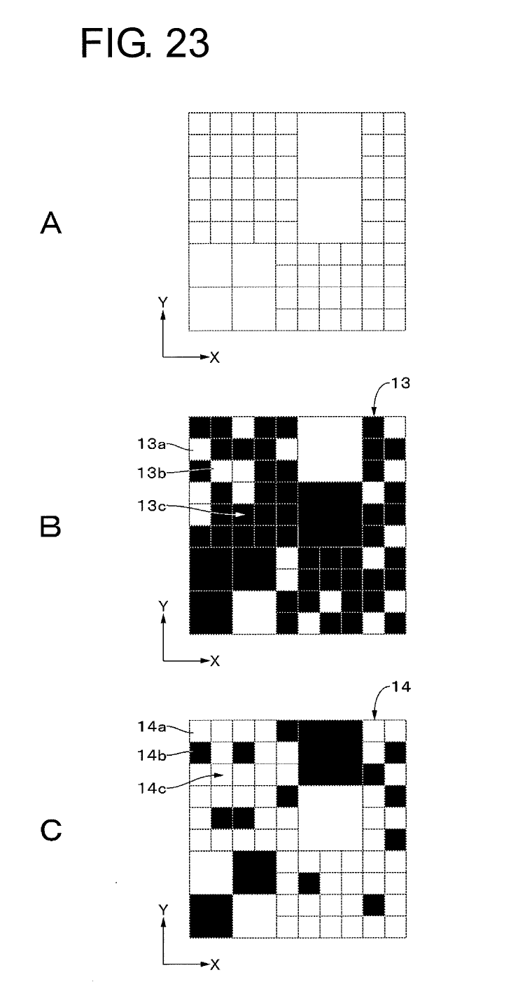

FIG. 23A shows an example of a grid with three dot sizes. FIGS. 23B and 23C show examples of a transparent electrode portion 13 and a transparent insulating portion 14 formed using this grid. These transparent electrode portion 13 and transparent insulating portion 14 include hole elements 13a and 14a with three sizes.

### 9. Ninth Embodiment

The ninth embodiment is different from the first embodiment in that the X-axis direction (the first direction) and the Y-axis direction (the second direction) are in a diagonally crossing relationship and hole elements 13a and 14a are randomly arranged two-dimensionally in the X- and Y-axis directions with such a relationship. To form the hole elements 13a and 14a in the diagonally crossing X-axis and Y-axis directions (first and second directions), a grid with a parallelogrammic dot shape, for example, may be used.

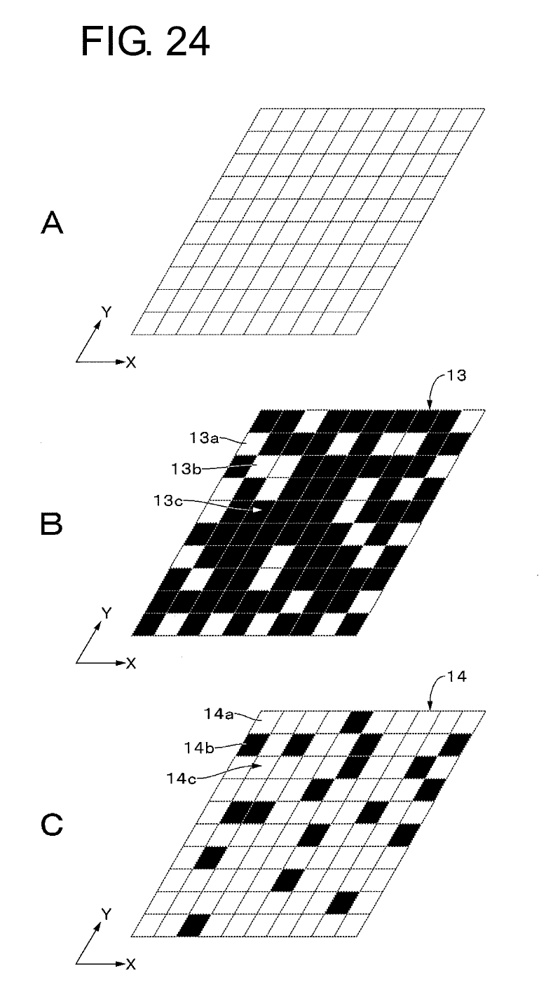

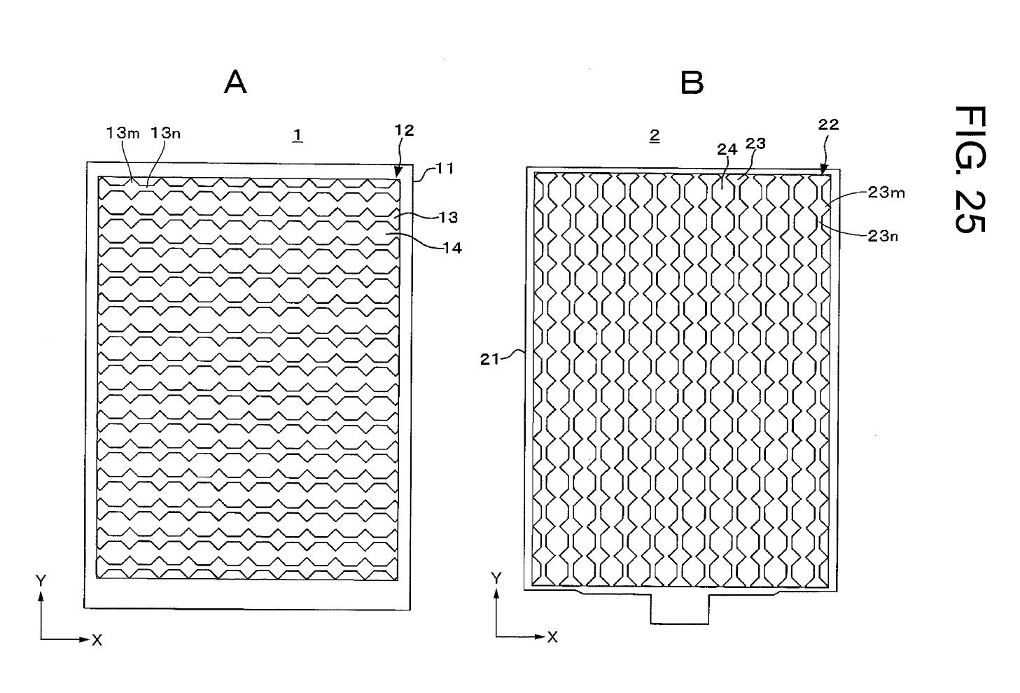

FIG. 24A shows an example of a grid with a parallelogrammic dot shape. FIGS. 24B and 24C show examples of a transparent electrode portion 13 and a transparent insulating portion 14 formed using this grid.

### 10. Tenth Embodiment

### [Configuration of Transparent Conductive Elements]

FIG. 25A is a plan view illustrating a configuration example of a first transparent conductive element according to the tenth embodiment of the present technique. FIG. 25B is a plan view illustrating a configuration example of a second transparent conductive element according to the tenth embodiment of the present technique. The tenth embodiment is the same as the first embodiment except for the configurations of the transparent electrode portions 13, the transparent insulating portions 14, the transparent electrode portions 23, and the transparent insulating portions 24.

Each transparent electrode portion 13 includes a plurality of pad sections (unit electrodes) 13m and a plurality of connection sections 13n that connect the plurality of pad sections 13m. The connection sections 13n extend in the X-axis direction to connect ends of adjacent pad sections 13m. The pad sections 13m and the connection sections 13n are integrally formed.

Each transparent electrode portion 23 includes a plurality of pad sections (unit electrodes) 23m and a plurality of connection sections 23n that connect the plurality of pad sections 23m. The connection sections 23n extend in the Y-axis direction to connect ends of adjacent pad sections 23m. The pad sections 23m and the connection sections 23n are integrally formed.

The shapes of the pad sections 13m and pad sections 23m used may be polygonal shapes such as rhombus (diamond) shapes or rectangular shapes, star shapes, or cross shapes but are not limited to these shapes.

Rectangular shapes may be used as the shapes of the connection sections 13n and connection sections 23n. However, the shapes of the connection sections 13n and connection sections 23n are not particularly limited to rectangular shapes, so long as they can connect adjacent pad sections 13m to each other and adjacent pad sections 23m to each other. Examples of the shapes other than the rectangular shapes may include linear, elliptical, triangular, and irregular shapes.

The tenth embodiment is the same as the first embodiment except for those described above.

### [Effects]

According to the tenth embodiment, the same effects as those in the first embodiment can be obtained.

### 11. Eleventh Embodiment

### [Configuration of Information Input Device]

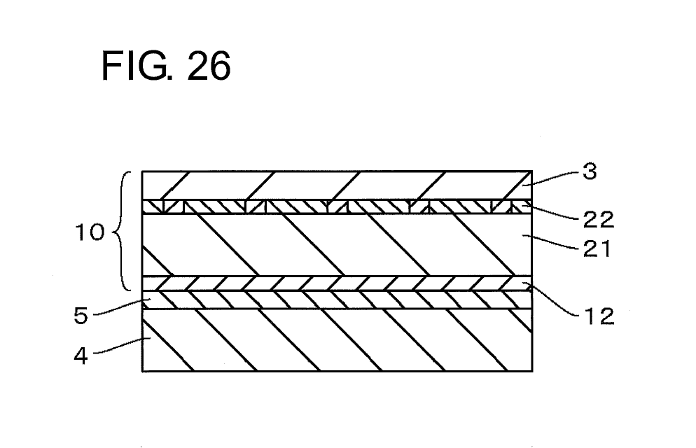

FIG. 26 is a cross-sectional view illustrating a configuration example of an information input device according to the eleventh embodiment of the present technique. The information input device 10 according to the eleventh embodiment is different from the information input device 10 according to the first embodiment in that the transparent conductive layer 12 is provided on one principal surface (first principal surface) of the substrate 21 and the transparent conductive layer 22 is provided on the other principal surface (second principal surface). The transparent conductive layer 12 includes transparent electrode portions and transparent insulating portions. The transparent conductive layer 22 includes transparent electrode portions and transparent insulating portions. The transparent electrode portions in the transparent conductive layer 12 are X electrode portions extending in the X-axis direction, and the transparent electrode portions in the transparent conductive layer 22 are Y electrode portions extending in the Y-axis direction. Therefore, the transparent electrode portion in the transparent conductive layer 12 and the transparent electrode portions in the transparent conductive layer 22 are orthogonal to each other.

The eleventh embodiment is the same as the first embodiment except for those described above.

### [Effects]

According to the eleventh embodiment, the following effects can be further obtained in addition to the effects in the first embodiment. Since the transparent conductive layer 12 is provided on one principal surface of the substrate 21 and the transparent conductive layer 22 is provided on the other principal surface, the substrate 11 (FIG. 1) in the first embodiment can be omitted. Therefore, the information input device 10 can be further reduced in thickness.

### 12. Twelfth Embodiment

### [Configuration of Information Input Device]

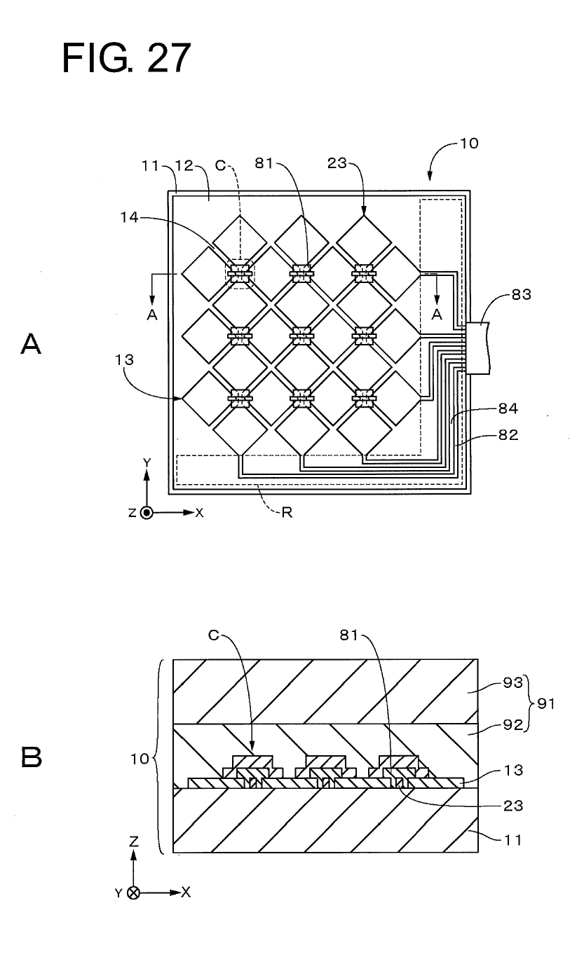

FIG. 27A is a plan view illustrating a configuration example of an information input device according to the twelfth embodiment of the present technique. FIG. 27B is a cross-sectional view taken along line A-A shown in FIG. 27A. The information input device 10 is a so-called projection type capacitive touch panel, and includes a substrate 11, a plurality of transparent electrode portions 13, a plurality of transparent electrode portions 23, transparent insulating portions 14, and a transparent insulating layer 81, as shown in FIGS. 27A and 27B. The plurality of transparent electrode portions 13 and the plurality of transparent electrode portions 23 are provided on the same surface of the substrate 11. The transparent insulating portions 14 are provided between the transparent electrode portions 13 and transparent electrode portions 23 in in-plane directions of the substrate 11. The transparent insulating layer 81 is disposed at the intersections of the transparent electrode portions 13 and the transparent electrode portions 23.

If necessary, an optical layer 91 may be further provided on the surface of the substrate 11 having the transparent electrode portions 13 and 23 formed thereon, as shown in FIG. 27B. In FIG. 27A, the optical layer 91 is omitted in the drawing. The optical layer 91 includes a bonding layer 92 and a base 93, and the base 93 is bonded to the surface of the substrate 11 through the bonding layer 92. The information input device 10 is suitably applied to the display surface of a display device. The substrate 11 and the optical layer 91 are transparent to, for example, visible light, and their refractive indexes n preferably fall within the range of 1.2 or more and 1.7 or less. In the following description, two mutually orthogonal directions in a plane of the surface of the information input device 10 are referred to as an X-axis direction and a Y-axis direction, and a direction perpendicular to the surface is referred to as a Z-axis direction.

### (Transparent Electrode Portions)

The transparent electrode portions 13 extend in the X-axis direction (first direction) on the surface of the substrate 11, and the transparent electrode portions 23 extend in the Y-axis direction (second direction) on the surface of the substrate 11. Therefore, the transparent electrode portions 13 and the transparent electrode portions 23 orthogonally cross each other. The transparent insulating layer 81 for insulating these electrodes from each other is disposed at intersecting portions C at which the transparent electrode portions 13 and the transparent electrode portions 23 cross each other.

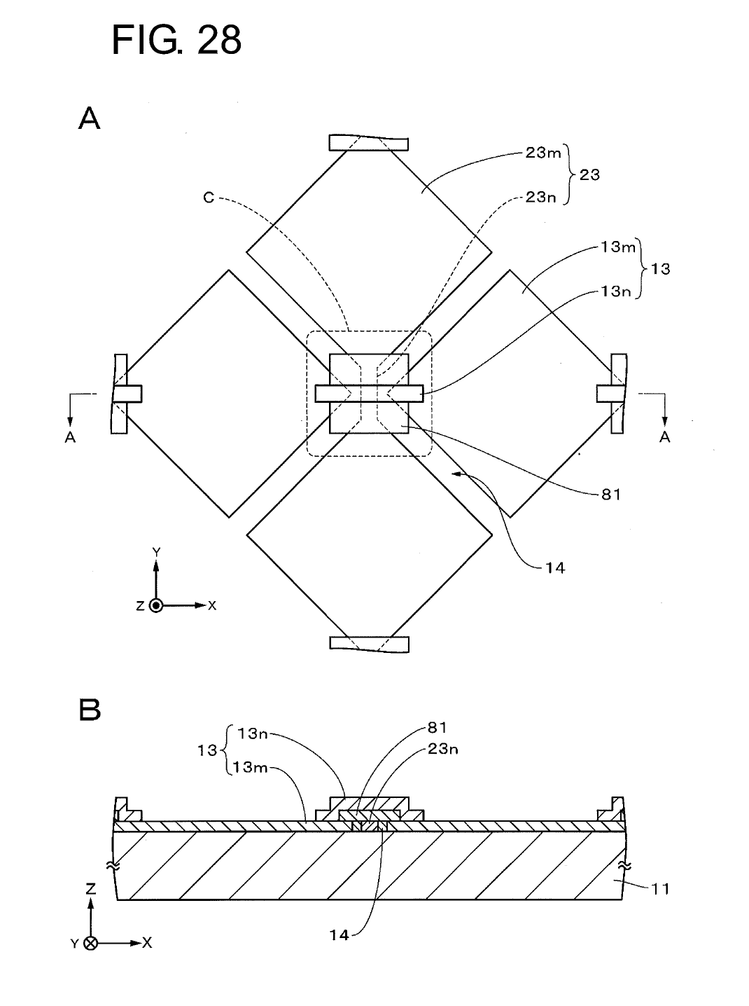

FIG. 28A is an enlarged plan view illustrating the vicinity of an intersecting portion C shown in FIG. 27A. FIG. 28B is a cross-sectional view taken along line A-A shown in FIG. 28A. Each transparent electrode portion 13 has a plurality of pad sections (unit electrodes) 13m and a plurality of connection sections 13n connecting the plurality of pad sections 13m. The connection sections 13n extend in the X-axis direction and connect ends of adjacent pad sections 13m. Each transparent electrode portion 23 has a plurality of pad sections (unit electrodes) 23m and a plurality of connection sections 23n connecting the plurality of pad sections 23m. The connection sections 23n extend in the Y-axis direction and connect ends of adjacent pad sections 23m.

At each intersecting portion C, a connection section 23n, the transparent insulating layer 81, and a connection section 13n are stacked in this order on the surface of the substrate 11. The connection section 13n is formed so as to cross and straddle the transparent insulating layer 81. One end of the connection section 13n that straddles the transparent insulating layer 81 is electrically connected to one of adjacent pad sections 13m, and the other end of the connection section 13n that straddles the transparent insulating layer 81 is electrically connected to the other one of the adjacent pad sections 13m.

The pad sections 23m and the connection sections 23n are integrally formed, but the pad sections 13m and the connection sections 13n are formed separately. The pad sections 13m, the pad sections 23m, the connection sections 23n, and the transparent insulating portions 14 are formed, for example, in a single transparent conductive layer 12 formed on the surface of the substrate 11. The connection sections 13n are formed, for example, from a conductive layer.

The shapes of the pad sections 13m and pad sections 23m used may be polygonal shapes such as rhombus shapes (diamond shape) or rectangular shapes, star shapes, or cross shapes but are not limited to these shapes.

For example, a metal layer or a transparent conductive layer can be used as the conductive layer forming the connection sections 13n. The metal layer contains a metal as a main component. The metal used is preferably a high electric conductivity metal, and examples of such a material may include Ag, Al, Cu, Ti, Nb, and impurity-doped Si. Of these, Ag is preferred in consideration of its high electric conductivity, depositability, and printability. It is preferable to use a high electric conductivity metal so that the connection sections 13n are reduced in width, thickness, and length. In this manner, visibility can be improved.

Rectangular shapes may be used as the shapes of the connection sections 13n and connection sections 23n. However, the shapes of the connection sections 13n and connection sections 23n are not particularly limited to rectangular shapes, so long as they can connect adjacent pad sections 13m to each other and adjacent pad sections 23m to each other. Examples of the shapes other than the rectangular shapes may include linear, elliptical, triangular, and irregular shapes.

### (Transparent Insulating Layer)

Preferably, at each of intersections at which the connection sections 13n and the connection section 23n cross each other, the transparent insulating layer 81 has an area larger than the area of the intersecting portion. For example, at each intersection, the transparent insulating layer 81 has a size that covers the ends of the pad sections 13m and 23m located in an intersecting portion C.

The transparent insulating layer 81 contains a transparent insulating material as a main component. The transparent insulating material used is preferably a transparent polymer material, and examples of such a material may include: (meth)acrylic-based resins such as copolymers of polymethyl methacrylate and methyl methacrylate with vinyl monomers such as other alkyl (meth)acrylates and styrene; polycarbonate-based resins such as polycarbonate and diethylene glycol bisallyl carbonate (CR-39); thermosetting (meth)acrylic-based resins such as a homopolymer and a copolymer of (brominated) bisphenol A type di(meth)acrylate and a polymer and a copolymer of a urethane-modified monomer of (brominated) bisphenol A type mono(meth)acrylate; polyesters, particularly polyethylene terephthalate, polyethylene naphthalate, and unsaturated polyesters; acrylonitrile-styrene copolymers; polyvinyl chloride; polyurethane; epoxy resin; polyarylate; polyether sulfone; polyether ketone; cycloolefin polymers (product names: ARTON and ZEONOR); and cycloolefin copolymers. An aramid-based resin with heat resistance taken into consideration can also be used. As employed herein, the (meth)acrylate means acrylate or methacrylate.

No particular limitation is imposed on the shape of the transparent insulating layer 81 so long as it is interposed between a transparent electrode portion 13 and a transparent electrode portion 23 at each intersecting portion C and can prevent these electrodes from coming into electric contact with each other. Examples of the shape may include polygonal shapes such as tetragonal shapes, ellipsoidal shapes, and circular shapes. Examples of the tetragonal shapes may include rectangular shapes, square shapes, rhombic shapes, trapezoidal shapes, parallelogrammic shapes, and rectangular shapes with corners having curvature R.

### (Traces)

Traces 82 are electrically connected to ends of the transparent electrode portions 13 and 23 as shown in a region R in FIG. 27A, and a driving circuit (not shown) is connected to these traces 82 through an FPC (Flexible Printed Circuit) 83. Insulating portions 84 having a shape such as a linear shape are provided between the traces 82, and adjacent traces 82 are insulated from each other through the insulating portions 84.

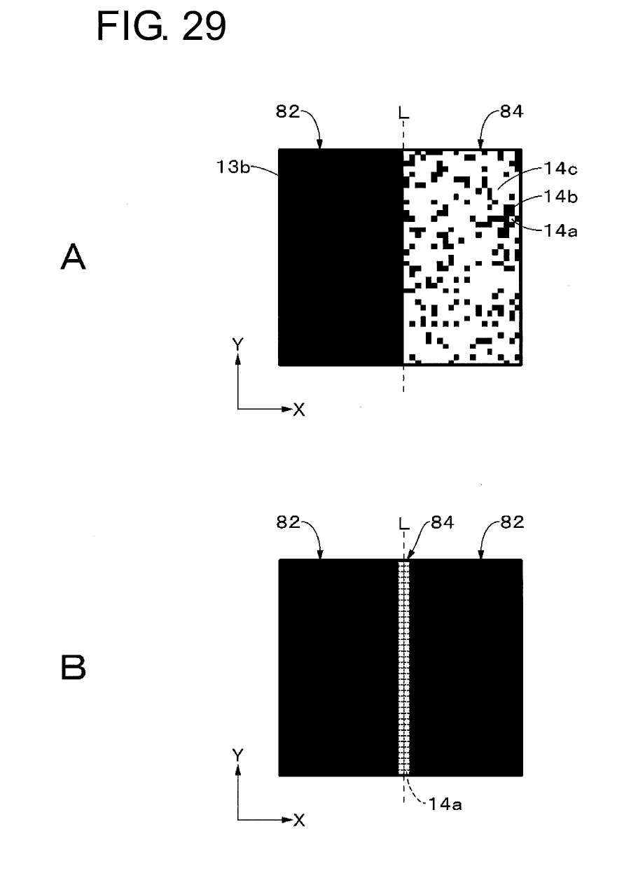

FIG. 29A is an enlarged plan view illustrating the region R shown in FIG. 27A. Each trace 82 is a conductive layer (a linear continuous film) that is provided continuously such that the surface of the substrate 11 is not exposed through hole portions, as shown in FIG. 29A. Preferably, each continuous film in the conductive layer has a substantially uniform thickness. The conductive layer contains a metal material or a transparent conductive material as a main component. The insulating portions 84 between the traces 82 have the same configuration as that of the transparent insulating portions 14 in the first embodiment described above except that island portions 14b contain a metal material or a transparent conductive material as a main component. Hole elements 14a in the insulating portions 84 can be formed using a printing method such as an inkjet printing method, as in the first embodiment described above.

Insulating portions 84 formed of one or at least two rows of hole elements 14a extending in the extending direction of the traces 82 may be formed between the traces 82, as shown in FIG. 29B. In this case, the hole elements 14a adjacent in the extending direction and a direction orthogonal to the extending direction are connected to each other. In this manner, the traces 82 are insulated from each other through the hole elements 14a. Preferably, the hole elements 14a adjacent in the extending direction and directions diagonal to the direction orthogonal to the extending direction are connected to each other. These hole elements 14a can also be formed using a printing method such as an inkjet printing method, as in the first embodiment described above.

The twelfth embodiment is the same as the first embodiment except for those described above.

### [Effects]

According to the twelfth embodiment, the following effects can be further obtained in addition to the effects in the first embodiment. Since the transparent electrode portions 13 and 23 are provided on one principal surface of the substrate 11, the substrate 21 (FIG. 1) in the first embodiment can be omitted. Therefore, the information input device 10 can be further reduced in thickness.

### 13. Thirteenth Embodiment

### (Application of Etching Solution Using Minute Droplet Application System)

To print (paint) the etching solution onto the transparent conductive layer 12 in any of the first to twelfth embodiments, an inkjet printing method, for example, is used. This can be replaced with the thirteenth embodiment of the present technique described below. An example of application of the etching solution using a minute droplet application system in the thirteenth embodiment of the present technique will next be described.

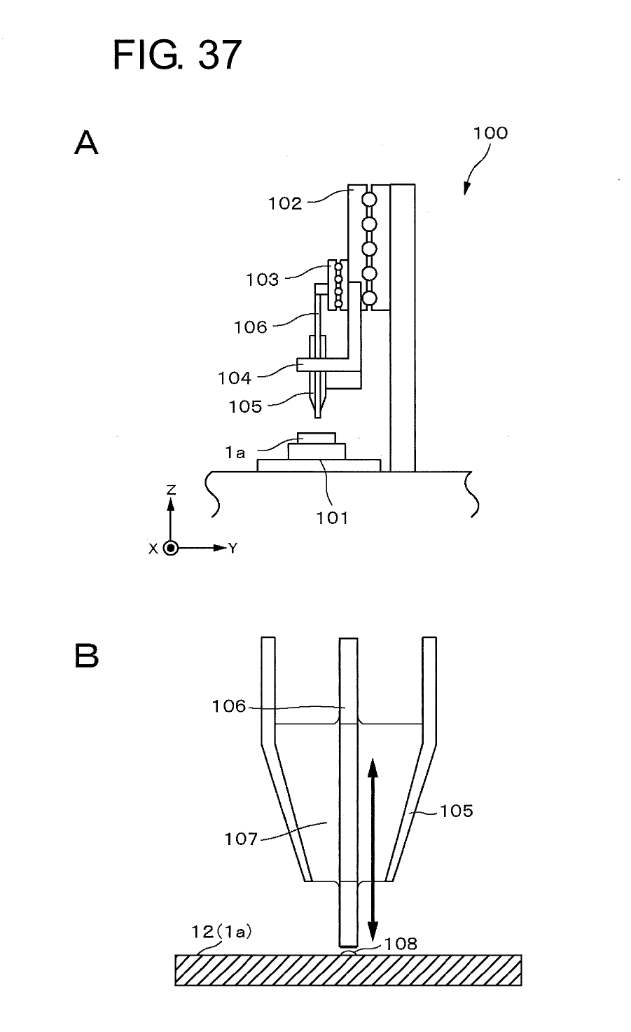

FIG. 37A is a schematic diagram illustrating a configuration example of a main body of the minute droplet application system. FIG. 37B is an enlarged schematic diagram illustrating a main part for liquid droplet application in FIG. 37A. The minute droplet application system used may be, for example, a needle type dispenser manufactured by Applied Micro Systems Inc. The needle type dispenser is described in, for example, Japanese Patent Application Laid-Open Nos. 2011-173029 and 2011-174907.

The main body 100 of the needle type dispenser includes an XY stage 101, a coarse adjustment stage 102, fine adjustment stage 103, a pipette holding member 104, a glass pipette (reservoir) 105, and an application needle 106. The coarse adjustment stage 102 and the fine adjustment stage 103 form a Z stage (Z-axis actuator). The minimum resolution of the Z stage is 0.25 [μm], and the accuracy of the repeated positioning falls within ±0.3 [μm]. The main body 100 of the needle type dispenser is controlled by an unillustrated controller.

A transparent conductive substrate 1a to which the etching solution is to be applied in placed on the XY stage 101. The transparent conductive substrate 1a includes a transparent conductive layer 12 deposited on the surface of a substrate 11. FIG. 37B shows only the vicinity of the transparent conductive layer 12 in the transparent conductive substrate 1a. The XY stage 101 moves the transparent conductive substrate 1a placed on its upper surface in the X-axis direction and the Y-axis direction. An XY position on the transparent conductive layer 12 to which the etching solution is to be applied can thereby be determined. The minimum resolution of the XY stage 101 is 0.25 [μm], and the accuracy of the repeated positioning falls within ±0.3

The fine adjustment stage 103 and the pipette holding member 104 are attached to the coarse adjustment stage 102. The coarse adjustment stage 102 slides coarsely in a direction toward or away from the surface of the transparent conductive substrate 1a, which is the application target, i.e., in the Z-axis direction. Therefore, the fine adjustment stage 103 and the pipette holding member 104 slide in the Z-axis direction together with the sliding of the coarse adjustment stage 102. The pipette holding member 104 holds the glass pipette 105. The glass pipette 105 is a hollow structure and extends in the Z-axis direction. Therefore, the glass pipette 105 slides in the Z-axis direction, which is the extending direction of the glass pipette 105, together with the sliding of the coarse adjustment stage 102 in the Z-axis direction.

The fine adjustment stage 103 slides in the Z-axis direction finely. The application needle 106 extending in the Z-axis direction is attached to the fine adjustment stage 103. Therefore, the application needle 106 can be finely moved in the Z-axis direction together with the sliding of the fine adjustment stage 103 in the Z-axis direction.

Glass, for example, is used for the glass pipette 105. The tip end of the glass pipette 105 faces the surface of the application target. The inner diameter of the tip end of the glass pipette 105 is, for example, 200 [μm]. The glass pipette 105 having a hollow structure is filled with an application liquid 107. The surface tension of the application liquid 107 causes it to be held inside the glass pipette 105. Tungsten, for example, is used for the application needle 106. The application needle 106 moves in the Z-axis direction so as to pass through the glass pipette 105. The end of the application needle 106 faces the surface of the application target. When the application needle 106 passes through the glass pipette 105, a liquid droplet adhering to the tip end of the application needle 106 adheres to the surface of the transparent conductive layer 12 serving as the application target, and a liquid droplet 108 is thereby formed on the transparent conductive layer 12. The application needle 106 is configured to be replaceable, and any of application needles 106 having tip ends with diameters of, for example, 10 [μm] and 100 [μm] can be selected. Specifically, a suitable application needle 106 can be selected according to the desired dot diameter.

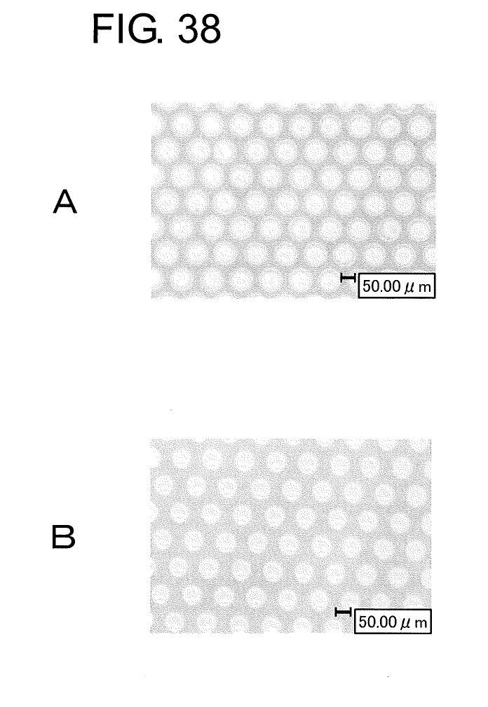

FIGS. 38A and 38B show examples of the etching solution applied using the minute droplet application system according to the thirteenth embodiment of the present technique. In FIG. 38A, the diameter of the tip end of the application needle 106 is 50 [μm]. In FIG. 38B, the diameter of the tip end of the application needle 106 is 30 [μm]. As described above, the amount of application can be adjusted by changing the diameter of the tip end of the application needle 106.

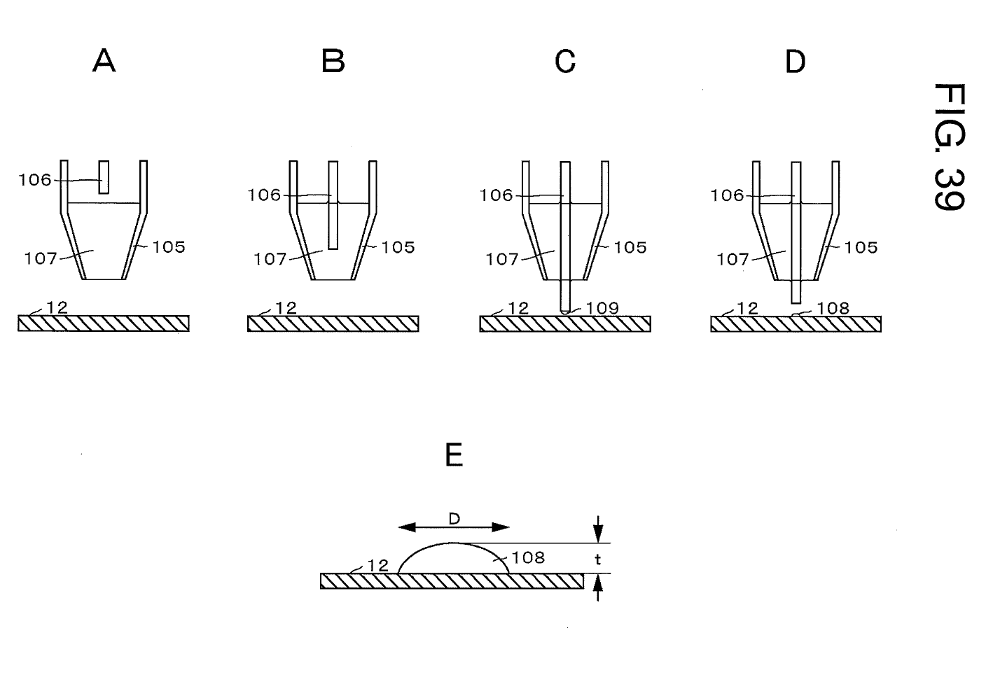

FIGS. 39A to 39D are schematic diagrams illustrating an exemplary operation of the application needle in the minute droplet application system. FIG. 39E is a schematic diagram illustrating a liquid droplet formed on the surface of an application target through the steps in FIGS. 39A to 39D. As described above, the application needle 106 is moved together with the sliding movement of the fine adjustment stage 103 (see FIG. 37A).

The glass pipette 105 is filled with the application liquid 107. In FIG. 39A, the tip end of the application needle 106 is located above the liquid surface of the application liquid 107. The tip end of the application needle 106 moves in a direction toward the surface of the transparent conductive layer 12 serving as the application target. In FIG. 39B, the tip end of the application needle 106 is located within the application liquid 107. In FIG. 39C, the tip end of the application needle 106 has moved below the glass pipette 105. In this case, part of the application liquid 107 adheres to the tip end of the application needle 106 as a liquid droplet 109. Then, as shown in FIG. 39D, the application needle 106 moves further downward, and the droplet 109 of the application liquid 107 adhering to the tip end of the application needle 106 comes into contact with the surface of the transparent conductive layer 12 and is transferred to the surface. In this case, a liquid droplet 108 is formed on the surface of the transparent conductive layer 12. Then the application needle 106 moves upward to the application liquid 107 in the glass pipette 105.

As shown in FIG. 39E, the liquid droplet 108 formed on the surface of the transparent conductive layer 12 has a droplet diameter D and a thickness t. The minimum possible dimensions of the liquid droplet 108 formed are a droplet diameter D of about 5 [μm] and a thickness t of about 1 [μm]. With the needle type dispenser, not only dots (stipple patterns) but also lines can be drawn. A phenomenon in which a ridged edge and uneven thickness occur, which occurs in inkjet printing, is less likely to occur with the needle type dispenser.

TABLE 5 shows features of various droplet forming methods.

TABLE 5

| | | | Jet-type and |
|---|---|---|---|
| | Needle-type | | pneumatic |
| Type | dispenser | InkJet method | dispensers |
| Viscosity [mPa · s] | 1 to 350,000 | 1 to 15 | 1 to 250,000 |
| Minimum possible | 5 | 50 | 500 |
| application | | | |
| diameter [μm] | | | |
| Thickness [μm] | 1 | 0.1 | — |
| Other | | Liquid landing | |
| | | deviation and | |
| | | coffee ring | |

With a jet type dispenser and a pneumatic dispenser, the minimum possible application amount of liquid is limited to 1,000 [pl]. However, with the needle type dispenser, a very small amount, i.e., 1 [pl], can be applied. As shown in TABLE 5, 1 [pl] corresponds to an application diameter of 5 [μm]. In the inkjet method, an application liquid having a low viscosity of 1 to 15 [mPa·s] is preferred, and a high viscosity liquid cannot be applied. On the other hand, in the needle type dispenser, low to high viscosity liquids having a viscosity of 1 to 350,000 [mPa·s] can be applied. As described above, with the needle type dispenser, pico-liters of high viscosity liquid, which cannot be applied with the inkjet method, can be applied. Therefore, the needle type dispenser having these features allows free application design. More specifically, not only a liquid containing a large amount of an organic solvent but also a liquid containing a large amount of a resin etc. can be used. In addition, a liquid including an increased amount of functional groups in order to improve adhesion can be used. Moreover, a thermosetting resin can be advantageously replaced with a UV curable resin, and this is advantageous also in terms of takt time. Since the liquid used can be selected from a variety of choices, cost can be reduced.

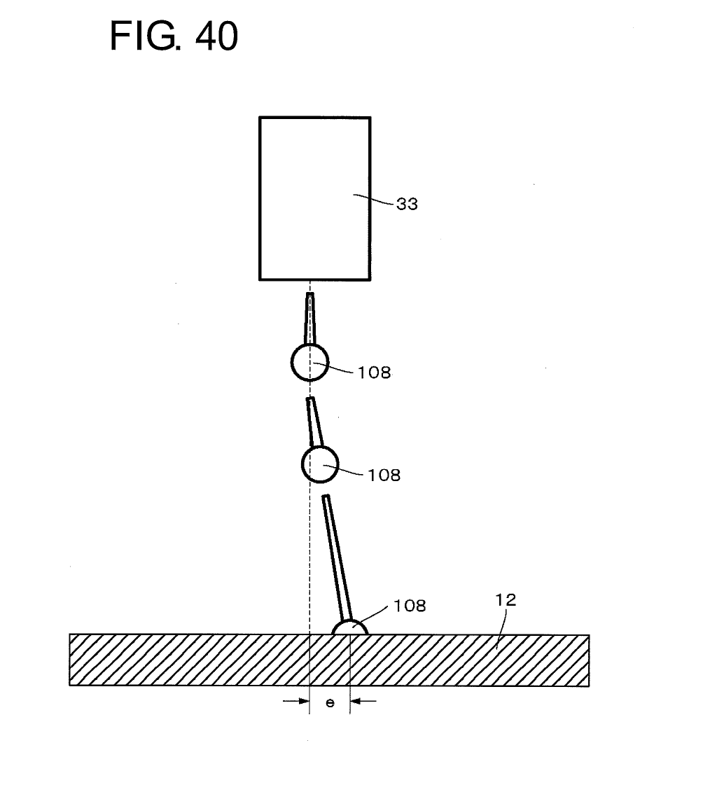

FIG. 40 shows the movement of a liquid droplet ejected from an inkjet nozzle until the liquid droplet lands on the application target. The flight path of the liquid droplet 108 ejected from the inkjet nozzle 33 is deflected due to the influence of airflow, electric charge, etc., so that the landing position of the droplet is deviated from a desired output position by “e.”

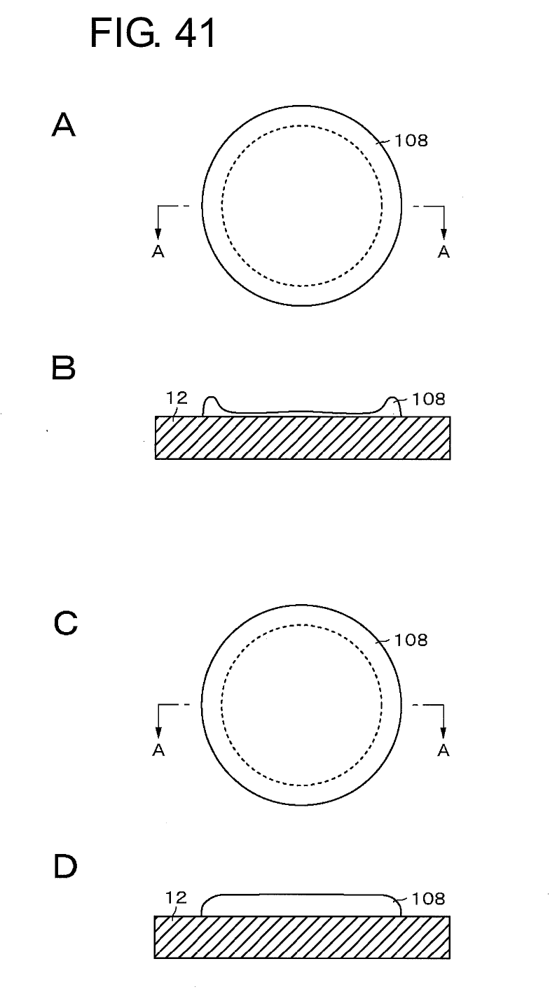

FIG. 41A is a plan view illustrating an example of a liquid droplet formed by inkjet printing. FIG. 41B is a cross-sectional view taken along line A-A shown in FIG. 41A. FIG. 41C is a plan view illustrating an example of a liquid droplet formed by the needle-type dispenser. FIG. 41D is a cross-sectional view taken along line A-A shown in FIG. 41C. As shown in FIGS. 41A and 41B, in the liquid droplet 108 formed by inkjet printing on, for example, the transparent conductive layer 12, a so-called coffee ring phenomenon in which the thickness of the droplet becomes uneven occurs. However, as shown in FIGS. 41C and 41D, in the liquid droplet 108 formed on, for example, the transparent conductive layer 12 by applying a high viscosity liquid using the needle type dispenser, a coffee ring is less likely to occur.

The thirteenth embodiment is the same as the first embodiment except for those described above.

### [Effects]

According to the thirteenth embodiment, the following effects can be further obtained in addition to the effects in the first embodiment. One effect according to the thirteenth embodiment is that application can be performed accurately at desired output positions. Another effect according to the thirteenth embodiment is that when a high viscosity coating is used, the coffee ring phenomenon caused by application and drying can be prevented.

### 14. Fourteenth Embodiment

(Wiping after Swelling with Organic Solvent or Water)

In the first to thirteenth embodiments, the etching solution is used to form the hole elements in the transparent electrode portions and transparent insulating portions. This can be replaced with the fourteenth embodiment of the present technique described below. Examples of transparent electrode portions and transparent insulating portions when hole elements are formed by wiping after swelling with a solvent such as an organic solvent (organic dissolvent) or water according to the fourteenth embodiment of the present technique will next be described.

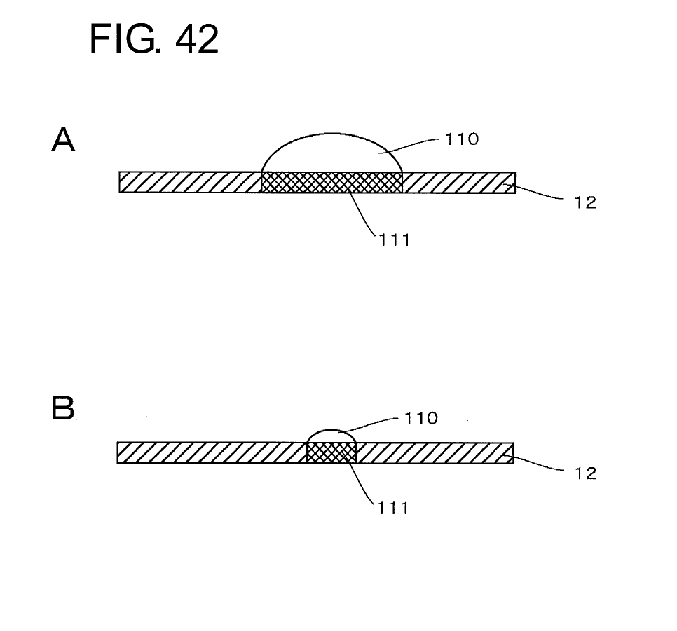

FIG. 42A is a cross-sectional view illustrating an example of a droplet of an organic solvent dropped on a transparent conductive layer. The transparent conductive layer 12 shown in FIG. 42A is formed on the surface of an unillustrated substrate. When the transparent conductive layer 12 is not over-coated, it is susceptible to organic solvents etc. and is easily eroded. Therefore, first, an organic solvent 110 is dropped on the surface of the transparent conductive layer 12. Then the organic solvent 110 infiltrates into the transparent conductive layer 12 from the contact area on the surface of the transparent conductive layer 12. In the transparent conductive layer 12, an infiltrated portion 111 infiltrated with the organic solvent 110 swells. By wiping off the infiltrated portion 111 swelled as described above, a hole element can be formed in the transparent conductive layer 12.

As employed herein, the transparent conductive layer 12 used has a structure that can be swelled with a solvent such as an organic solvent or water. A transparent conductive film that can be formed using a wet process can be used as the above-described transparent conductive layer 12. More specifically, a transparent conductive film containing a conductive nano-filler or a conductive polymer can be used. The transparent conductive layer 12 may further contain a binder etc. as needed. For example, the transparent conductive layer 12 is obtained by printing or applying a composition containing a conductive nano-filler or a conductive polymer onto the surface of a substrate, drying the applied composition, and, if necessary, firing the dried composition.

FIG. 42B is a cross-sectional view illustrating an example of a minute amount of the organic solvent dropped on the transparent conductive layer. As shown in FIG. 42B, when the amount of the organic solvent 110 dropped on the transparent conductive layer 12 is very small, a very small infiltrated portion 111 is wiped off.

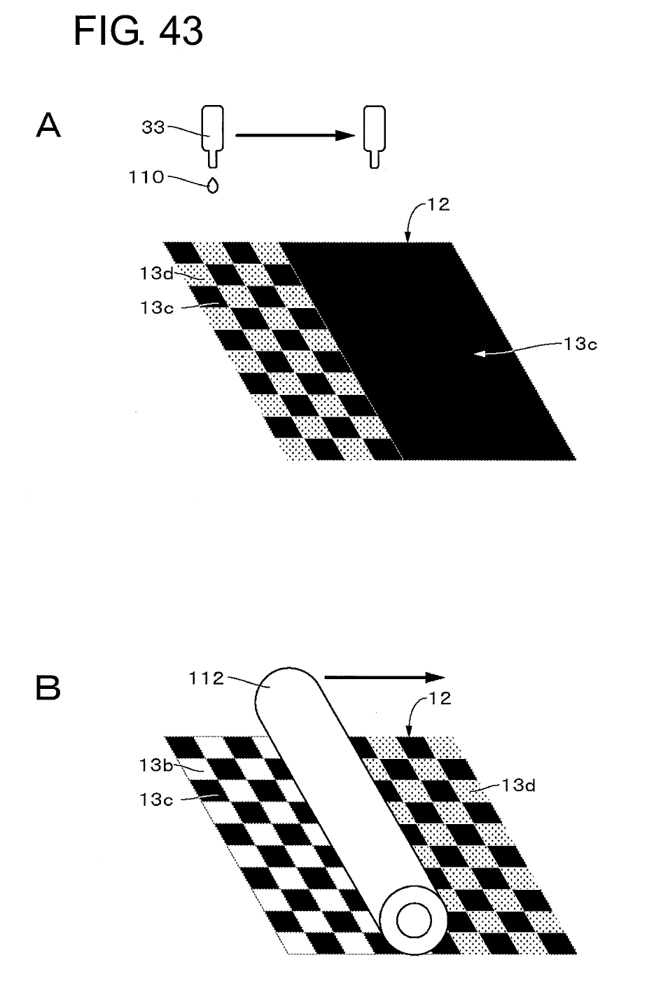

FIGS. 43A and 43B are process diagrams illustrating an example of a method of forming hole elements in transparent electrode portions and transparent insulating portions according to the fourteenth embodiment of the present technique. As shown in FIG. 43A, first, a transparent conductive layer 12, which is a continuous film, is provided continuously on the surface of an unillustrated substrate. The transparent conductive layer 12 contains, for example, silver nano-wires. To apply a coating forming the transparent conductive layer 12, a method such as a slit coater may be used.

Next, an organic solvent 110 is dropped from a nozzle 33 onto a hole formation target portion 13d. In the hole formation target portion 13d, the transparent conductive layer 12 is infiltrated with the organic solvent 110, and swelling occurs in the transparent conductive layer 12. Any material can be used as the organic solvent 110 so long as it can swell the transparent conductive layer 12. Examples of the organic solvent 110 used may include ethanol, acetone, and isopropyl alcohol (2-propanol). Water may be used instead of the organic solvent 110. Any dropping method can be used so long as an appropriate amount of the organic solvent 110 can be dispensed onto a desired position. For example, any of the above-described inkjet method and minute droplet application system is used for the dropping method. For example, when the inkjet method is used, multiple heads may be used. When multiple heads are used, a short takt time can be achieved. When the minute droplet application system is used, the solvent can be dropped with high precision.

The organic solvent 110 is dropped so as to be arranged in a prescribed manner. In the example shown in FIG. 43A, portions onto which the organic solvent 110 is dropped are arranged in a regular pattern. The arrangement may be a random arrangement. Such a pattern is controlled using digital data, and the organic solvent 110 can be dropped without using any mask.

Next, as shown in FIG. 43B, wiping (for example, rubbing) is performed on the transparent conductive layer 12 having been patterned with the organic solvent 110. By wiping off the swelled hole formation target portions 13d, hole portions 13b are formed in the transparent conductive layer 12. For example, a roll rubbing machine 112 is used for wiping. Any wiping method can be used so long as the transparent conductive layer 12 is transferred and the swelled hole formation target portions 13d can be wiped off. Portions with no organic solvent 110 dropped become transparent conductive portions 13c. The transparent electrode portions have been described above. However, hole elements can be formed in transparent insulating portions in a similar manner.

### [Effects]

In this embodiment, it is not necessary to use a highly acidic etching solution. Therefore, this embodiment has an effect in that the life of the head of a dispensing device is extended. Since it is not necessary to use glass for the head and the nozzle and various materials can be used, this embodiment has an effect in that an increase in cost can be suppressed and large size products can be produced. In addition, since a rinsing step required after etching is not necessary and the working process can be simplified, this embodiment has an effect in that working hours can be reduced and cost can also be reduced.

### 15. Fifteenth Embodiment

An electronic apparatus according to the fifteenth embodiment includes, in its display unit, any of the information input devices 10 according to the first to fourteenth embodiments. Examples of the electronic apparatus according to the fifteenth embodiment of the present technique will next be described.

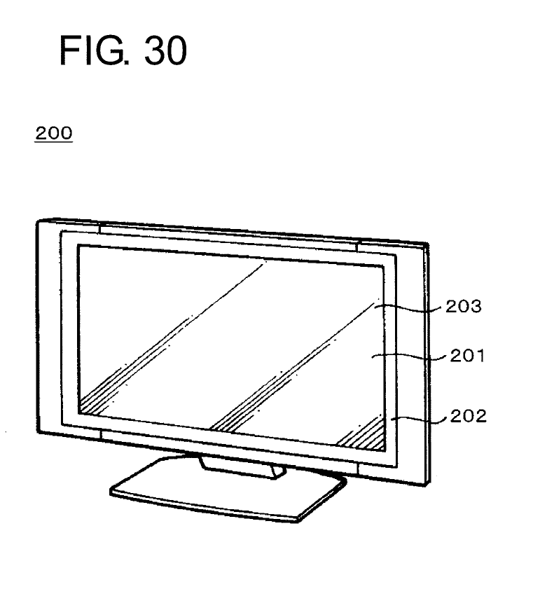

FIG. 30 is an appearance diagram of a television set 200 shown as an example of the electronic apparatus. The television set 200 has a display unit 201 including a front panel 202, a glass filter 203, etc., and the display unit 201 further includes any of the information input devices 10 according to the first to fifth embodiments.

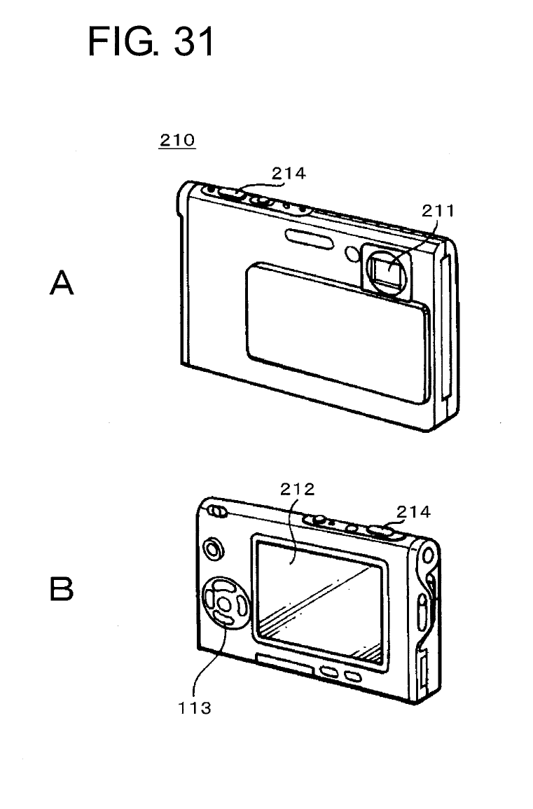

FIGS. 31A and 31B are appearance diagrams of a digital camera shown as an example of the electronic apparatus. FIG. 31A is an appearance diagram when the digital camera is viewed from its front side. FIG. 31B is an appearance diagram when the digital camera is viewed from its rear side. The digital camera 210 includes a light emitting unit 211 for a flash, a display unit 212, a menu switch 213, a shutter button 214, etc, and the display unit 212 includes any of the information input devices 10 according to the first to fourteenth embodiments.

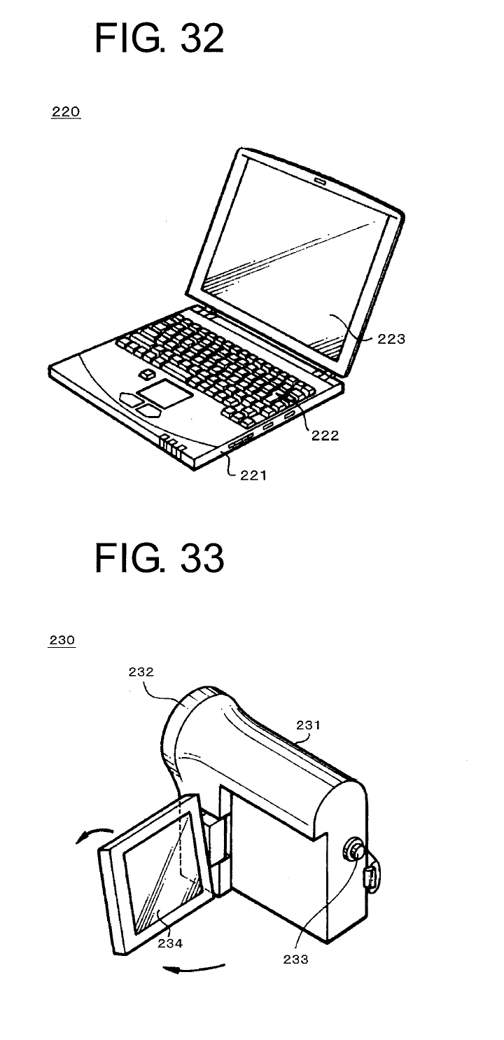

FIG. 32 is an appearance diagram of a notebook personal computer shown as an example of the electronic apparatus. The notebook personal computer 220 includes a main body 221, a keyboard 222 operated for inputting such as letters, a display unit 223 for displaying an image, and the like. The display unit 223 includes any of the information input devices 10 according to the first to fourteenth embodiments.

FIG. 33 is an appearance diagram of a video camera shown as an example of the electronic apparatus. The video camera 230 includes a main body 231, a lens 232 disposed on a side surface facing forward and used to take an image of a subject, a start-stop switch 233 for imaging, a display unit 234, etc., and the display unit 234 includes any of the information input devices 10 according to the first to fourteenth embodiments.

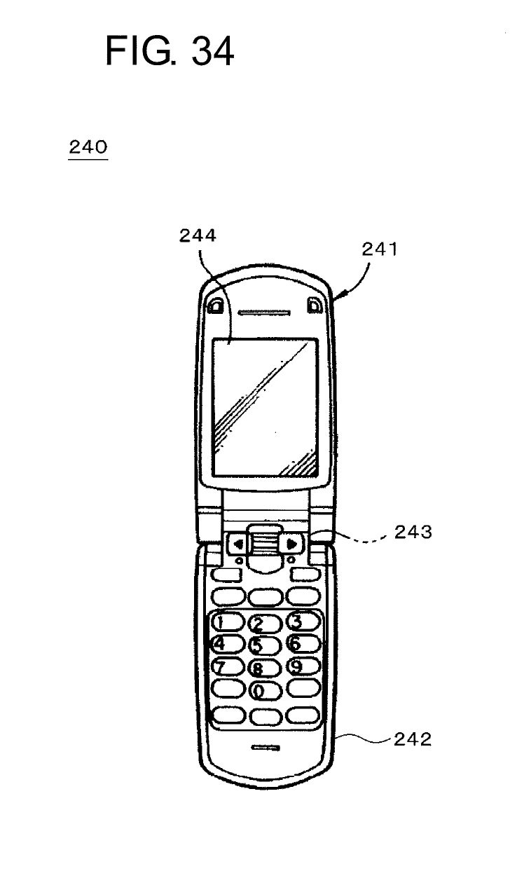

FIG. 34 is an appearance diagram of a portable terminal device shown as an example of the electronic apparatus. The portable terminal device is, for example, a mobile phone and includes an upper case 241, a lower case 242, a connection portion (a hinge portion in this case) 243, and a display unit 244. The display unit 244 includes any of the information input devices 10 according to the first to fourteenth embodiments.

### [Effects]

The above-described electronic apparatuses according the fifteenth embodiment include any of the information input devices 10 according to the first to fourteenth embodiments. Therefore, visual recognition of the information input device 10 in the display unit can be suppressed.

### EXAMPLES

The present technique will next be specifically described by way of Examples, but the present technique is not limited only to these Examples.

The Examples will be described in the following order.

<1. The relationship between the ratio of dots forming hole elements and the characteristics of the transparent conductive layer>

<2. The relationship between visibility and the difference in the ratio of dots forming hole elements>

<3. The electric characteristics of transparent conductive layers produced using the minute droplet application system>

<4. The visibility of transparent conductive layers produced using the minute droplet application system>

<5. Example of a patterning method using wiping treatment on a transparent conductive layer>

### <1. The Relationship Between the Ratio of Dots Forming Hole Elements and the Characteristics of the Transparent Conductive Layer>

Samples with different ratios p of dots forming hole elements were produced, and the characteristics of the produced samples were evaluated.

### Example 1

First, a transparent conductive layer containing silver nano-wires was formed on the surface of a 125 thick PET sheet by a coating method to thereby obtain a transparent conductive sheet. The sheet resistance of the transparent conductive sheet was measured by a four probe method. The measurement device used was Loresta EP type MCP-T360 manufactured by Mitsubishi Chemical Analytech Co., Ltd. The results showed that the surface resistance was 200 Ω/square.

Next, an iodine solution used as an etching solution was prepared. The iodine solution was prepared as follows. First, water and diethylene glycol monoethyl ether were mixed at a weight ratio of 2:8 to prepare a solution mixture. Then 0.1 mol/l of iodine and 0.6 mol/l of potassium iodide were dissolved in the solution mixture to prepare the iodine solution.

Next, the prepared iodine solution was printed on the surface of the transparent conductive layer in the transparent conductive sheet by an inkjet printing method. Areas on which the iodine solution was printed were etched, and hole elements were thereby formed. With the iodine solution used in this Example, dots of 45 μm at a minimum could be printed using the inkjet printing method, so a print pattern was produced at a resolution of 600 dpi. Printing was performed such that adjacent hole elements (dots) in adjacent rows that were adjacent in the X-axis or Y-axis direction were connected to each other. A random pattern produced according to the raster image production algorithm shown in FIG. 10 was used as a print pattern. During production of the print pattern, the ratio p of dots forming hole elements was set to 20[%].

Next, the printed transparent conductive sheet was heated in an oven at 60° C. for 2 minutes and then washed with distilled water. An intended transparent conductive sheet was thereby obtained.

### Example 2

A transparent conductive sheet was obtained in the same manner as in Example 1 except that the ratio p of dots forming hole elements was set to 30[%].

### Example 3

A transparent conductive sheet was obtained in the same manner as in Example 1 except that the ratio p of dots forming hole elements was set to 40[%].

### Example 4

A transparent conductive sheet was obtained in the same manner as in Example 1 except that the ratio p of dots forming hole elements was set to 50[%].

### Example 5

A transparent conductive sheet was obtained in the same manner as in Example 1 except that the ratio p of dots forming hole elements was set to 60[%].

### Example 6

A transparent conductive sheet was obtained in the same manner as in Example 1 except that the ratio p of dots forming hole elements was set to 70 M.

### Example 7

A transparent conductive sheet was obtained in the same manner as in Example 1 except that the ratio p of dots forming hole elements was set to 80[%].

### <Evaluation of Electric Conductivity>

The sheet resistance [Ω/square] of each of the transparent conductive sheets obtained as described above was measured using a noncontact electrical resistance meter.

<Moiré>

One of the transparent conductive sheets obtained as described above was affixed to a glass slide using an adhesive sheet. Then a black tape was affixed to the rear side to allow surface reflection to be easily seen, and sensory evaluation was performed visually on the basis of the following criteria.

G (Good): No moiré was found.

NG (No Good): Moiré was found.

### <Optical Evaluation>

The haze (the degree of cloudiness) and the total light transmittance of each of the transparent conductive sheets obtained as described above were measured using a haze meter.

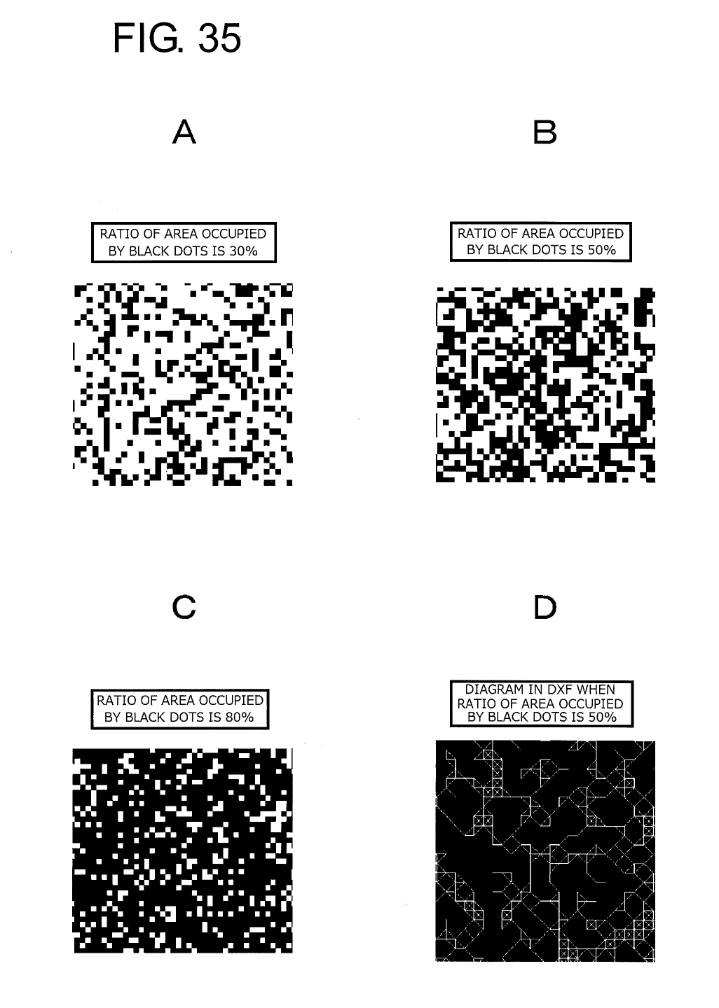

FIGS. 35A to 35C show raster images (random patterns) in bitmap format used to produce transparent conductive sheets in Examples 2, 4, and 7. FIG. 35D shows a vector image in DXF (Drawing Exchange Format) converted from the raster image (random pattern) used to produce the transparent conductive sheet in Example 4. In FIGS. 35A to 35C, black dots correspond to positions on which the etching solution is printed, and white dots correspond to positions on which no etching solution is printed. The ratio of area occupied by black dots in each of FIGS. 35A to 35D corresponds to the ratio p of dots forming hole elements.

TABLE 3 shows the evaluation results for the transparent conductive sheets in Examples 1 to 7.

TABLE 3

| | | Electric | | | |
|---|---|---|---|---|---|
| | Ratio | Resistance | Haze | Transmittance | |
| | p (%) | (Ω/□) | (%) | (%) | Moiré |
| Example 1 | 20 | 265 | 1.10 | 90.29 | G |
| Example 2 | 30 | 300 | 0.99 | 90.17 | G |
| Example 3 | 40 | 390 | 0.98 | 90.25 | G |
| Example 4 | 50 | 403 | 0.89 | 90.26 | G |
| Example 5 | 60 | 10³ or | 0.89 | 89.70 | G |
| | | higher | | | |
| Example 6 | 70 | 10³ or | 0.68 | 89.73 | G |
| | | higher | | | |
| Example 7 | 80 | 10³ or | 0.72 | 90.06 | G |
| | | higher | | | |

Ration p: Ratio of dots (black dots) on which etching solution is printed.

The following can be seen from TABLE 3.

When the ratio p of dots forming hole elements was set to 50[%] or less, an increase in the electric resistance of the transparent conductive layer was suppressed, and it was possible to allow the transparent conductive layer to function as an electrode having good electric conductivity. However, when the ratio p of dots forming hole elements was set to be higher than 50[%], a reduction in the electric resistance of the transparent conductive layer was suppressed, and it was possible to allow the transparent conductive layer to function as an insulating portion having good insulating properties.

From the viewpoint of allowing the transparent conductive layer to function as an electrode having good electric conductivity, the ratio p of dots forming hole elements is preferably set to be p≦50[%], more preferably p≦40[%], and still more preferably p≦30[%]. More specifically, the average ratio P1 of hole elements per unit section in the transparent conductive layer is preferably set to be P1≦50[%], more preferably P1≦40[%], and still more preferably P1≦30[%].

From the viewpoint of allowing the transparent conductive layer to function as an insulating portion having good insulating properties, the ratio p of dots forming hole elements is preferably set to be 50[%]<p and more preferably 60[%]<p. More specifically, the average ratio P2 of hole elements per unit section in the transparent conductive layer is preferably set to be 50[%]<P2 and more preferably 60[%]<P2.

By printing the etching solution on the transparent conductive layer using a random pattern (raster image) produced on the basis of the algorithm shown in FIG. 10, hole elements could be randomly formed in the transparent conductive layer. The occurrence of moiré was thereby suppressed.

### <2. The Relationship Between Visibility and the Difference in the Ratio of Dots Forming Hole Elements>

Samples in which regions with different ratios p of dots forming hole elements were adjacent to each other were formed, and visibility of each sample including these regions was evaluated.

### Example 8

First regions R₁ in which the ratio p of dots forming hole elements was set to 20[%] and second regions R₂ in which the ratio p of dots forming hole elements was set to [%] were alternately formed on a transparent conductive layer on the surface of a PET sheet. The first regions R₁ and the second regions R₂ had slim rectangular shapes. The same procedure as in Example 1 except for those described above was repeated to obtain a transparent conductive sheet.

### Example 9

A transparent conductive sheet was obtained in the same manner as in Example 8 except that the ratio p of dots in the first regions R₁ was set to 30[%] and the ratio p of dots in the second regions R₂ was set to 50 [%].

### Example 10

A transparent conductive sheet was obtained in the same manner as in Example 8 except that the ratio p of dots in the first regions R₁ was set to 30[%] and the ratio p of dots in the second regions R₂ was set to 60 [%].

### Example 11

A transparent conductive sheet was obtained in the same manner as in Example 8 except that the ratio p of dots in the first regions R₁ was set to 40[%] and the ratio p of dots in the second regions R₂ was set to 50[%].

### Example 12

A transparent conductive sheet was obtained in the same manner as in Example 8 except that the ratio p of dots in the first regions R₁ was set to 40[%] and the ratio p of dots in the second regions R₂ was set to 60[%].

### Example 13

A transparent conductive sheet was obtained in the same manner as in Example 8 except that the ratio p of dots in the first regions R₁ was set to 40 [%] and the ratio p of dots in the second regions R₂ was set to 70[%].

### Example 14

A transparent conductive sheet was obtained in the same manner as in Example 8 except that the ratio p of dots in the first regions R₁ was set to 45[%] and the ratio p of dots in the second regions R₂ was set to 50[%].

### Example 15

A transparent conductive sheet was obtained in the same manner as in Example 8 except that the ratio p of dots in the first regions R₁ was set to 30[%] and the ratio p of dots in the second regions R₂ was set to 70[%].

### Example 16

A transparent conductive sheet was obtained in the same manner as in Example 8 except that the ratio p of dots in the first regions R₁ was set to 40[%] and the ratio p of dots in the second regions R₂ was set to 80[%].

### <Visibility>

One of the transparent conductive sheets obtained as described above was affixed to a glass slide using an adhesive sheet. Then a black tape was affixed to the rear side to allow surface reflection to be easily seen, and sensory evaluation was performed visually on the basis of the following criteria.

G (Good): The boundary portions between the first regions R₁ and the second regions R₂ were not clearly recognized.

NG (No Good): The boundary portions between the first regions R₁ and the second regions R₂ were clearly recognized.

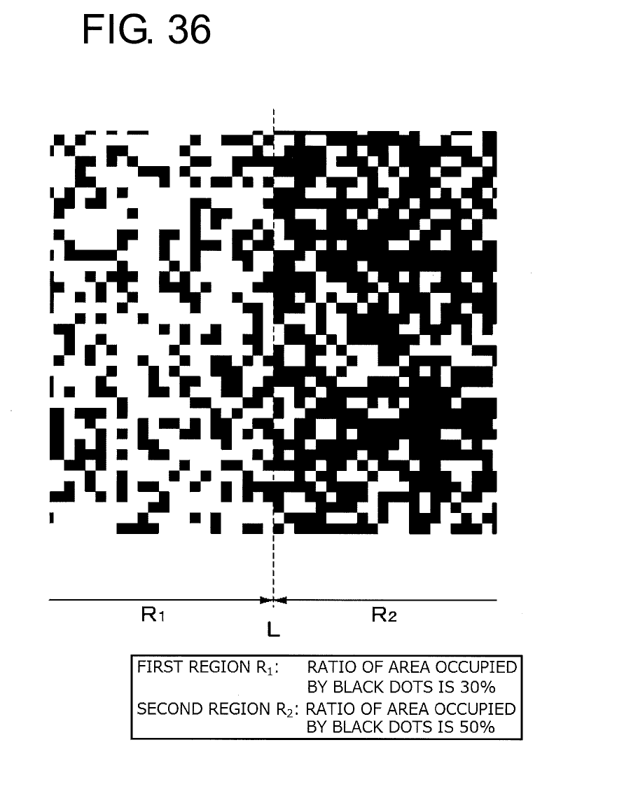

FIG. 36 shows a raster image (random pattern) in bitmap format used to produce the transparent conductive sheet in Example 9. In FIG. 36, black dots correspond to positions on which the etching solution is printed, and white dots correspond to positions on which no etching solution is printed. The ratio of area occupied by black dots in FIG. 36 corresponds to the ratio p of dots forming hole elements.

TABLE 4 shows the evaluation results for the transparent conductive sheets in Examples 8 to 16.

TABLE 4

Ratio p (%)

| | First | Second | | |
|---|---|---|---|---|
| | region R₁ | region R₂ | Δp (%) | Visibility |
| Example 8 | 20 | 50 | 30 | G |
| Example 9 | 30 | 50 | 20 | G |
| Example 10 | 30 | 60 | 30 | G |
| Example 11 | 40 | 50 | 10 | G |
| Example 12 | 40 | 60 | 20 | G |
| Example 13 | 40 | 70 | 30 | G |
| Example 14 | 45 | 50 | 5 | G |
| Example 15 | 30 | 70 | 40 | NG |
| Example 16 | 40 | 80 | 40 | NG |

Ratio p: Ratio of dots (black dots) on which etching solution is printed.
Δp: Difference in ratio p between first region R₁ and second region R₂.

The following can be seen from TABLE 4.

When the difference Δp between the ratio p of dots in the second regions R₂ and the ratio p of dots in the first regions R₁ is set to 30[%] or less, the visual recognition of the boundaries between the first regions R₁ and the second regions R₂ could be suppressed. Specifically, from the viewpoint of suppressing the visual recognition of the boundaries between the transparent electrode portions and the transparent insulating portions, the difference ΔP (=P2−P1) between the average ratio P2 of hole elements per unit section in the transparent insulating portions and the average ratio P1 of hole elements per unit section in the transparent electrode portions is preferably set to be 30[%] or less.

### <3. The Electric Characteristics of Transparent Conductive Layers Produced Using the Minute Droplet Application System>

The etching solution was applied using the minute droplet application system described in the thirteenth embodiment to produce samples with hole elements formed therein, and the characteristics of these samples were evaluated.

### Example 17

First, a transparent conductive layer containing silver nano-wire (AgNW) was formed on the surface of a 100 μm-thick PET sheet by a coating method to thereby obtain a transparent conductive sheet. The sheet resistance of the transparent conductive sheet was measured by a four probe method. The measurement device used was Loresta EP type MCP-T360 manufactured by Mitsubishi Chemical Analytech Co., Ltd. The results showed that the surface resistance was 100 Ω/square.

### Example 18

Next, an iodine solution used as an etching solution was prepared. The iodine solution was prepared as follows. First, water and diethylene glycol monoethyl ether were mixed at a weight ratio of 2:8 to prepare a solution mixture. Then 0.1 mol/l of iodine and 0.6 mol/l of potassium iodide were dissolved in the solution mixture to prepare the iodine solution.

Next, the prepared iodine solution was applied, using the needle type dispenser, to the surface of a transparent conductive layer of a transparent conductive sheet obtained in the same manner as in Example 17. Areas on which the iodine solution was applied were etched, and hole elements were thereby formed. In this Example, an application needle 106 having a tip end with a diameter of 50[μm] was used. Application was performed such that adjacent hole elements (dots) in adjacent rows that were adjacent in the X-axis or Y-axis direction were connected to each other. A random pattern produced according to the raster image production algorithm shown in FIG. 10 was used as an application (print) pattern. During production of the application pattern, the ratio p of dots forming hole elements was set to 15[%].

Next, the applied (printed) transparent conductive sheet was heated in an oven at 60° C. for 2 minutes and then washed with distilled water. An intended transparent conductive sheet was thereby obtained.

### Example 19

A transparent conductive sheet was obtained in the same manner as in Example 18 except that the ratio p of dots forming hole elements was set to 25 M.

### Example 20

A transparent conductive sheet was obtained in the same manner as in Example 18 except that the ratio p of dots forming hole elements was set to 35[%].

### Example 21

A transparent conductive sheet was obtained in the same manner as in Example 18 except that the ratio p of dots forming hole elements was set to 50[%].

### Example 22

A transparent conductive sheet was obtained in the same manner as in Example 18 except that the ratio p of dots forming hole elements was set to 65[%].

### <Evaluation of Electric Conductivity>

The sheet resistance [Ω/square] of each of the transparent conductive sheets obtained as described above was measured using a noncontact electrical resistance meter. In addition, the resistance ratio [−] of each of the transparent conductive sheets obtained as described above was computed. As employed herein, the resistance ratio refers to a value computed by dividing the sheet resistance [Ω/square] of the transparent conductive sheet in a processed portion irradiated with laser light (the sheet resistance after processing) by the sheet resistance [Ω/square] of the transparent conductive sheet before processing. The value measured in Example 17 (100[Ω/square]) was used as the sheet resistance [Ω/square] of the transparent conductive sheet before processing.

TABLE 6 shows the evaluation results for the transparent conductive sheets in Examples 17 to 22.

TABLE 6

| | Ratio p | Electric resistance Rs | Resistance |
|---|---|---|---|
| | (%) | (Ω/□) | ratio [—] |
| Example 17 | 0 | 100 | 1.0 |
| Example 18 | 15 | 156 | 1.6 |
| Example 19 | 25 | 188 | 1.9 |
| Example 20 | 35 | 224 | 2.2 |
| Example 21 | 50 | 305 | 3.1 |
| Example 22 | 65 | 10³ or higher | — |

Evaluation of electric characteristics of conductive plate
Structure: 100 [μm] - thick PET sheet/AgNW layer
Surface resistance Rs: 100 Ω/□ (Square)
Resistance measurement: Noncontact electrical resistance meter
Etching solution: Iodine solution

The following can be seen from TABLE 6.

When the ratio p of dots forming hole elements was set to 50[%] or less, an increase in the electric resistance of the transparent conductive layer was suppressed, and it was possible to allow the transparent conductive layer to function as an electrode having favorable electric conductivity. However, when the ratio p of dots forming hole elements was set to be higher than 50[%], a reduction in the electric resistance of the transparent conductive layer was suppressed, and it was possible to allow the transparent conductive layer to function as an insulating portion having good insulating properties.

Therefore, even with the samples in which hole elements were formed by application of the etching solution using the minute droplet application system, a transparent conductive sheet having the same functions as those obtained by the inkjet printing method could be produced.

### <4. The Visibility of Transparent Conductive Layers Produced Using the Minute Droplet Application System>

Samples in which regions with different ratios p of dots forming hole elements were adjacent to each other were formed using the minute droplet application system, and the visibility of each sample including these regions was evaluated. As described above, when the ratio p of dots is 50[%] or less, a conductive electrode (conductive portion) with an increase in electric resistance suppressed is obtained. When the ratio p of dots is higher than 50[%], an insulating electrode (non-conductive portion) with a reduction in electric resistance suppressed is obtained.

### Example 23

First regions R₁ in which the ratio p of dots forming hole elements was set to 10[%] and second regions R₂ in which the ratio p of dots forming hole elements was set to 50[%] were alternately formed on a transparent conductive layer on the surface of a PET sheet. The first regions R₁ and the second regions R₂ had slim rectangular shapes. The same procedure as in Example 18 except for those described above was repeated to obtain a transparent conductive sheet.

### Example 24

A transparent conductive sheet was obtained in the same manner as in Example 23 except that the ratio p of dots in the first regions R₁ was set to 15[%] and the ratio p of dots in the second regions R₂ was set to 50[%].

### Example 25

A transparent conductive sheet was obtained in the same manner as in Example 23 except that the ratio p of dots in the first regions R₁ was set to 20[%] and the ratio p of dots in the second regions R₂ was set to 50[%].

### Example 26

A transparent conductive sheet was obtained in the same manner as in Example 23 except that the ratio p of dots in the first regions R₁ was set to 30[%] and the ratio p of dots in the second regions R₂ was set to 50[%].

### Example 27

A transparent conductive sheet was obtained in the same manner as in Example 23 except that the ratio p of dots in the first regions R₁ was set to 40[%] and the ratio p of dots in the second regions R₂ was set to 50[%].

### Example 28

A transparent conductive sheet was obtained in the same manner as in Example 23 except that the ratio p of dots in the first regions R₁ was set to 10[%] and the ratio p of dots in the second regions R₂ was set to 60[%].

### Example 29

A transparent conductive sheet was obtained in the same manner as in Example 23 except that the ratio p of dots in the first regions R₁ was set to 20[%] and the ratio p of dots in the second regions R₂ was set to 60[%].

### Example 30

A transparent conductive sheet was obtained in the same manner as in Example 23 except that the ratio p of dots in the first regions R₁ was set to 30[%] and the ratio p of dots in the second regions R₂ was set to 60[%].

### Example 31

A transparent conductive sheet was obtained in the same manner as in Example 23 except that the ratio p of dots in the first regions R₁ was set to 40[%] and the ratio p of dots in the second regions R₂ was set to 60[%].

### Example 32

A transparent conductive sheet was obtained in the same manner as in Example 23 except that the ratio p of dots in the first regions R₁ was set to 20[%-] and the ratio p of dots in the second regions R₂ was set to 70[%].

### Example 33

A transparent conductive sheet was obtained in the same manner as in Example 23 except that the ratio p of dots in the first regions R₁ was set to 30[%] and the ratio p of dots in the second regions R₂ was set to 70[%].

### Example 34

A transparent conductive sheet was obtained in the same manner as in Example 23 except that the ratio p of dots in the first regions R₁ was set to 40[%] and the ratio p of dots in the second regions R₂ was set to 70[%].

### Example 35

A transparent conductive sheet was obtained in the same manner as in Example 23 except that the ratio p of dots in the first regions R₁ was set to 40[%-] and the ratio p of dots in the second regions R₂ was set to 80[%].

### <Visibility>

One of the transparent conductive sheets obtained as described above was affixed to a glass slide using an adhesive sheet. Then a black tape was affixed to the rear side to allow surface reflection to be easily seen, and sensory evaluation was performed visually on the basis of the following criteria.

A: The boundary portions between the first regions R₁ and the second regions R₂ were not clearly recognized.

B: The boundary portions between the first regions R₁ and the second regions R₂ were clearly recognized.

TABLE 7 shows the evaluation results for the transparent conductive sheets in Examples 23 to 35.

TABLE 7

Ratio p (%)

| | First | Second | | |
|---|---|---|---|---|
| | region R₁ | region R₂ | Δp (%) | Visibility |
| Example 23 | 10 | 50 | 40 | NG |
| Example 24 | 15 | 50 | 35 | NG |
| Example 25 | 20 | 50 | 30 | G |
| Example 26 | 30 | 50 | 20 | G |
| Example 27 | 40 | 50 | 10 | G |
| Example 28 | 10 | 60 | 50 | NG |
| Example 29 | 20 | 60 | 40 | NG |
| Example 30 | 30 | 60 | 30 | G |
| Example 31 | 40 | 60 | 20 | G |
| Example 32 | 20 | 70 | 50 | NG |
| Example 33 | 30 | 70 | 40 | NG |
| Example 34 | 40 | 70 | 30 | G |
| Example 35 | 40 | 80 | 40 | NG |

Evaluation of electric characteristics of conductive plate
Ratio p of dots
50 ≦ p: Increase in electric resistance is suppressed. Conductive electrodes (conductive portions)
p < 50: Reduction in electric resistance is suppressed. Insulating electrodes (non-conductive portions)
Δp: Δp = |p2 − p1|, preferably 30 [%] or less

The following can be seen from TABLE 7.

When the difference Δp between the ratio p of dots in the second regions R₂ and the ratio p of dots in the first regions R₁ was set to 30[%] or less, the visual recognition of the boundaries between the first regions R₁ and the second regions R₂ could be suppressed. Specifically, from the viewpoint of suppressing the visual recognition of the boundaries between the transparent electrode portions and the transparent insulating portions, the difference ΔP (=P2−P1) between the average ratio P2 of hole elements per unit section in the transparent insulating portions and the average ratio P1 of hole elements per unit section in the transparent electrode portions is preferably set to be 30[%] or less.

### <5. Example of a Patterning Method Using Wiping Treatment on a Transparent Conductive Layer>

A sample in which hole elements were formed by wiping after swelling with an organic solvent described in the fourteenth embodiment was produced, and the characteristics of the produced sample were evaluated.

### Example 36

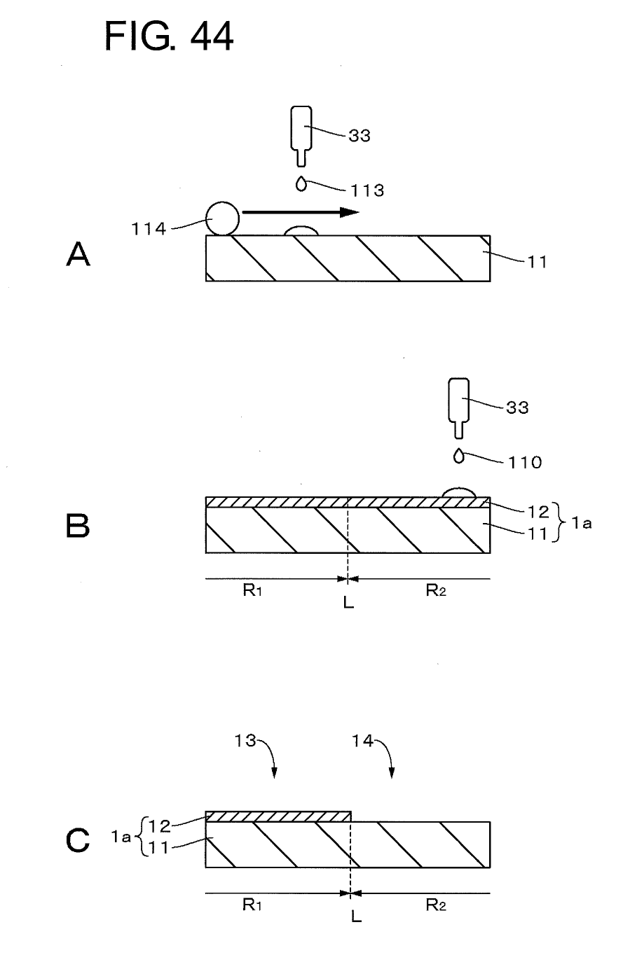

FIGS. 44A to 44C are process diagrams illustrating a method for manufacturing a transparent conductive substrate in Example 36. First, as shown in FIG. 44A, a silver nano-wire coating 113 was dropped from a nozzle 33 onto a substrate 11. Next, the silver nano-wire coating 113 was applied to the surface of the substrate 11 using a coil bar (#8) 114. Then the applied silver nano-wire coating 113 was annealed at 120[° C.] for 30 minutes. A transparent conductive layer containing the silver nano-wires was thereby formed on the surface of the substrate 11 to thereby obtain a transparent conductive sheet. The surface resistance of the transparent conductive sheet was 100 [Ω/square].

Next, as shown in FIG. 44B, an organic solvent 110 was dropped from the nozzle 33 onto the transparent conductive layer 12 formed on the substrate 11. In the transparent conductive substrate 1a including the substrate 11 extending horizontally and the transparent conductive layer 12 formed thereon in FIG. 44B, two regions, i.e., a first region R₁ and a second region R₂, are shown with a vertically extending boundary L therebetween. The first regions R₁ are regions for forming transparent electrode portions 13, and the second regions R₂ are regions for forming transparent insulating portions 14. The organic solvent 110 was dropped onto the second regions R₂ serving as the regions for forming transparent insulating portions 14. In this Example, ethanol was used as the organic solvent 110. Next, the transparent conductive substrate 1a with ethanol dropped thereonto was subjected to heat treatment on a hot plate. The heat treatment was stopped before ethanol was completely dried.

Next, as shown in FIG. 44C, the transparent conductive layer 12 in the second regions R₂ that had been swelled with ethanol was wiped (rubbed) with a paper sheet. The sheet used was KimWipe ((registered trademark) manufactured by NIPPON PAPER CRECIA Co., Ltd.). Transparent insulating portions 14 were thereby formed in the second regions R₂. Transparent electrode portions 13 were formed in the first regions R₁ onto which no organic solvent 110 was dropped and which was not wiped.

### <Evaluation of Electric Conductivity>

The sheet resistances [Ω/square] of the transparent electrode portions 13 and transparent insulating portions 14 in the transparent conductive sheet obtained as described above were measured using a noncontact electrical resistance meter. The results showed that the surface resistance of the transparent electrode portions 13 was 100 [Ω/square]. The surface resistance of the transparent insulating portions 14 was not measurable (higher than the upper limit of measurement, i.e., the transparent insulating portions 14 were in an insulating state). Accordingly, even with the sample in which the hole elements were formed by wiping after swelling with an organic solvent, a transparent conductive sheet having the same functions as those of the transparent conductive sheets obtained by the inkjet printing method and application of the etching solution using the minute droplet application system could be produced.

The embodiments and Examples of the present technique have been specifically described. However, the present technique is not limited to the above embodiments and Examples, and various modifications can be made on the basis of the technical idea of the present technique.

For example, the configurations, methods, processes, shapes, materials, values, etc. described in the above embodiments and Examples are merely examples, and configurations, methods, processes, shapes, materials, values, etc. different from those described above may be used as needed.

In addition, the present technique may be configured as follows.

(1) A transparent conductive element including:

a substrate having a surface;

transparent conductive portions and transparent insulating portions that are alternately provided in a planar manner on the surface, wherein

each of the transparent insulating portions is a transparent conductive layer including a plurality of hole elements provided two-dimensionally in a first direction and a second direction on the surface of the substrate, and

the hole elements that are adjacent in the first direction are connected to each other, and he hole elements that are adjacent in the second direction are connected to each other.

(2) The transparent conductive element according to (1), wherein the transparent conductive layer comprises a plurality of island portions separated from each other through the hole elements.
(3) The transparent conductive element according to (1) or (2), wherein the plurality of hole elements are randomly arranged two-dimensionally in the first direction and the second direction.
(4) The transparent conductive element according to any one of (1) to (3), wherein the hole elements are circular, substantially circular, elliptical, or substantially elliptical.
(5) The transparent conductive element according to any one of (1) to (4), wherein the hole elements that are adjacent in a direction diagonal to the first direction or the second direction are connected to each other.
(6) The transparent conductive element according to any one of (1) to (5), wherein the hole elements are obtained by printing of an etching solution on the transparent conductive layer.
(7) The transparent conductive element according to (6), wherein the printing is printing by an inkjet method or a minute droplet application method.
(8) The transparent conductive element according to any one of (1) to (7), wherein the hole elements are provided at boundary portions between the transparent conductive portions and the transparent insulating portions and arranged in a direction in which the boundary portions extend.
(9) The transparent conductive element according to any one of (1) to (8), wherein

each of the transparent conductive portions is the transparent conductive layer including hole elements arranged two-dimensionally in the first direction and the second direction on the surface of the substrate, and

the hole elements that are adjacent in the first direction are connected to each other, and the hole elements that are adjacent in the second direction are connected to each other.

(10) The transparent conductive element according to (9), wherein

the plurality of hole elements in the transparent conductive portions and the transparent insulating portions are randomly provided two-dimensionally in the first direction and the second direction,

an average ratio P1 of the hole elements in the transparent conductive portions satisfies a relationship P1≦50[%], and

an average ratio P2 of hole elements in the transparent insulating portions satisfies a relationship 50[%]<P2.

(11) The transparent conductive element according to (9), wherein a difference ΔP (=P2−P1) between the average ratio P2 of the hole elements in the transparent insulating portions and the average ratio P1 of the hole elements in the transparent conductive portions satisfies a relationship ΔP≦30[%].
(12) The transparent conductive element according to any one of (1) to (8), wherein each of the transparent conductive portions is the transparent conductive layer that is continuously provided in a region between the transparent insulating portions.
(13) An input device including:

a substrate having a first surface and a second surface,

transparent conductive portions and transparent insulating portions that are alternately provided in a planar manner on the first surface and on the second surface, wherein

each of the transparent insulating portions is a transparent conductive layer including a plurality of hole elements provided two-dimensionally in a first direction and a second direction, and

the hole elements that are adjacent in the first direction are connected to each other, and the hole elements that are adjacent in the second direction are connected to each other.

(14) An input device including:

a first transparent conductive element; and

a second transparent conductive element provided on a surface of the first transparent conductive element, wherein

each of the first transparent conductive element and the second transparent conductive element includes
a substrate having a surface, and
transparent conductive portions and transparent insulating portions that are alternately provided in a planar manner on the surface,

each of the transparent insulating portions is a transparent conductive layer including hole elements provided two-dimensionally in a first direction and a second direction, and

the hole elements that are adjacent in the first direction are connected to each other, and the hole elements that are adjacent in the second direction are connected to each other.

(15) An electronic apparatus including:

a transparent conductive element including a substrate having a first surface and a second surface, transparent conductive portions and transparent insulating portions that are alternately provided in a planar manner on the first surface and on the second surface, wherein

each of the transparent insulating portions is a transparent conductive layer including hole elements provided two-dimensionally in a first direction and a second direction, and

the hole elements that are adjacent in the first direction are connected to each other, and the hole elements that are adjacent in the second direction are connected to each other.

(16) An electronic apparatus including:

a first transparent conductive element; and

a second transparent conductive element provided on a surface of the first transparent conductive element, wherein

each of the first transparent conductive element and the second transparent conductive element includes
a substrate having a first surface and a second surface,
transparent conductive portions and transparent insulating portions that are alternately provided in a planar manner on the first surface and on the second surface, wherein

each of the transparent insulating portions is a transparent conductive layer including hole elements provided two-dimensionally in a first direction and a second direction, and

the hole elements that are adjacent in the first direction are connected to each other, and the hole elements that are adjacent in the second direction are connected to each other.

(17) A method for manufacturing a transparent conductive element, the method including:

printing an etching solution onto a transparent conductive layer provided on a surface of a substrate to form hole elements arranged two-dimensionally in a first direction and a second direction on the surface of the substrate, whereby transparent conductive portions and transparent insulating portions alternately provided in a planar manner on the surface are formed, wherein

the hole elements that are adjacent in the first direction are connected to each other, and the hole elements that are adjacent in the second direction are connected to each other.

(18) The method for manufacturing a transparent conductive element according to (17), wherein the printing is printing by an inkjet method or a minute droplet application method.
(19) The method for manufacturing a transparent conductive element according to (17) or (18), wherein a virtual grid is set on the surface of the substrate, and the etching solution is printed on the basis of the set grid.
(20) A method for patterning a thin film, the method including:

printing an etching solution onto a thin film provided on a surface of a substrate to form a plurality of hole elements arranged one-dimensionally or two-dimensionally in the thin film, wherein

the hole elements are connected to each other.

(21) A method for manufacturing a transparent conductive element, the method including:

printing an organic solvent or water onto a transparent conductive layer provided on a surface of a substrate to form hole elements arranged two-dimensionally in a first direction and a second direction on the surface of the substrate, whereby transparent conductive portions and transparent insulating portions that are alternately provided in a planar manner on the surface are formed, wherein

the hole elements that are adjacent in the first direction are connected to each other, and the hole elements that are adjacent in the second direction are connected to each other.

(22) The method for manufacturing a transparent conductive element according to (21), wherein after the organic solvent or water is printed onto the transparent conductive layer, a swelled portion of the transparent conductive layer is wiped off.
(23) A method for patterning a thin film, the method including:

printing an organic solvent or water onto a thin film provided on a surface of a substrate to form a plurality of hole elements arranged one-dimensionally or two-dimensionally in the thin film, wherein

the hole elements are connected to each other.

### REFERENCE SIGNS LIST

1 First transparent conductive element
2 Second transparent conductive element
3 Optical layer
4 Display device
5, 6 Bonding layer
10 Information input device
11, 21 Substrate
12, 22 Transparent conductive layer
13, 23 Transparent electrode portion
14, 24 Transparent insulating portion
13a Hole element
13b Hole portion
13c Transparent conductive portion
14a Hole element
14b Island portion
14c Separation portion
L Boundary
R₁ First region
R₂ Second region

1. A transparent conductive element comprising:
a substrate having a surface;
transparent conductive portions and transparent insulating portions that are alternately provided in a planar manner on the surface, wherein
each of the transparent insulating portions is a transparent conductive layer including a plurality of hole elements provided two-dimensionally in a first direction and a second direction on the surface of the substrate, and
the hole elements that are adjacent in the first direction are connected to each other, and the hole elements that are adjacent in the second direction are connected to each other.

2. The transparent conductive element according to claim 1, wherein the transparent conductive layer comprises a plurality of island portions separated from each other through the hole elements.

3. The transparent conductive element according to claim 1, wherein the plurality of hole elements are randomly arranged two-dimensionally in the first direction and the second direction.

4. The transparent conductive element according to claim 1, wherein the hole elements are circular, substantially circular, elliptical, or substantially elliptical.

5. The transparent conductive element according to claim 1, wherein the hole elements that are adjacent in a direction diagonal to the first direction or the second direction are connected to each other.

6. The transparent conductive element according to claim 1, wherein the hole elements are obtained by printing of an etching solution on the transparent conductive layer.

7. The transparent conductive element according to claim 6, wherein the printing is printing by an inkjet method or a minute droplet application method.

8. The transparent conductive element according to claim 1, wherein the hole elements are provided at boundary portions between the transparent conductive portions and the transparent insulating portions and arranged in a direction in which the boundary portions extend.

9. The transparent conductive element according to claim 1, wherein
each of the transparent conductive portions is the transparent conductive layer including hole elements arranged two-dimensionally in the first direction and the second direction on the surface of the substrate, and
the hole elements that are adjacent in the first direction are connected to each other, and the hole elements that are adjacent in the second direction are connected to each other.

10. The transparent conductive element according to claim 9, wherein
the plurality of hole elements in the transparent conductive portions and the transparent insulating portions are randomly provided two-dimensionally in the first direction and the second direction,
an average ratio P1 of the hole elements in the transparent conductive portions satisfies a relationship P1≦50[%], and
an average ratio P2 of hole elements in the transparent insulating portions satisfies a relationship 50[%]<P2.

11. The transparent conductive element according to claim 9, wherein a difference ΔP (=P2−P1) between the average ratio P2 of the hole elements in the transparent insulating portions and the average ratio P1 of the hole elements in the transparent conductive portions satisfies a relationship ΔP≦30[%].

12. The transparent conductive element according to claim 1, wherein each of the transparent conductive portions is the transparent conductive layer that is continuously provided in a region between the transparent insulating portions.

13. An input device comprising:
a substrate having a first surface and a second surface,
transparent conductive portions and transparent insulating portions that are alternately provided in a planar manner on the first surface and on the second surface, wherein
each of the transparent insulating portions is a transparent conductive layer including a plurality of hole elements provided two-dimensionally in a first direction and a second direction, and
the hole elements that are adjacent in the first direction are connected to each other, and the hole elements that are adjacent in the second direction are connected to each other.

14. An input device comprising:
a first transparent conductive element; and
a second transparent conductive element provided on a surface of the first transparent conductive element, wherein
each of the first transparent conductive element and the second transparent conductive element includes
a substrate having a surface, and
transparent conductive portions and transparent insulating portions that are alternately provided in a planar manner on the surface,
each of the transparent insulating portions is a transparent conductive layer including hole elements provided two-dimensionally in a first direction and a second direction, and
the hole elements that are adjacent in the first direction are connected to each other, and the hole elements that are adjacent in the second direction are connected to each other.

15. An electronic apparatus comprising:
a transparent conductive element including a substrate having a first surface and a second surface, transparent conductive portions and transparent insulating portions that are alternately provided in a planar manner on the first surface and on the second surface, wherein
each of the transparent insulating portions is a transparent conductive layer including hole elements provided two-dimensionally in a first direction and a second direction, and
the hole elements that are adjacent in the first direction are connected to each other, and the hole elements that are adjacent in the second direction are connected to each other.

16. An electronic apparatus comprising:
a first transparent conductive element; and
a second transparent conductive element provided on a surface of the first transparent conductive element, wherein
each of the first transparent conductive element and the second transparent conductive element includes
a substrate having a first surface and a second surface,
transparent conductive portions and transparent insulating portions that are alternately provided in a planar manner on the first surface and on the second surface, wherein
each of the transparent insulating portions is a transparent conductive layer including hole elements provided two-dimensionally in a first direction and a second direction, and
the hole elements that are adjacent in the first direction are connected to each other, and the hole elements that are adjacent in the second direction are connected to each other.

17. A method for manufacturing a transparent conductive element, the method comprising:
printing an etching solution onto a transparent conductive layer provided on a surface of a substrate to form hole elements arranged two-dimensionally in a first direction and a second direction on the surface of the substrate, whereby transparent conductive portions and transparent insulating portions alternately provided in a planar manner on the surface are formed, wherein
the hole elements that are adjacent in the first direction are connected to each other, and the hole elements that are adjacent in the second direction are connected to each other.

18. The method for manufacturing a transparent conductive element according to claim 17, wherein the printing is printing by an inkjet method or a minute droplet application method.

19. The method for manufacturing a transparent conductive element according to claim 17, wherein a virtual grid is set on the surface of the substrate, and the etching solution is printed on the basis of the set grid.

20. A method for patterning a thin film, the method comprising:
printing an etching solution onto a thin film provided on a surface of a substrate to form a plurality of hole elements arranged one-dimensionally or two-dimensionally in the thin film, wherein
the hole elements are connected to each other.
